(19) United States
(12) Patent Application Publication
(10) Pub. No.: US 2012/0037206 A1
(43) Pub. Date: Feb. 16, 2012

(54) SYSTEMS FOR COST EFFECTIVE CONCENTRATION AND UTILIZATION OF SOLAR ENERGY

(76) Inventors: Richard NORMAN, Sutton (CA); Frederick de St. Croix, Black Creek (CA)

(21) Appl. No.: 12/857,536

(22) Filed: Aug. 16, 2010

(51) Int. Cl. H01L 31/052

(52) U.S. Cl. 136/246

(57) ABSTRACT

The present invention is primarily directed to improvements to cost-effective systems for concentrating and using solar energy. The present invention co-optimizes the frame and the primary mirrors and secondary concentrator for a cost-effective very high concentration quasi-parabolic dish system that uses no moulded optics for the primary concentration, and also optimizes fabrication jigs for the main components of that design. The present invention also optimizes cell contacts and provides cost effective receiver cooling for dense receiver arrays for very high concentration photovoltaic systems. The present invention also includes a semi-dense receiver array that can provide a higher acceptance angle than a dense receiver array, and finally includes mutual-shading impact minimization methods and apparatus compatible with very high concentration photovoltaic systems.

### TECHNICAL FIELD

This invention relates to the field of solar mirror fabrication and alignment, concentrated photo-voltaics, photo-voltaic receivers, heat exchangers and control systems for photo-voltaic systems.

### SUMMARY OF THE PRIOR ART

Pre-shaped glass mirrors offer the highest specular reflectivity, and pre-shaped glass parabolic trough segments are generally made by pressing mirrored glass against an accurately curved parabolic mandrel while an adhesive bonding the glass to a sturdy backing material sets, locking in the appropriate curvature (“Sandwich Construction Solar Structural Facets”, Sandia National Laboratories; and “Further Analysis of Accelerated Exposure Testing of Thin-Glass Mirror”, Kennedy et al, ES2007), or similarly pre-shaping a backing material and then bonding the glass to it using a mandrel (U.S. Pat. No. 7,550,054, Lasich), or slump-molding glass against an accurate mandrel. However these methods require extensive time on an expensive mandrel, which limits production capacity from a given investment in tooling.

Very high concentration large parabolic dish systems are designed to maximize concentration and maximize error tolerance or acceptance angle using a given mirror segment size and shape. To reduce the need for bypass diodes, a large receiver can be divided into a number of sub-arrays small enough to each have a relatively even illumination intensity, and these sub-arrays can be connected in parallel (U.S. patent application Ser. No. 10/557,456, Lasich). When significantly uneven focal intensity may occur, bypass diodes are used to prevent the weakest cell or the weakest sub-array from pulling the performance of the whole receiver down.

Frames for parabolic troughs and dishes are manufactured with precisely cut or precisely drilled components to produce accurate curves for maximum concentration and/or acceptance angle are well known in the art, dating back at least to Carter, who in U.S. Pat. No. 811,274 teaches supporting mirror segments directly on curved metal rails whose curve is determined by sleeves of precise lengths, and is exemplified by Wood, who in U.S. Pat. No. 6,485,152 teaches an entire frame made of a few sets of identical pieces with the curvature determined by precisely located holes. But such precision adds cost to the manufacturing process. Hybrid rib/rails on a thin central truss with the ribs acting as parts of a larger compound truss is taught by co-pending U.S. patent application Ser. No. 12/424,393 (Norman et al, hereinafter referred to as Norman) which is hereby incorporated by reference, but this requires complex bracing.

When cooling demands exceed the capability of rectangular tubes carrying cooling fluid, mini-channel or micro-channel coolers can be used (Nonuniform Temperature Distribution in Electronic Devices Cooled by Flow in Parallel Microchannels, Hetsroni et al; and Single-Phase Heat Transfer Enhancement Techniques in Microchannel and Minichannel Flows, Steinke et al). However fabricating these numerous narrow and deep channels by etching a block of silicon or machining a block of copper with saws or with electron discharge machining is expensive and time consuming.

Photovoltaic cells are generally placed by pick-and-place machinery which typically has 50-micron accuracy. When cells are widely separated this adds only a small cost from needing slightly larger cells to cover for this inaccuracy, but in dense arrays the 50-micron gap remains unfilled, reducing efficiency.

Individual ceramic substrates for cells under high concentration and very high concentration are commonly used, but one such substrate is required per cell. Multi-cell ceramic substrates have been used by Solar Systems Pty (Lasich '456), but these comprise complex high-current circuits to interconnect the cells.

Concentrator solar cells typically have a back contact covering the back of the cell for one contact polarity, and have one or more wide bus-bar front contacts for the other contact polarity. Such cells are well suited to sparse arrays of cells, where a separate wire can connect the bus bar on the front of one cell to the back of another cell, connecting the cells in series. However there is no room for such a separate wire in a dense receiver array. Instead using such cells in a dense receiver array can be done by shingling the back of one cell onto the bus bar on the front of a neighboring cell (as taught in Norman), thus connecting the cells in series. However the bus bar covers a few percent of the cell surface, and while the bus bar is in turn covered by active cell area on the next cell, the bus bar still increases the size of the cell and thus reduces the number of cells per wafer and raises the cell cost. Shingling the cells also slants the cells relative to the incoming light, increasing the incidence angle for light from one side and decreasing it for the other side, creating asymmetry in the optics that complicates obtaining an even focus.

Cells for dense receiver arrays can also have backside contacts for both contact polarities, allowing the cells to be placed side by side in a dense array as shown in Lasich '456. This, however, requires placing the cells on a substrate containing a high-current circuit that connects the cells in series.

High concentration and especially very high concentration photovoltaic systems generally use sparse arrays where the cells are relatively evenly spaced over an array as large as the whole system's aperture. While this allows even passive cooling to keep the cells below their maximum operating temperature, it require extensive inter-cell wiring and a sealed unit the size of the whole system's aperture. Systems that use a multi-cell focus use dense arrays that conveniently centralize the electronics (Lasich '456), but such arrays are hard to cool well even with pumped-liquid active cooling and require expensive mini-channel or micro-channel coolers. Systems that use arrays of refractive optics in contact with arrays of cells are also known (A Solid 500 Suns Compound Concentrator PV Design, Horne et al, WCPEC4), but these require an area of precision-moulded optics the size of the entire light-collecting area.

Anti-shading algorithms for trackers with non-concentrating flat panels are known in the art. Trackers can be equipped with sensors to detect when their lowest rows of cells are shaded, and the sensors can then cause the shading tracker to backtrack until those cells are no longer shaded. However high-concentration photovoltaic system only work when pointed accurately at the sun so implementing this anti-shading algorithm with high concentration photovoltaic systems would generally misalign all systems enough that no appreciable power would be generated.

Because harnessing solar energy at a cost that allows it to replace fossil fuels is so important to humanity's future, there is a critical need to overcome the drawbacks of the current art, as discussed above, by providing more cost-effective ways to focus the sun's energy to high concentration and very high concentration and to use that concentration for photovoltaics and a wide variety of energy-intensive thermal transformations.

### SUMMARY OF THE INVENTION

It is an object of the present invention to provide a very high concentration system that uses just one type of mirror of a shape that can be formed from a flat sheet of mirror material simply by affixing the material to a properly shaped frame.

It is a further object of the present invention to accomplish this with a mirror shape whose surface curves in only one direction at any given point.

It is an even further object of the present invention to accomplish this with a mirror shape that is symmetrical so that it can be shaped by shaping means, on each side of the mirror's frame, that are identical, and so that during installation it does not matter which end of the mirror is placed in which direction, reducing installation errors.

It is another object of the present invention to provide a panel frame for a mirror of a shape that can be formed from a flat sheet of mirror material simply by affixing the material to a properly shaped frame, where the back of one frame serves as a mandrel for pressing the next mirror to fit its panel frame, holding the mirrors in a stack of panels (mirrors-and-frames) in shape and against their respective frames while an adhesive affixing the mirrors to their respective frames sets.

It is a further object of the present invention to provide a panel frame for assembling mirrors and frames into a stack of panels, where one face of the frame has retention means that help hold the next mirror in place, in the stack of mirrors and frames, while an adhesive sets to secure that next mirror to its frame.

It is an even further object of the present invention to provide a panel frame for assembling mirrors and frames into a stack of panels, where the back of one frame has retention means that help hold the next mirror in place in the stack of mirrors and frames, and where the retention means also help to align the next mirror's panel frame to said next mirror.

It is a still further object of the present invention to provide such retaining and aligning means on the back of each frame so that a stack of mirrors and frames can be assembled mirror face down so that any excess adhesive that drips falls onto the back, rather than onto the front, of the previous mirror.

It is a further object of the present invention to provide a panel frame for assembling mirrors and frames in a stack, where there are protrusions on the surface of the frame to which the adhesive will be applied that keep the adhesive from being squeezed out too thin, under the weight of a stack of mirrors and frames, by supporting the mirror back when the adhesive is at the proper thickness.

It is an even further object of the present invention to provide a panel frame for assembling mirrors and frames in a stack, where the protrusions on the surface of the frame to which the adhesive will be applied are bumps formed into the frame at the time that the overall shape of the frame member to which the adhesive will be applied is formed.

It is a still further object of the present invention to provide a panel frame for assembling mirrors and frames in a stack, where the frame member with the surface of the frame to which the adhesive will be applied is a curved member stamped from sheet metal, where the bumps that keep the adhesive from being squeezed to thin are on a concave surface of said member that is stretched during said stamping, and where the opposite surface that will serve as a mandrel has ridges in it that relieve the slight compression from the stamping without interfering with its ability to serve as a mandrel.

It is also an object of the present invention to provide multiple identical quasi-parabolic rails that support multiple mirror segments that focus light onto a receiver, where the shape of the rails where they support one or more of the mirror segments that have the tightest foci on the receiver is deliberately off from parabolic to an extent that produces a more even focus on said receiver.

It is a further object of the present invention to accomplish this where the receiver has a secondary concentrator that tightens the focus, and having the rails' shape deliberately off from parabolic throws more light onto said secondary concentrator than a comparable true parabolic shape would.

It is an even further object of the present invention to accomplish this in a manner that produces a focus even enough in at least one direction that when the rails and their mirrors are properly aligned, identical sets of photovoltaic cells in series in said direction all receive sufficient illumination to contribute a voltage that increases the voltage of said series of sets of cells.

It is another object of the present invention to provide such ribs that are adapted to a lattice box central truss, where the box central truss has its own short rib sections that support sets of an integral number of reflective panels.

It is also an object of the present invention to provide a high-accuracy, low-cost method of forming parabolic ribs with integrated rails, and a low-cost jig for implementing said method.

It is a further object of the present invention to provide a high-accuracy, low-cost method of forming parabolic ribs with integrated rails, and a low-cost jig for implementing said method, where none of the parts of the parabolic rib or integrated rail need precise cutting or machining.

It is an even further object of the present invention to provide a high-accuracy, low-cost method of forming parabolic ribs with integrated rails, and a low-cost jig for implementing said method, where none of the parts of the parabolic rib or integrated rail need precise cutting or machining and where all parts can be welded without added weld material.

It is also an object of the present invention to provide an easy-to-fabricate, low-cost evaporative heat pipe cooling tube for each individual row of cells for a very high concentration dense-array photovoltaic receiver, where said evaporative heap pipe uses gravity return for condensed liquid at all angles encountered while tracking the sun across the sky.

It is a further object of the present invention to provide such an easy-to-fabricate, low-cost gravity-return evaporative heat pipe cooling tube for each individual row of cells for a very high concentration dense-array photovoltaic receiver, where said evaporative heap pipe uses a chamber made from at most two stamped pieces, and where inward dimples in the stamped surfaces touch in the interior of the chamber to prevent the chamber walls from collapsing under the partial vacuum of the heat pipe liquid's vapor pressure.

It is another object of the present invention to provide an easy-to-fabricate, low-cost mini-channel coolant tube array for a very high concentration dense-array photovoltaic receiver.

It is a further object of the present invention to provide an easy-to-fabricate, low-cost mini-channel coolant tube array for a very high concentration dense-array photovoltaic receiver, where a mini-channel cooling tube is cut from a block made from overlapping strips of high thermal conductivity material.

It is an even further object of the present invention to provide an easy-to-fabricate, low-cost mini-channel coolant tube array for a very high concentration dense-array photovoltaic receiver, where multiple mini-channel cooling tubes are cut from a block made from overlapping strips of high thermal conductivity material.

It is a further object of the present invention to provide an easy-to-fabricate, low-cost mini-channel coolant tube array for a very high concentration dense-array photovoltaic receiver, where multiple mini-channel cooling tubes are cut from a block made from sheets of high thermal conductivity material alternating with spacers.

It is an even further object of the present invention to provide an easy-to-fabricate, low-cost mini-channel coolant tube array for a very high concentration dense-array photovoltaic receiver, where multiple mini-channel cooling tubes are cut from a block made from sheets of high thermal conductivity material alternating containing spacers and the spacers include depth marks to aide in controlling the thinning of the tube face nearest the heat source to be cooled.

It is an even further object of the present invention to provide an easy-to-fabricate, low-cost mini-channel coolant tube array for a very high concentration dense-array photovoltaic receiver, where multiple mini-channel cooling tubes are cut from a block made from sheets of high thermal conductivity material alternating containing spacers and the spacers comprise pairs of wires.

It is an even further object of the present invention to provide an easy-to-fabricate, low-cost mini-channel coolant tube array for a very high concentration dense-array photovoltaic receiver, where multiple mini-channel cooling tubes are cut from a block made from sheets of high thermal conductivity material alternating containing spacers and the spacers comprise strips of thermally conductive material.

It is a still further object of the present invention to provide an easy-to-fabricate, low-cost mini-channel coolant tube array for a very high concentration dense-array photovoltaic receiver, where multiple mini-channel cooling tubes are cut from a block made from sheets of high thermal conductivity material alternating containing spacers, where each cooling tube has multiple inlets and outlets for the cooling fluid.

It is a yet further object of the present invention to provide an easy-to-fabricate, low-cost mini-channel coolant tube array for a very high concentration dense-array photovoltaic receiver, where multiple mini-channel cooling tubes are cut from a block made from sheets of high thermal conductivity material alternating containing spacers, where each cooling tube has multiple inlets and outlets for the cooling fluid, and where the spacers comprise strips of thermally conductive material that are contoured to enhance the cooling efficiency of the resulting cooling tube.

It is a further object of the present invention to provide an easy-to-fabricate, low-cost mini-channel cold plate the size of the dense receiver array for a very high concentration dense-array photovoltaic receiver, where multiple mini-channel cold plates are cut from a block made from sheets of high thermal conductivity material alternating containing spacers, where the cold plate has multiple inlets and outlets for the cooling fluid, and where the spacers comprise strips of thermally conductive material that are contoured to enhance the cooling efficiency of the resulting cold plate.

It is another object of the present invention to provide cooling tubes and cold plates in which the thermally conductive fins are constructed so that during expansion or contraction relative to the faces of the cooling tube or cold plate the fins apply very little force on said faces.

It is a further object of the present invention to provide cooling tubes and cold plates in which the thermally conductive fins are pre-bent, or corrugated, so that during expansion or contraction relative to the faces of the cooling tube or cold plate the fins apply very little force on said faces.

It is an even further object of the present invention to provide cooling tubes and cold plates in which the thermally conductive fins are pre-bent, or corrugated, so that during expansion or contraction relative to the faces of the cooling tube or cold plate the fins apply very little force on said faces, where the faces have their thermal expansion constrained to a far lower coefficient of thermal expansion than the material of the internal thermally conductive fins.

It is a further object of the present invention to provide cooling tubes and cold plates in which the thermally conductive fins are slit so that during expansion or contraction relative to the faces of the cooling tube or cold plate the fins apply very little force on said faces.

It is an even further object of the present invention to provide cooling tubes and cold plates in which the thermally conductive fins are slit so that during expansion or contraction relative to the faces of the cooling tube or cold plate the fins apply very little force on said faces, where the faces have their thermal expansion constrained to a far lower coefficient of thermal expansion than the material of the internal thermally conductive fins.

It is also an object of the present invention to provide an easy-to-fabricate, low-cost mini-channel coolant tube array for a very high concentration dense-array photovoltaic receiver that uses one wall of one coolant tube to provide an alignment guide for cells being placed on the next coolant tube.

It is a further object of the present invention to provide an easy-to-assemble, low-cost mini-channel coolant tube array for a very high concentration dense-array photovoltaic receiver that uses one wall of one coolant tube to provide an alignment guide for cells being placed on the next coolant tube, and where cells are placed snug by force feedback rather than by position.

It is an even further object of the present invention to provide an easy-to-assemble, low-cost mini-channel coolant tube array for a very high concentration dense-array photovoltaic receiver that uses one wall of one coolant tube to provide an alignment guide for cells being placed on the next coolant tube, where cells are placed snug by force feedback rather than by position, and where said wall is provided with a tacky surface that holds in place cells pressed against it.

It is another object of the present invention to provide a highly thermally conductive but electrically insulating interposer for one more or photovoltaic cells, wherein the interposer provides a flat surface for photovoltaic cells that is angled at a suitable angle for shingling said cells into a dense array photovoltaic receiver.

It is a further object of the present invention to provide a highly thermally conductive but electrically insulating interposer for one more or photovoltaic cells, wherein the interposer provides a flat surface for photovoltaic cells that is angled at a suitable angle for shingling said cells into a dense array photovoltaic receiver, and where the assembly processes uses one wall of one interposer as an alignment guide for cells being placed on the next interposer, where cells are placed snug by force feedback rather than by position, and where said wall is provided with a tacky surface that holds in place cells pressed against it.

It is another object of the present invention to provide a jig for assembling photovoltaic cells on a highly thermally conductive but electrically insulating interposer, where the jig has one face that is replaceably covered with two-sided tacky tape, and where cells are placed snug by force feedback rather than by position, and where said tacky tape releaseably holds in place cells pressed against it.

It is also an object of the present invention to provide improved cells for high-concentration solar energy systems, where the cells are made more efficient by using controlled-shape top contacts that are formed separately from the cell and then transferred to the cell.

It is a further object of the present invention to provide such separately-formed contacts that have substantially vertical sides so as to reflect far-from-normal angle-of-incidence light onto the active surface of the cell.

It is a further object of the present invention to provide such separately-formed contacts that are formed within cavities in an optical element that is then placed so that those contacts come into contact with the cell surface or with conductive traces on the cell surface.

It is another object of the present invention to provide solar cells with contacts on opposing sides that allow the cells to be placed electrically in parallel by pressing the cells' sides against each other.

It is another object of the present invention to provide solar cells with contacts on opposing sides that allow the cells to be placed electrically in series by pressing the cells' sides against each other.

It is a further object of the present invention to provide solar cells with contacts on opposing sides that allow cells in a row of cells to be placed electrically in parallel by pressing the cells' sides within a row against each other, and to allow rows of cells to be placed electrically in series with other rows of cells by placing the cells' sides between rows against each other.

It is an even further object of the present invention to provide solar cells with contacts on opposing sides that allow cells in a row of cells to be placed electrically in parallel by pressing the cells' sides within a row against each other, and to allow rows of cells to be placed electrically in series with other rows of cells by placing the cells' sides between rows against each other, where one or more of a given cell's side contacts also serve as bus bars for the cell's top contacts.

It is a still further object of the present invention to provide solar cells with contacts on opposing sides that allow cells in a row of cells to be placed electrically in parallel by pressing the cells' sides within a row against each other, and to allow rows of cells to be placed electrically in series with other rows of cells by placing the cells' sides between rows against each other, where each cell has side contacts on all four sides that also serve as bus bars for the cell's top contacts.

It is a further object of the present invention to provide solar cells with contacts on opposing sides that allow cells in a row of cells to be placed electrically in parallel and or in series by pressing the cells' sides against each other, where the side contacts are made in streets cut into the surface of a wafer of cells before the wafer is diced along the streets.

It is a further object of the present invention to provide solar cells with contacts on opposing sides that allow cells in a row of cells to be placed electrically in parallel and or in series by pressing the cells' sides against each other, where the side contacts have insulation between them and the cell substrate.

It is a further object of the present invention to provide solar cells with contacts on opposing sides that allow cells in a row of cells to be placed electrically in parallel and or in series by pressing the cells' sides against each other, where the side contacts have positional tolerance.

It is an even further object of the present invention to provide solar cells with contacts on opposing sides that allow cells in a row of cells to be placed electrically in parallel and or in series by pressing the cells' sides against each other, where the side contacts have positional tolerance provided by releasing the contact material from the cell substrate or from insulation on the cell substrate.

It is a further object of the present invention to provide a method for making side contacts en masse on the cells of multiple interposers each with multiple cells.

It is an even further object of the present invention to provide a method for making side contacts en masse on the cells of multiple interposers each with multiple cells, where the side contacts have positional tolerance provided by releasing the contact material from the cell substrate or from insulation on the cell substrate.

It is an even further object of the present invention to provide a jig for making side contacts en masse on the cells of multiple interposers each with multiple cells.

It is another object of the present invention to provide solar cells with a reflective side face on the edge of the cell that will be shingled above another cell.

It is a further object of the present invention to have such a reflective face also serve as a bus bar for the cell's top contacts.

It is also an object of the present invention to provide a semi-dense array of cells for a photovoltaic receiver that provides greater space for improved cooling capability per cell than a dense array provides while using a small area of refractive optics and minimizing or avoiding the need for bypass diodes.

It is a further object of the present invention to provide a semi-dense array that functions cooperatively with reflective secondary optics to further minimize the overall area of refractive optics relative to the minimum space around each cell for improved cooling capability.

It is another object of the present invention to provide a semi-dense array of cells for a photovoltaic receiver that uses an array of small refractive optical elements that have aperture areas substantially inversely proportional to the insolation intensity at the aperture of each such refractive optical element.

It is another object of the present invention to provide a semi-dense array of cells for a photovoltaic receiver that uses an array of small refractive optical elements that have sets of cells-in-parallel where the aperture area for the refractive optical elements for each set of cells is substantially inversely proportional to the average insolation intensity at the aperture of the refractive optical elements for said set of cells.

It is a further object of the present invention to provide a semi-dense array of cells for a photovoltaic receiver that uses an array of small refractive optical elements that have set of cells in parallel where the aperture area for the refractive optical elements for each set of cells is substantially inversely proportional to the average insolation intensity at the aperture of the refractive optical elements for said set of cells until said average insolation intensity falls to roughly half as great as the highest average insolation intensity, at which point the number of cells in each set of cells is approximately doubled.

It is another object of the present invention to provide a semi-dense array of cells for a photovoltaic receiver that has a small area of refractive optics that provides a refractive optical element for each cell, where multiple refractive optical elements are moulded as a single piece.

It is another object of the present invention to provide a dense or semi-dense array of cells for a photovoltaic receiver for a large-aperture primary concentrator, where the impact of partial shading and/or of tracking error of the primary concentrator in minimized by putting cells on one side or end of the array in parallel with cells from the opposite side or end of the array.

It is a further object of the present invention to provide a dense or semi-dense array of cells for a photovoltaic receiver for a large-aperture primary concentrator, where the receiver comprises row of cells in parallel, and where the impact of partial shading and/or of tracking error of the primary concentrator in minimized by putting half-rows of cells on one side or end of the array in parallel with half-rows of cells from the opposite side or end of the array.

It is also an object of the present invention to provide mutual shading impact minimization methods compatible with high-concentration photovoltaic systems to allow denser packing of such systems without undue performance loss from mutual shading at low sun altitude.

It is a further object of the present invention to provide this in a manner which is compatible with bypass-diode-free dense of semi-dense receiver arrays.

It is an even further objective of the present invention to accomplish this by deliberately slightly misaligning a tracker relative to the direction of the sun in a manner that maximizes total output power under partial shading conditions.

It is a still further objective of the present invention to accomplish this by deliberately slightly misaligning a tracker relative to the direction of the sun in a manner that maximizes total output power under partial shading conditions, but reduces the extra tracking motion needed to maximize the power by combining astronomically calculated adjustments in between maximum-power-seeking trial adjustments.

It is a still further objective of the present invention to accomplish this by deliberately slightly misaligning a tracker relative to the direction of the sun in a manner that maximizes total output power under partial shading conditions, but reduces the extra tracking motion needed to maximize the power by providing simultaneous measurements of the insolation intensity on numerous regions of the receiver to allow more accurately calculating how much the receiver misalignment needs to be adjusted to maximize overall receiver power output.

It is a further objective of the present invention to accomplish this by rotating a subset of the trackers in a field of trackers substantially edge-to-the-sun to minimize the size of their shadows.

It is an even further objective of the present invention to accomplish this by rotating half of any remaining face-to-the-sun trackers to edge-to-the-sun whenever the dishes on the face-to-the-sun trackers are approximately half shaded.

It is another object of the present invention to provide a thermal mass capable of cooling the receiver below its maximum safe operating temperature in the event that the cooling fans cannot be run.

It is a further object of the present invention to provide such a thermal mass in a manner that also keeps the concrete from freezing on winter nights.

It is a further object of the present invention to provide such a thermal mass in a manner that also provides a thermal mass that can keep a receiver from freezing on winter nights.

It is a further object of the present invention to provide a solar power system having a photovoltaic apparatus using any one or more of the above objects, an electrical load, and a transmission line connecting the photovoltaic apparatus to the load. The apparatus can be located in a location with good insolation, such as high altitude or sunny or desert climates, while the load can be located where there is good need for electrical power.

### DEFINITIONS

“Acceptance Angle” as used herein means the angular range over which light entering the tracker aperture or mirror aperture will generally be reflected, refracted and/or diffracted so that it reaches a receiver, and is thus ‘accepted’ by that receiver. When more specificity is needed, the “Acceptance Angle” of a solar concentrator is defined as the angular range for incoming light for which 90% of the light entering the aperture, which is not absorbed on its way to the receiver, reaches the surface of the receiver. In general a system with a higher acceptance angle is more tolerant of errors in design, manufacturing, assembly and tracking.

“Active Cooling” as used herein means a system that uses applied power to remove heat, including thermo-electric chillers and plasma wind generators without moving parts, as well as pumps or fans. See also “Passive Cooling”.

“Altitude” as used herein means vertical angle above the horizon (e.g., the altitude of the sun is the angle that the sun is above the horizon).

“Altitude Tracking” as used herein means motion in the vertical direction to track the height of the sun.

“Aperture” as used herein means the profile of the light-collecting area as seen from a direction that maximizes its apparent (effective) size.

“Astronomic Tracking” as used herein means tracking based on the calculated position of the sun, generally as determined by the latitude and longitude of the tracker, the season, and the time of day.

“Axis of Symmetry” as used herein means an axis about which an object has either rotational or reflectional symmetry. For a parabola this is in the direction of the focus for light at a ‘normal’ angle (at right angles to the surface at the axis of symmetry), and for a paraboloid of rotation it is also the axis about which the starting parabola is rotated.

“Bus Bar” as used herein means a large conductor that receives electrical current from, or delivers electrical current to, a number of smaller conductors.

“Bypass Diode” as used herein means a one-way device for electrical current, which will let current substantially freely flow across it in one direction if the voltage on a first side of the diode is higher than the voltage on a second side, but will substantially block the flow of current in the reverse direction if the voltage on the first side is lower than the voltage on the second side.

“Cell String” as used herein means a string of photovoltaic cells that are connected in series. While a string of cells adds cell voltages (rather than cell currents) and thus minimizes conductor sizes and resistive losses, the cells must either be evenly illuminated or have bypass diodes to prevent a less-illuminated cell from reducing the efficiency of the entire cell string. Also called a “String of Cells”.

“Center of Gravity (also Center of Mass)” as used herein means the point at which an object will balance around any axis through that point. See also “Balance Height”.

“Center of Wind Loading” as used herein means the point at which constant-speed wind from any direction will produce no net rotational force about that point.

“Circular Arc” as used herein means an arc that is a section of a circle, and thus whose radius of curvature is constant”.

“Coefficient of Thermal Expansion” (also “CTE”, “Thermal Coefficient of Expansion” and “TCE”) as used herein means the rate at which the size of an object changes due to changes in the object's temperature, usually measured in parts-per-million per degree Celsius (ppm/° C.). Differences in thermal expansion can cause thermal stress in materials especially when large regions of rigid materials with substantially different TCEs are bonded together at one temperature and then heated or cooled to a significantly different temperature. For the purposes of the photovoltaic receivers of the present application, two substances are said to have a close match in CTE if their CTE's differ by less than two parts per million per degree Celsius (2 ppm/° C.) because with so low a difference even relatively brittle materials like the solar cells can be bonded to other materials and survive the summer-day to winter night temperature changes.

“Compound Mirror” as used herein means a mirror composed of multiple discrete segments of mirror material.

“Cold Plate” as used herein means a cooling device with numerous small channels cut into it to allow for high channel surface area near a surface to be cooled.

“Concave” as used herein means a curve that bends toward the observer.

“Concentration” as used herein can be either geometric concentration, which is the ratio of the aperture size to the focal spot size (this ignores imperfections in mirrors and minor shadows but is useful for calculating acceptance angles and focal spot sizes), or illumination concentration, which is the ratio of the intensity of focused sunlight to the intensity of direct sunlight, and which thus includes the losses from such imperfections. Geometric concentration is symbolized with an ‘×’ (e.g., 100×), whereas illumination concentration is measured in ‘suns’ (e.g., 1000 suns).

“Conduction Losses” as used herein means a loss of voltage, and thus power and energy, through the resistance of a conductor to the flow of electrons (electrical current) through it.

“Conic Sections” as used herein means the curved sections that can be obtained by planar cuts through a straight-sided cone. These are the circle, ellipse, parabola and hyperbola, depending on the angle of the plane to the angle of the cone.

“Convex” as used herein means a curve that bends away from the observer.

“Cooling Tube” as used herein means a tube that carries a fluid to cool a photovoltaic or solar thermal receiver.

“Cusp” as used herein means a pointed projection (a bit like a tooth).

“Cylindrically Curved” as used herein means a surface that at every point bends in at most one direction, with the directions of curvature at all points substantially parallel to each other (like a section of a cylinder).

“Dead Zone” as used herein means a zone where the velocity of a flowing fluid is substantially reduced.

“Dense Receiver Array” as used herein means a receiver array where the photovoltaic cells of an array of cells are packed into an area less than twice as large as the total receptive area of the cells themselves. See also “Semi-dense Receiver Array” and “Sparse Receiver Array”.

“Dish Frame” as used herein means a rigid frame, typically of steel, to which multiple mirror segments are attached, either directly or indirectly through ribs and or rails, to be held in fixed positions relative to each other. See “Panel Frame”.

“Energy” as used herein means the ability to do work. The efficiency of actually converting energy to work depends on the quality of the energy and the quality of the cold sink into which the energy eventually flows; mechanical potential energy and electrical energy are both very high quality, as are high-energy-density chemicals such as fossil fuels. For thermal energy, the energy quality depends on the temperature, with higher temperatures being higher quality energy as well as generally containing more heat.

“Fine Tracking” as used herein means supplemental tracking that compensates for the inaccuracy of other tracking to achieve increased accuracy.

“Focus” when used as a verb herein is meant multiple surface regions redirecting incident light so that the light from the multiple regions converges into a region smaller than their combined effective area.

“Focus” when used as a noun herein is meant a region that multiple surface regions redirect incident light into, with the ‘focus’ region being smaller than the combined effective area of the multiple surface regions.

“Focal Length” as used herein means the distance from focusing a mirror or a lens at which the focus and the focal spot are smallest.

“Focal Spot” as used herein means the area of a surface into which substantially all of the light focused by a lens or a mirror is concentrated.

“Fossil Fuels” as used herein means fuels that are obtained from long-dead plants, fungi, bacteria, archaea and/or animals or other life-forms yet to be discovered.

“Fresnel Lens” as used herein means a lens that instead of using a continuously curved surface (which results in a standard lens whose thickness, for given focal length, grows approximately with the square of its diameter), uses discontinuous segments of comparable curvature and angle to the standard lens surface but arranged so that the segments form a thin sheet whose thickness is relatively independent of the lens diameter. This emulates the focusing of a standard lens, but requires much less material for even a moderate-aperture lens.

“Gallium Arsenide Substrate” as used herein means a thin wafer of crystalline gallium arsenide. Gallium Arsenide serves as the substrate some high-efficiency solar cells.

“Germanium Substrate” as used herein means a thin wafer of crystalline germanium. Germanium currently serves as the substrate for most of the highest-efficiency solar cells, and accounts for roughly half of their cost.

“Glass Mirror” as used herein means a thin sheet of glass, whether flat, bent, or molded, that has a metallic layer that reflects incident light. Most mirrors have the reflective layer on the back surface of the glass; this is called a ‘second-surface glass mirror’ because the light first passes through the front surface of the glass and is then reflected at the back surface of the glass by the interface to the metallic layer. While first-surface mirrors can have higher reflectivity, a second-surface mirror facilitates weather-proofing, and is thus typically more durable for outdoor use.

“Grazing angle” as used herein means a very low incidence angle that causes much of the light incident at that angle light to be reflected from a surface, even the surface would readily absorb such light if it came in at a higher incidence angle.

“Grid” as used herein means a high-voltage power distribution grid to which the photovoltaic system supplies power when in operation.

“Grid-tied Inverter” as used herein means an inverter that converts DC output from one or more photovoltaic receivers into a form suitable for transmission on a power distribution grid. Grid-tied inverters must shut down feeding the grid when the grid is down to prevent shock hazards to repair crews repairing or maintaining the grid. See also “Grid”, “Inverter” and “Non-grid-tied Inverter”.

“Heat Pipe” as used herein means a sealed tube, or pipe, that transfers heat from a hot region to colder regions of the heat pipe. By starting with just a liquid (such as water) and its vapor in the pipe, the liquid is rapidly evaporated at the hot region and there is little resistance to the vapor travelling to all colder surfaces of the pipe, where it condenses and whence it is returned either by gravity or by capillary action to the hot end of the pipe to complete the cycle. Since evaporating a liquid takes a lot of energy and the vapor can move at up to the speed of sound, a heat pipe can provide thermal conductivity over a hundred times higher than solid copper. See also “Fin Tube”.

“Heat Transfer Coefficient” as used herein means the amount of heat transferred per unit area of a surface per degree of temperature difference.

“High Concentration” as used herein means 100× to 1000× or 100 suns to 1000 suns. This concentration range is readily achievable with two-axis focusing. See also “Low Concentration” and “Very High Concentration”.

“Imaging Concentrator” (also “Imaging Secondary”) as used herein means a concentrator that focuses light without scrambling it, so that a sheet of paper held at the focus would show an approximate image of the object from which the light originates. See also “Non-imaging Concentrator”.

“In Parallel” as used herein means photovoltaic cells that are connected so that their ends are at the same voltages and their photocurrents add together. See also “In Series”.

“In Series” as used herein means photovoltaic cells that are connected together so that the higher-voltage contact of one cell is connected to the lower-voltage contact of the next cell. In this way the voltages of the cells add together, while the current from the cells is not increased. See also “In Parallel”.

“Incidence Angle” as used herein means the angle at which incoming light strikes a surface. In general the lower the incidence angle, the less light a surface will absorb. See also “Grazing angle”.

“Interposer” as used herein means an adaptor placed (interposed) between two surfaces.

“Inverter” as used herein means a device that converts direct current (the output of essentially all photovoltaic systems) into alternating current (the type of current carried by essentially all power lines (with a few very long transmission lines being exceptions).

“Kerf” as used herein means the region of an item that is reduced to sawdust when the item is cut with a saw.

“Kohler” as used herein means a shape for a final concentrating optical element such as is known for secondary concentrator in the art of sparse array Fresnel lens concentrating photovoltaic systems. See also “Spherical Dome”, “SILO”, and “Refractive ITP”.

“Lattice Box Truss” as used herein means a lattice truss whose cross-section (perpendicular to its length) is substantially rectangular.

“Lattice Truss” as used herein means a truss, usually of steel, where multiple thin members are connected by crisscrossing braces. This produces a strong yet comparatively light-weight truss that uses much less material than a solid beam or truss of the same strength.

“Low Concentration” as used herein means less than 10× or less than 10 suns. In some cases this can be achieved without trackers. See also “High Concentration” and “Very High Concentration”.

A “Mandrel” as used herein means a form that something can be pressed against to be bent into a precise shape.

“Micro-channel” as used herein means a channel of less than 0.3 millimeters in width. See also “Mini-channel”.

“Mini-channel” as used herein means a channel of between 0.3 and 3 millimeters in width. See also “Micro-channel”.

“A mirror's normal line” (also “The normal line of a mirror”) as used herein means a line normal (perpendicular) to the mirror's surface; at the center of the mirror if the mirror has a curved surface.

“Mirror Segment” as used herein means a mirror that is aligned with other mirrors to focus on substantially the same region as those other mirrors.

“Mirror Segment Length” as used herein means the length of the long axis of a mirror segment.

“Mirror Segment Width” as used herein means the length of the short axis of a mirror segment.

“Multi junction cell” as used herein means a photovoltaic cell that has multiple photovoltaic junctions (electron-liberating regions) stacked on top of one another. Because most semiconductors are transparent to photons of lower energy than their band gap, high band-gap layers capture the most energetic photons (e.g. ultraviolet, blue) to generate power, while letting lower-energy photons pass on to the next junction (photovoltaic region), etc. This raises the overall efficiency because the photons absorbed by each layer have only a little excess energy above that needed to liberate an electron over the band gap. However, the photocurrents (number of electrons liberated per unit time) of the junctions must typically be matched because the layers are typically in series (which adds the voltages of the layers, reducing resistive losses).

“Mutual Shading” as used herein means the shading of the at least part of the apertures of some trackers by other trackers in a field of trackers.

“Non-grid-tied Inverter” as used herein means an inverter that converts DC output to AC power but does feed that power to the power distribution grid. See also “Grid” and “Grid-tied Inverter”.

“Non-Imaging Concentrator” as used herein means a concentrator that focuses light without the focus maintaining an image of the object emitting the light. While for a telescope the image of an object is essential, an image is not essential for a solar energy receiver, and not having to maintain an image creates more freedom in concentrator design and allows for significantly higher concentration (over 80,000 suns has been achieved with a refractive non-imaging concentrator, and over 40,000 suns could be achieved with a perfect reflective non-imaging concentrator, versus a maximum of just over 10,000 suns for a perfect reflective imaging concentrator).

“Non-Imaging Secondary Concentrator” (also “Non-imaging Secondary Reflector” or “Non-Imaging Secondary”) as used herein means a non-imaging concentrator that increases the concentration of light already focused by a primary (typically imaging) mirror or lens.

“Normal angle” as used herein means the angle between a mirror's normal line and the direction of the sun, which is also the angle from the mirror's normal line to the sun's reflection from the mirror.

“Normal line” as used herein means a line normal (perpendicular) to a surface.

“A mirror's normal line” (also “The normal line of a mirror”) as used herein means a line normal (perpendicular) to the mirror's surface; at the center of the mirror if the mirror has a curved surface.

“Off-axis Aberration” (also “Coma Aberration”) as used herein means a spreading of the focus of a parabolic mirror when the incoming light is from a direction not parallel to the axis of symmetry of the parabola (or paraboloid).

“Open-Circuit Voltage” as used herein means the voltage that a photovoltaic cell produces at zero current.

“Optical Efficiency” as used herein means the percentage of light entering the aperture of a concentrator that reaches a receiver that that concentrator is focusing on.

“Optically Coupled” as used herein means that one substantially transparent object is optically joined to another object through a substantially transparent material whose index of refraction is such that light rays passing through the first object impinge upon the second object at angles where the vast majority of the light rays enter the second object.

“Panel” as used herein means a shaped reflective sheet, typically of mirrored glass adhered to a metal frame, that forms one segment of a segmented primary concentrator. Also called a “Reflective Panel”.

“Panel Frame” as used herein means a frame, typically of metal, that's shapes and/or support a reflective sheet in forming a panel.

“Parabola” as used herein means a conic section cut parallel to the side of a cone. A parabola is the ideal shape for an imaging concentrator for light parallel to the parabola's axis of symmetry. See “Conic Sections”.

“Parabolic Dish” as used herein means a shape whose cross-section on any plane parallel to an axis of symmetry is a parabola. A parabolic dish includes a “Paraboloid of Rotation”, in which a parabola is rotated around its axis of symmetry so that all cross sections containing the axis of symmetry are parabolas of equal focal length, as well as an “Elliptical Paraboloid”, where different cross sections containing the axis of symmetry have different focal lengths (called “elliptical” because a cross section perpendicular to the axis of symmetry is an ellipse).

“Parabolic Trough” (also “Paraboloid of Displacement” and “Paraboloid of Translation”) as used herein means a long straight trough whose cross-section perpendicular to the length of the trough is a parabola.

“Passive Cooling” as used herein means a system that uses no applied power other than the heat itself to move heat from a hot region (such as a solar cell) to a cold sink (such as the atmosphere). See “Heat Pipe” and “Active Cooling”.

“Photocurrent” as used herein means the current generated by a photovoltaic cell (which comes from the rate at which electrons liberated at a photovoltaic junction are collected and delivered to a photovoltaic cell contact).

“Photovoltaic” as used herein means using the energy of individual photons of light to liberate electrons from a semiconductor, and collecting those electrons to deliver them as electrical current.

“Photovoltaic Receiver” as used herein means a receiver for solar energy that uses photovoltaics as its primary means of producing electricity.

“PPM” (usually written as “ppm”) as used herein means parts per million.

“Pre-shaped” as used herein is meant an object whose shape does not change substantially when installed. For example, metal ribs and rails bent into substantially their installed shape before installation, and mirror segments bent into substantially their installed shape before installation, are referred to as pre-shaped.

“Primary Mirror” as used herein means the first focusing mirror that incident sunlight is reflected by in a system with multiple focusing elements in its light path. See also “Secondary Concentrator”.

“Quasi-Parabolic” as used herein means a shape that is approximately parabolic, but is deliberately slightly modified from a true parabolic shape.

“Rail” as used herein means a strut or tube, typically of steel, to which mirror segments are attached. When a frame comprises a lattice of crisscrossing struts, the struts to which the mirrors are attached are referred to as rails. See also “Dish Frame” and “Rib”.

“Ray Tracing” as used herein means the process of calculating the path of rays, typically of sunlight, as they are reflected of refracted by optical elements.

“Receiver” as used herein means a device with an energy-absorbing receiver surface onto which solar energy is focused, such as a densely packed array of photovoltaic cells, a single photovoltaic cell for a small-aperture mirror, or a maximally absorptive, minimally radiant surface for a solar thermal system. A receiver generally includes ancillary functions such as cooling for the receiver surface for photovoltaic receivers, the transfer of heat from the receiver surface to a working fluid for solar thermal receivers, or transport of reactants to and products from the focus for photochemical systems.

“Receiver Area” as used herein means the area of a receiver that is available to receive incoming focused light and productively use the energy therein.

“Receiver Support” as used herein means a means for supporting a receiver at or near the focus of a mirror. Receiver supports are generally engineered to block a minimal amount of light while holding the receiver firmly in position.

“Receiver Surface” as used herein means an energy absorber onto which solar energy is focused, such as a densely packed array of photovoltaic cells, a single photovoltaic cell for a small-aperture mirror, or a maximally absorptive, minimally radiant surface for a solar thermal system.

“Reflective Panel” as used herein means a shaped reflective sheet, typically of mirrored glass adhered to a metal frame, that forms one segment of a segmented primary concentrator. Also called a “Panel”.

“Refraction” as used herein refers to the change in angle of a light ray as it passes from one medium to another medium.

“Refractive Optical Element” as used herein refers to an optical element that uses refraction to guide the path of light passing through it.

“Refractive Final Optical Element” as used herein refers to a refractive optical element that is the last optical element that guides light before reaching the surface of a receiver, with that receiver surface typically comprising photovoltaic cells.

“Refractive ITP” as used herein means a shape for a final concentrating optical element such as is known for secondary concentrator in the art of sparse array Fresnel lens concentrating photovoltaic systems. See also “Spherical Dome”, “SILO”, and “Kohler”.

“Resistance” as used herein is generally meant the resistance to the flow of electrical current. When resistance to the flow of coolant is meant, this is explicitly stated; and when it refers to the flow of heat through a thermal conductor, this is explicitly referred to as thermal resistance to distinguish it from electrical resistance.

“Resistive Losses” as used herein means the loss of power through the voltage drop caused by electrical resistance. These losses are proportional to the resistance times the square of the electrical current.

“Rib” as used herein means a strut or tube, typically of steel, to which rails are attached (with the rails in turn holding mirror segments). See also “Dish Frame” and “Rail”.

“Rim Angle” as used herein means the angle of a mirror's surface at the rim (edge) of a mirror relative to the angle of the mirror's surface at the mirror's axis of symmetry. For a rectangular paraboloid mirror, the rim angle is measured in the middle of a side of the mirror, rather than at a corner, because the effects of curvature in each dimension are largely independent of the effects of curvature in other dimensions. A rectangular mirror thus has a different rim angle in each dimension.

“Scallops” as used herein means a series of crescent-shaped protrusions on an edge, like the edge of a scallop shell.

“Secondary Concentrator” as used herein means an entity that further concentrates and redirects light focused by a primary mirror or lens.

“Semi-Dense Receiver Array” as used herein means a receiver array where the photovoltaic cells of an array of cells are spread across an area at least twice as large as the total receptive area of the cells themselves, and at least ten times smaller than the overall primary aperture through which sunlight will be focused onto the cells. See also “Dense Receiver Array” and “Sparse Array”.

“Shingled” as used herein means an arrangement of photovoltaic cells such that a bottom edge of one cell overlies a top edge of an adjacent cell, somewhat similar to the way shingles on a roof overlap.

“SILO” as used herein means a shape for a final concentrating optical element such as is known for secondary concentrator in the art of sparse array Fresnel lens concentrating photovoltaic systems. See also “Spherical dome”, “Refractive ITP”, and “Kohler”.

“Solar Glass” as used herein means a very clear (low absorption, low dispersion) glass. Solar glass is very low in iron content, and is typically thinner than standard glass, usually between one and three millimeters thick.

“Solar Glass Mirror” as used herein means a second-surface mirror made with solar glass. Because solar glass is very clear and very smooth, a solar glass mirror has very high specular reflectivity.

“Solar Thermal” as used herein means a system that captures the sun's energy as heat, which is then typically put to productive use to generate steam to run a turbine to turn a generator to produce electricity.

“Sparse Array” as used herein means a receiver array where the photovoltaic cells of an array of cells are spread across at least one tenth as large as the overall primary aperture through which sunlight will be focused onto the cells. See also “Dense Receiver Array” and “Semi-dense Receiver Array”.

“Specular Reflectivity” as used herein means the percentage of incident light on a mirror that is reflected to within a fraction of a degree of an equal but opposite angle about the mirror's normal line. Specular reflectivity is usually measured out to 7 milliradians (about 0.4 degrees) from the equal-but-opposite angle. “Specular” is from the Latin word for mirror (speculum). Glass mirrors have very high specular reflectivity, but while snow has a very high reflectivity, that reflectivity is diffuse rather than specular and so one cannot see one's mirror image in snow.

“Spherical Dome” as used herein means a shape for a final concentrating optical element such as is known for secondary concentrator in the art of sparse array Fresnel lens concentrating photovoltaic systems. See also SILO, Refractive ITP, and Kohler.

“Spline” as used herein means the shape taken by a long, semi-rigid object when it is subject to bending force at discrete points. A spline is strongly dominated by a second-order curve, and it thus closely approximates a parabola where more than a few points on a parabola are used.

“String of Cells” (also “Cell String”) as used herein means a set of photovoltaic cells connected in series. While a string of cells adds cell voltages (rather than cell currents) and thus minimizes conductor sizes and resistive losses, the cells must either be evenly illuminated or have bypass diodes to prevent a less-illuminated cell from reducing the efficiency of the entire cell string.

“Substantially Parabolic” as used herein to describe shapes of supports for mirrors is to be understood to take into account that it is the reflective surface of a mirror that is to be most closely parabolically curved, and that a “substantially parabolic” rail or rib that supports such mirrors will be a curve that is an offset from a true parabola, with the amount of offset being substantially equal to the distance from the mirror surface to the relevant part of the rail or rib. When applied to a series of points, “substantially parabolic” means that the points all lie close to the same parabolic curve, and when applied to segments “substantially parabolic” means that a single parabolic curve can cross all segments at substantially the same location on each segment.

“Substrate” as used herein means a substance used as the foundation for building up one or more layers of other materials.

Sun Movement Expressions referring to the ‘Movement of the Sun’ as used herein are meant as referring to the apparent angular motion of the sun across the sky due to the daily rotation of the earth about its own polar axis and the yearly rotation of the earth around the sun.

“Suns” as used herein means the ratio of the intensity of focused sunlight to the intensity of direct sunlight, which is similar to geometric concentration but also includes losses such as shadows from supporting structures and mirrors not being perfectly reflective. See also “Concentration”.

“Thermal Coefficient of Expansion” (also “TCE”, “Coefficient of Thermal Expansion” and “CTE”) as used herein means the rate at which the size of an object changes due to changes in the object's temperature, usually measured in parts-per-million per degree Celsius (ppm/° C.). Differences in thermal expansion can cause thermal stress in materials especially when large regions of rigid materials with substantially different TCEs are bonded together at one temperature and then heated or cooled to a significantly different temperature.

“Thermal Expansion” as used herein means the change in size of an object due to changes in the object's temperature. See also “Thermal Coefficient of Expansion”.

“Top Contact” as used herein means an electrical contact on the top (receptive) surface of a photovoltaic cell that is connected to a bus-bar that serves as one of the cell's electrical contacts.

“Tracker” as used herein means a device that changes angle as the sun ‘moves’ so as to keep one or more mirrors or lenses on the tracker focused on one or more receivers.

“Triple junction Cell” as used herein means a photovoltaic cell that has three different junctions with three different band-gaps stacked on one another so that each can absorb photons of an energy that it can convert efficiently to electricity. Triple junction cells currently have a maximum efficiency of around 40%, which is much higher than that of silicon cells or thin film photovoltaics. On the other hand, triple junction cells currently cost 200 times more per area than silicon cells, and so require concentrated light to be economical.

“Two-Axis Tracker” as used herein means a tracker that tracks in two dimensions to compensate for the changing position of the sun. Two-axis trackers are generally azimuth/altitude trackers, where one tracking dimension corresponds to the compass direction of the sun and the other dimension corresponds to its height above the horizon. Daily/seasonal trackers and X/Y trackers also exist but are less common.

“Very High Concentration” as used herein means 500× to 1200×, ideal for high-efficiency triple junction cells. This is ideal for today's high-efficiency triple junction cells, and hence rates its own concentration terminology. See also “Low Concentration” and “High Concentration”.

“Wind Loading” as used herein means the forces applied to a structure by moderate to high winds.

### BRIEF DESCRIPTION OF THE DRAWINGS

FIG. 1A is an illustration of the prior art of using different types of reflective panels that are each true parabolic sections in one dimension of an overall parabolic dish;

FIG. 1B is an illustration of using identical reflective panels, that are also rotationally symmetric, throughout a segmented mirror that focuses to very high concentration;

FIG. 1C is a depiction of empirically determining the best cylindrical section for identical inner reflective panels and outer reflective panels for any given rim angle, focal length and mirror length by using ray tracing of the sun's rays;

FIG. 1D is an illustration of a frame for a reflective panel where the back of the frame acts as a mandrel for shaping another reflective panel;

FIG. 1E is an illustration of assembling a vertical stack of reflective panels where the back of the frame of one panel acts as a mandrel for shaping the mirror of the next reflective panel in the stack;

FIG. 1F is an illustration of protrusions, on the frame surface to which a mirror will be adhered, to prevent adhesive from being squeezed out;

FIG. 1G is an illustration of in the flanges of a frame that will serve as a mandrel for the mirror of the next panel in a stack of panels, where the protrusions and ridges are formed in a multi-step stamping process to provide greater accuracy;

FIG. 1H is an illustration of a panel frame that contains a built-in alignment guide for aligning the mirror of the next panel in a stack of panels to that mirror's frame;

FIG. 1I is an illustration of an alternative die that eliminates compression when stamping members of a panel frame;

FIG. 2A is an illustration of a quasi-parabolic rail for holding and aligning panels where the rail is modified from parabolic to even out the intensity of light on a receiver;

FIG. 2B is a detail view of the modified shape of the rib of FIG. 2A;

FIG. 2C is an illustration of the critical features of the rib of FIG. 2A;

FIG. 2D is an illustration of a jig for building accurate hybrid rib/rails for holding and aligning panels where the rib/rails require no precision cut pieces;

FIG. 2E is an illustration of a the critical areas of a jig for building accurate hybrid rib/rails where the rib/rails require no precision cut pieces;

FIG. 2F is an illustration of using the jig of FIG. 2D to build a rib;

FIG. 2G is an illustration of a modified rib that avoids requiring any rib components to be precision-cut and avoids the use of added materials in welding;

FIG. 2H is an illustration of a rib adapted to a central lattice box truss;

FIG. 3A is an illustration of gravity-return heat pipes for a dense receiver array where a secondary cooling fluid can flow around condensing sections of the heat pipes;

FIG. 3B is an illustration of a method of making mini-channel cooling tubes by stacking and bonding overlapping copper strips and then cutting the stack;

FIG. 3C is an illustration of a mini-channel cooling tube made by stacking and bonding overlapping copper strips and then cutting the stack, where the mini-channel tube is reinforced by being placed in an outer tube;

FIG. 3D is an illustration of a method of making mini-channel cooling tubes by stacking and bonding copper sheets and copper wire spacers;

FIG. 3E is an illustration of multi-inlet, multi-outlet mini-channel cooling tubes with contoured walls between inlets and outlets to ensure even fluid flow;

FIG. 3F is an illustration of a method of making multi-inlet, multi-outlet mini-channel cooling tubes with contoured walls by stacking and bonding copper sheets and contoured copper strip spacers;

FIG. 3G is an illustration of a dense receiver array cooling system that uses a thermally conductive but electrically insulation interposer between the cells and a single large cold plate made by stacking and bonding copper sheets and contoured copper strip spacers;

FIG. 3H is a cut-away illustration of the dense receiver array cooling system of FIG. 3G that shows the use of corrugated strip fins that reduce the force of thermal expansion mismatches;

FIG. 3I is a cut-away illustration of the dense receiver array cooling system of FIG. 3G that shows the use of slit-strip fins that reduce the force of thermal expansion mismatches;

FIG. 3J is an illustration of stacking wires and spacers to produce a block from which multiple cold-plate cores with minimal force from thermal expansion can be cut;

FIG. 4A is an illustration of a dense receiver array where cooling tubes are separated by insulating two-sided sticky tape, and where a strip of tape surface remains exposed to hold cells in place during assembly and soldering;

FIG. 4B is a depiction of placing cells on a dense receiver array where cooling tubes are separated by insulating two-sided sticky tape that holds cells in place during assembly and soldering;

FIG. 4C is an illustration of a dense receiver array where bars of a thermally conductive but electrically insulation interposer are separated by insulating tacky material where a strip of tacky material remains exposed to hold cells in place during assembly and soldering;

FIG. 4D is an illustration of a dense receiver array where bars of a thermally conductive but electrically insulation interposer have cells pre-soldered on them before being assembled into the array;

FIG. 4E is an illustration of a dense receiver array where thermal expansion and contraction are constrained by reinforcing plates of a material with an appropriate coefficient of thermal expansion;

FIG. 5A is an illustration of top contacts for a cell formed in a template and then transferred to the top of the cell;

FIG. 5B is an illustration of top contacts for a cell formed in a template within a final refractive optical element for the cell;

FIG. 5C is an illustration of side contacts for cells that allow cells to be place into series and/or in parallel with other cells by pressing the sides of the cells against each other;

FIG. 5D is an illustration of a corner of a cell that includes side contacts on all four sides that serve as bus bars for the cell's top contacts;

FIG. 5E is an illustration of a cell that includes insulating layers between side contacts and the cell body;

FIG. 5F is an illustration of a cell that includes insulating layers between side contacts and the cell body, where the insulating layer on one side provides compliance for that side's contact to maintain electrical contact with another cell's side contact even if the cells shrink upon cooling;

FIG. 5G is an illustration of a cell that includes a compliant contact on at least one side;

FIG. 5H is an illustration of side contacts deposited at the sides of streets where the wafer will be sawn into cells;

FIG. 5I is an illustration of a method for manufacturing compliant cell side contacts that uses a decomposable release layer to free a side contact from the surface it was deposited on so that it can flex for compliance;

FIG. 5J is an illustration of side contacts formed after multiple cells are place on an interposer;

FIG. 5K is an illustration of multiple interposers each with multiple cells packed into an array for forming side contacts in bulk;

FIG. 5L is an illustration of a cell with a reflective side contact;

FIG. 6A is an illustration of a semi-dense receiver array that uses far less area of moulded optics than sparse arrays and does not require an even focus;

FIG. 6B is an illustration of the increased space for improved cooling that the semi-dense array of FIG. 6A provides;

FIG. 6C is a schematic depiction of putting multiple rows of cells of a semi-dense receiver in parallel where the light is less than half as intense as in the center of the focus;

FIG. 6D is an illustration of using a semi-dense receiver array in conjunction with a secondary concentrator to make the system less sensitive to tracker misalignment;

FIG. 6E is an illustration of placing rows from the opposite ends of a receiver in parallel to further reduce the sensitivity to tracker misalignment;

FIG. 6F is an illustration of placing opposite-corner half-rows from the opposite ends of a receiver in parallel to further reduce the sensitivity to tracker misalignment;

FIG. 6G is an illustration of combining a monolithic semi-dense array with cell top contacts embedded in the array's final refractive optical elements;

FIG. 6H is an illustration of adapting a dense receiver array for an uneven focus by using cells of sizes that are inversely proportional to the focal intensity;

FIG. 6I is an illustration of adapting a dense receiver array for lower sensitivity to tracker misalignment by cross-coupling opposite-corner half-rows of cells;

FIG. 6J is an illustration of adapting a dense receiver array to cross-couple all cells in half-rows;

FIG. 7A is an illustration of deliberately slightly misaligning a tracker and its dishes relative to the sun to maximize the power output under partial shading;

FIG. 7B is a flow chart of a method for reducing tracker wear when deliberately slightly misaligning a tracker and its dishes relative to the sun to maximize the power output under partial shading;

FIG. 7B1 is a flow chart of a method for using voltage measurements from multiple groups of rows of cells to calculate a power-maximizing adjustment to make when deliberately slightly misaligning a tracker and its dishes relative to the sun to maximize the power output under partial shading;

FIG. 7C is an illustration of using the voltages produced by cell rows for fine tracking in one dimension;

FIG. 7D is an illustration of reducing the impact of differential shading of dishes on the same tracker by putting matching dishes on different trackers in series with each other;

FIG. 7E is an illustration of reducing the impact of differential shading of dishes on the same tracker by allowing independent fine altitude tracking of at least one dish;

FIG. 7F is an illustration of a fail-safe method for moving the receivers from the sun in the event of a coolant power failure;

FIG. 7G is an illustration of using the thermal mass of the base of a tracker to reduce temperature changes in the receiver;

FIG. 7H is an illustration of using a small inverter to supply AC tracking and cooling power to numerous trackers when the electricity transmission grid is down;

FIG. 7I is an illustration of a method for ensuring that that when the sun is low to the horizon, almost all light falls onto receivers whose concentrations are near their cells' peak efficiency concentration.

FIG. 8 is an illustration of using one or more of the preferred embodiments of the present invention to cost-effectively produce power in a sunny location, where that power is then transported to a distant location for powering electrical devices.

These figures are presented by way of example, and not by way of limitation, and unless otherwise specified in the accompanying text, the provision of a given number of items, or a given style of an item, is merely illustrative.

To allow easier understanding of the figures and the descriptions thereof, a figure reference number taxonomy has been used.

Figure labeling:

In labeling the figures, each family of related figures receives a figure number that is assigned sequentially. Figures in a family of figures are distinguished by a figure letter appended to the figure number.

Reference number for items within the figures:

Any item that is the same from figure to figure keeps the same reference number, as is required.

When a new item is introduced, it receives a new reference number. In assigning a reference number, the first digit of the reference number is the number of the figure in which the item is introduced.

Parts of an already referenced item receive an item number comprising the parent item's reference number with additional digits appended. An attempt has been made to have similar parts of different item have similar sets of digits appended, and when there are no similar parts, the additional digits to append are chosen sequentially starting with ‘1’.

When groups of an already-referenced item are referenced, the reference number for the group comprises reference number of the item with a zero (‘0’) appended. A zero is also appended for a reusable jig for making sets many of an item.

If a similar item has already been introduced in the same family of figures, the item has the figure letter of the figure in which it was introduced appended to the item's reference number after the reference number is chosen.

Primes are appended to reference numbers when several related items are introduced in the same figure, or an item is introduced into a figure that already has a similar but not identical item. For legibility, primes beyond three primes are represented by a lower-case Roman numeral superscript.

Subscripts are appended to reference numbers when two items introduced on the same page are substantially identical but must be referred to separately in the description.

To the extent that this taxonomy can be easily applied, the reference numbers for items in the figures are as follows:
*=Figure Family Number
*0 overall parabolic dish
*1 Reflective panels
*2 Focus
*3 Ribs
*4 Frame
*5 Cooling
*6 Cells and receiver
*7 Tracking
10 Parabolic dish
11 Reflective panels
110 Stack of panels
111 Reflective-panel frames
1111 Sleeves of reflective panel frames
11110 Die for forming sleeves
11111 Protrusions in sleeve surface to which the mirror will be adhered.
11112 Sleeve surface to which the back of mirror will be adhered.
11113 Sleeve flange which will serves as a mandrel
11114 Ridges the backs of mandrel flange.
11115 Sidewall of the sleeve.
11116 Built-in alignment guide to align and hold the next panel's mirror glass
112 Cylindrical section mirror
113 Cross braces
114 Adhesive
121 Panel focus
122 Gap for wind to flow through
20 Overall dish
21 Panels for discussing ribs
221 Panel focus
222 Gap/step for between panels
224 Secondary concentrator
23 Ribs
230 Rib jig
2301 Rib jig body
23011 Pins for mounting plate bolt holes
23012 Stops for end of mounting plate and for end of end plate
2302 Supports for angle irons on bottom face of rib
2303 Alignment pins for non-critical rib parts (not in jig body)
231 Rail
2311 Regions on rails where panels are attached to a rail.
232 Mounting plate
2321 Bolt holes
2322 End of mounting plate
233 Verticals
234 Angle iron pair (near rail)
2341 Individual angle irons 2341_{B} and 2341_{T} of pair near rail
2342 Tabs between angle iron pair near rail
235 Angle iron pair (far from rail)
2351 Individual angle irons 2351_{B} and 2351_{T} of pair far from rail
2352 Tab between angle iron pair far from rail
236 Diagonal braces
237 End plate
2372 End of end plate
2381 Gaps between plates and rail
24 Frame
241 Central truss
2411 Central region to be left panel-free due to shading.
2412 Stop for rib height on truss
24131 Truss-rail
24133 Truss-rail vertical
26 Receiver
351 Heat pipe, cooling tubes, cold plate
3511 Coolant channels
35111 Cusps in channel
35112 Scallops in channel
3512 Sheets, strips or fins of highly thermally conductive material to transfer heat to a fluid
35120 Stack of copper strips or sheets
3513 Spacers
35131 Wire of pair of wires in wire-pair spacer
35132 Milling depth marks for thinning faces
3514 Reinforcing strips and reinforcing tube
3515 Evaporative coolant
35151 Coolant level
3516 Dimples
3517 Hot face
352 Inlet
3520 Inlet manifold
353 Outlet
3530 Outlet manifold
361 Photovoltaic Cells
362 Low-CTE highly thermally conductive, electrically Insulating Interposer for cells
451 Cooling tubes
4514 Restraining plate
461 Photovoltaic Cells
462 Low-CTE highly thermally conductive plate
4620 Jig for placing and soldering cells on AlN bar
463 Tacky tape for holding cells in place
5251 Refractive final optical element
56 Dense receive array
561 Cells
5610 Wafer of cells
56101 Streets in wafer for sawing into cells
5611 Cell top contacts
56110 Template for top contacts
56111 Adhesive paste for attaching top contacts
56112 Optical coupling agent
5612 Bottom contact
56123 Exposed edge of bottom contact
5613 Contact on the side of the cell,
5614 Insulator behind side contact
562 Interposer for a row of cells
5620 Jig for block of interposers of cells
56201 Stop for interposer in jig
56202 Tooth to press interposer to stop
562020 Comb of teeth
5621 Top solder or adhesive from interposer side contact to top contacts of next row cells
5623 Contact on the side of interposer of cells
5624 Insulator on sides of interposer of cells
5625 Release layer on insulator on sides of interposer of cells
623 Focal spot after secondary concentration
624 Secondary Concentrator
625 Refractive final optical element array
6251 Refractive final optical element
651 Heat Spreader
66 Semi-dense receiver array
661 Cell of semi-dense receiver array
6611 Contacts formed in optical element
6610 Row of cells
66100 Array of cells
66102 Gap between rows of cells
70 Parabolic dish
700 Tracker
7000 Array of trackers
7001-3 Tracking algorithm steps
70003 Inverter
701 Axis of symmetry of dishes
702 Concrete tracker base
74 Receiver support leg controlling altitude
741 Actuator for moving receiver relative to dish
742 Failsafe spring for moving receiver relative to dish if power fails
751 Heater for receiver
7511 Coolant piping in concrete base
76 Receiver
7610 Row of cells
76100 Sets of row of cells

### DESCRIPTION OF THE PREFERRED EMBODIMENTS

### First Family of Preferred Embodiments

### Improvements to Methods for Making Pre-Shaped Reflective Panels for High-Concentration Solar Systems

Pre-shaped solar glass mirrors offer the highest specular reflectivity of any current cost-effective reflective surface, and also offer one of the most scratch-resistant surfaces and have the longest proven field life as well. However pre-shaped solar glass mirrors are currently too expensive. Pre-shaped glass parabolic trough segments are generally made by pressing flat mirrored glass sheets against an accurately curved parabolic mandrel while an adhesive bonding the glass to a sturdy backing material sets, or similarly pre-shaping a backing material and then bonding the glass to it (“Sandwich Construction Solar Structural Facets, Sandia National Labs 1999), or by slump-molding glass against an accurate mandrel. When the glass is thin enough and the curvature is slight enough, even compound curves can be formed in glass mirrors by cold pressing them in a mould while an adhesive sets (U.S. Pat. No. 7,550,054, Lasich), although in general heat-forming in a mould or heat-slumping against a mandrel is used for compound curves. All of these techniques require extensive time on an expensive mandrel, which limits production capacity from a given investment in tooling. There is thus a need for a more cost effective way to form reflective panels for high concentration and very high concentration solar systems. While multiple panels of glass sandwiched with adhesive to a constant-thickness backing could be stacked on top of a single mandrel, any imperfections in the thickness would add with every panel stacked onto the mandrel, quickly leading to unusable panels.

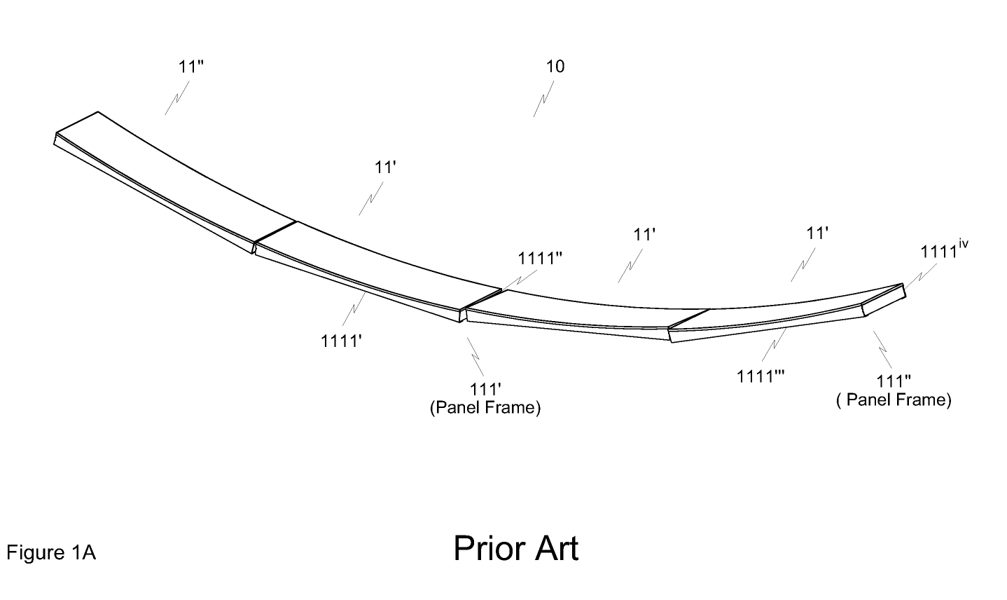

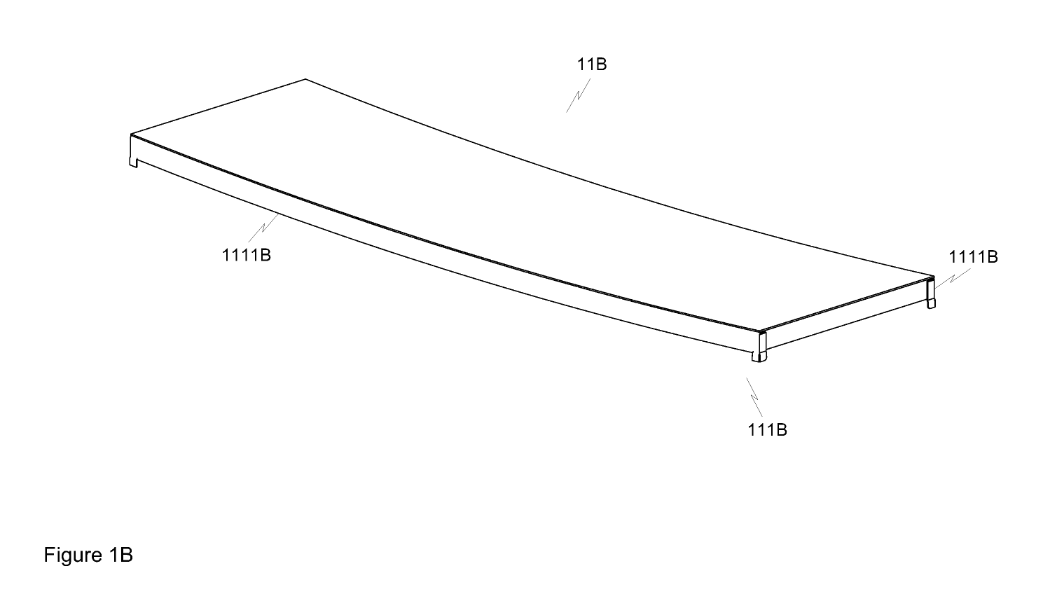

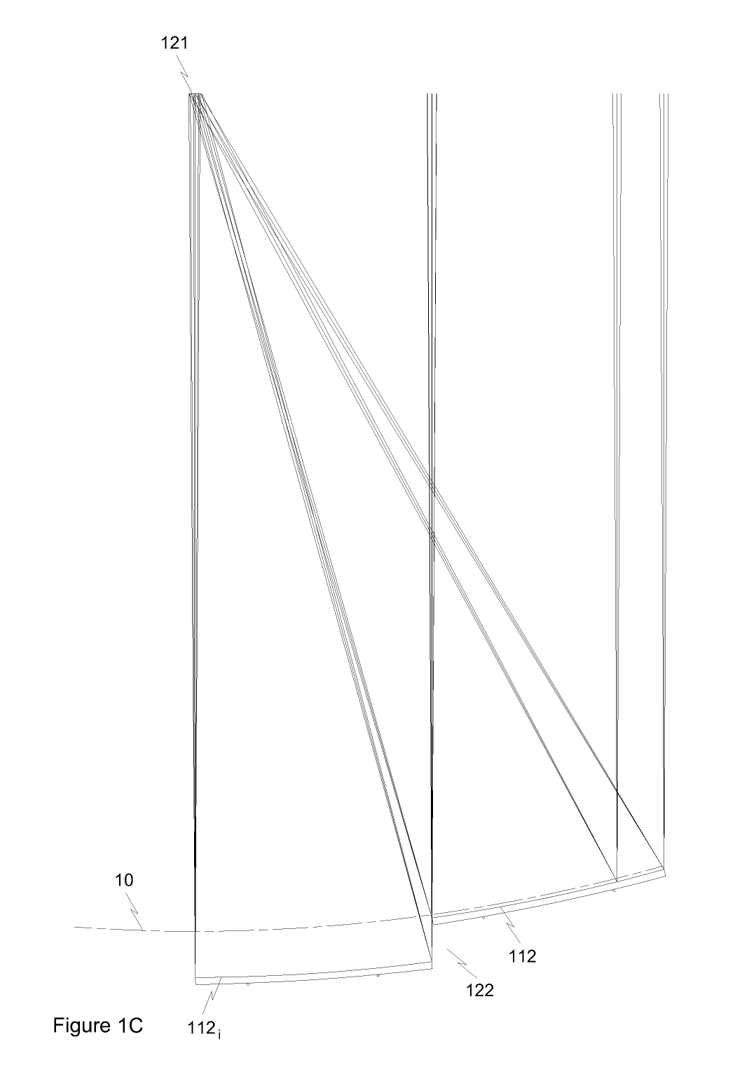

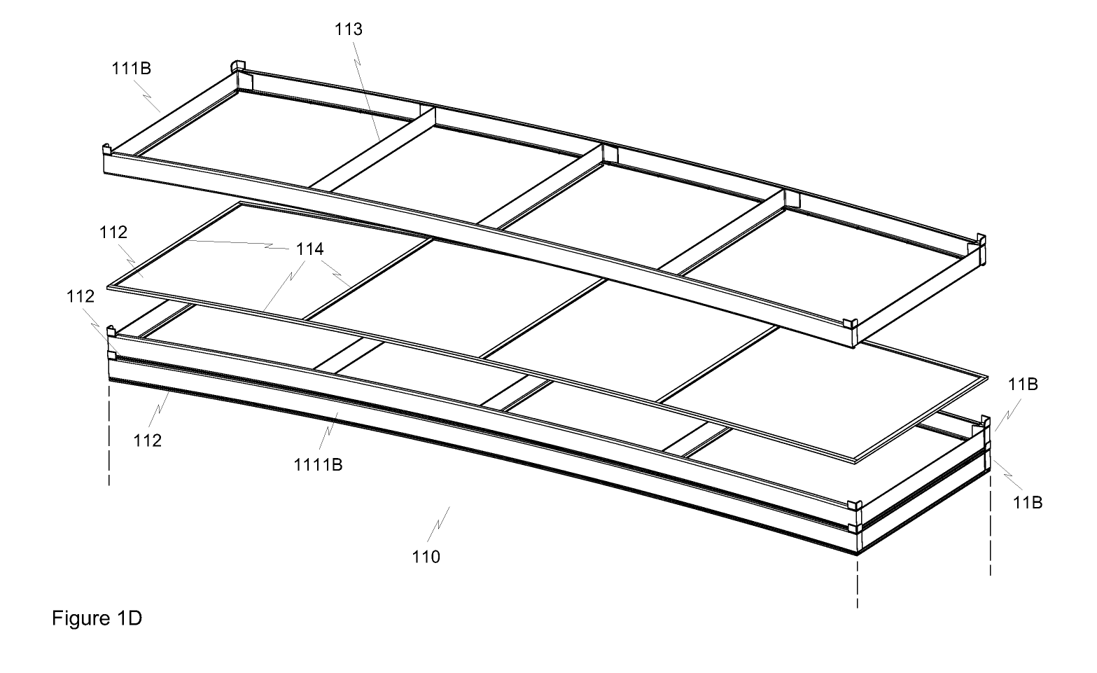

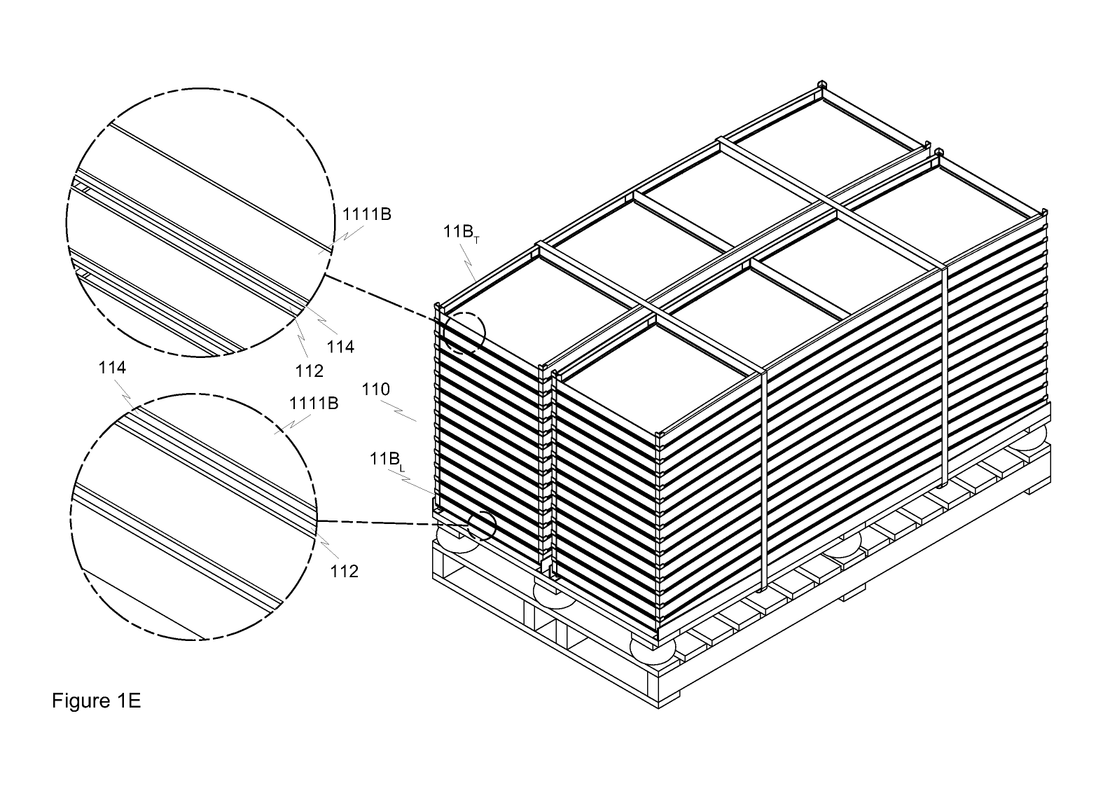

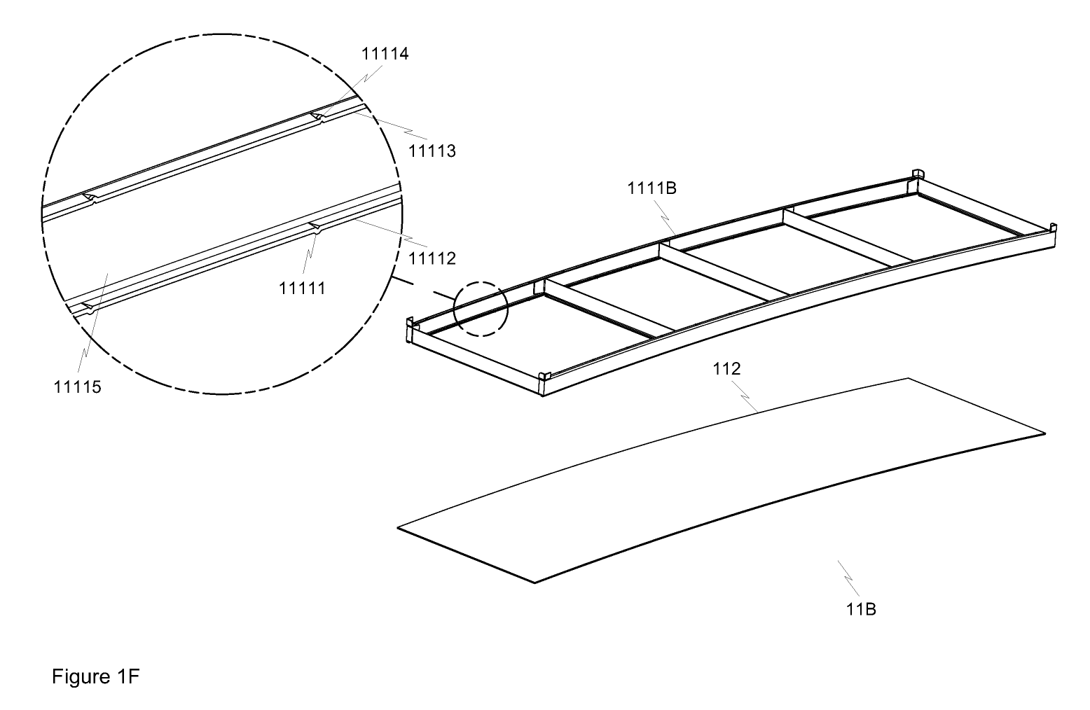

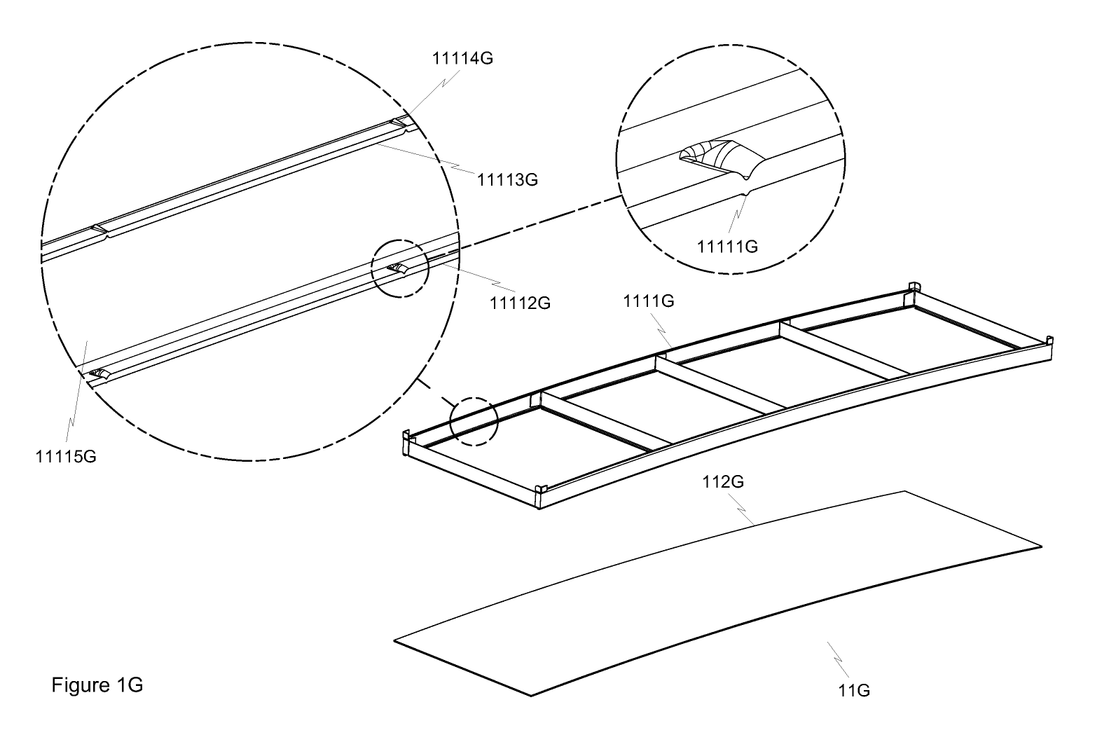

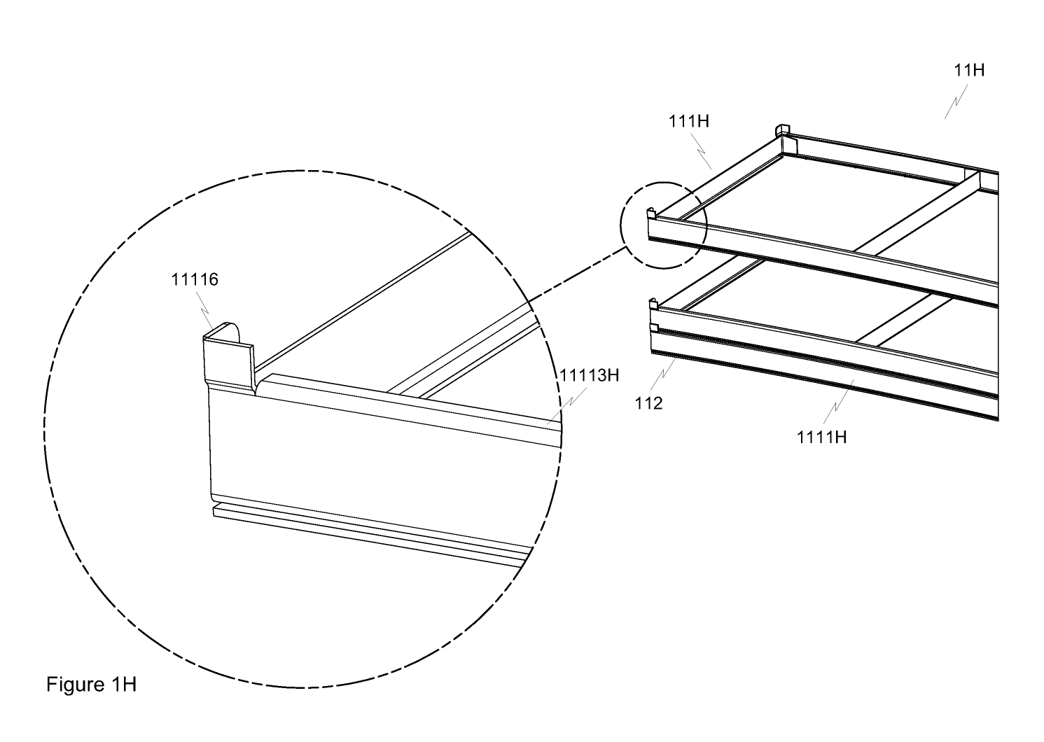

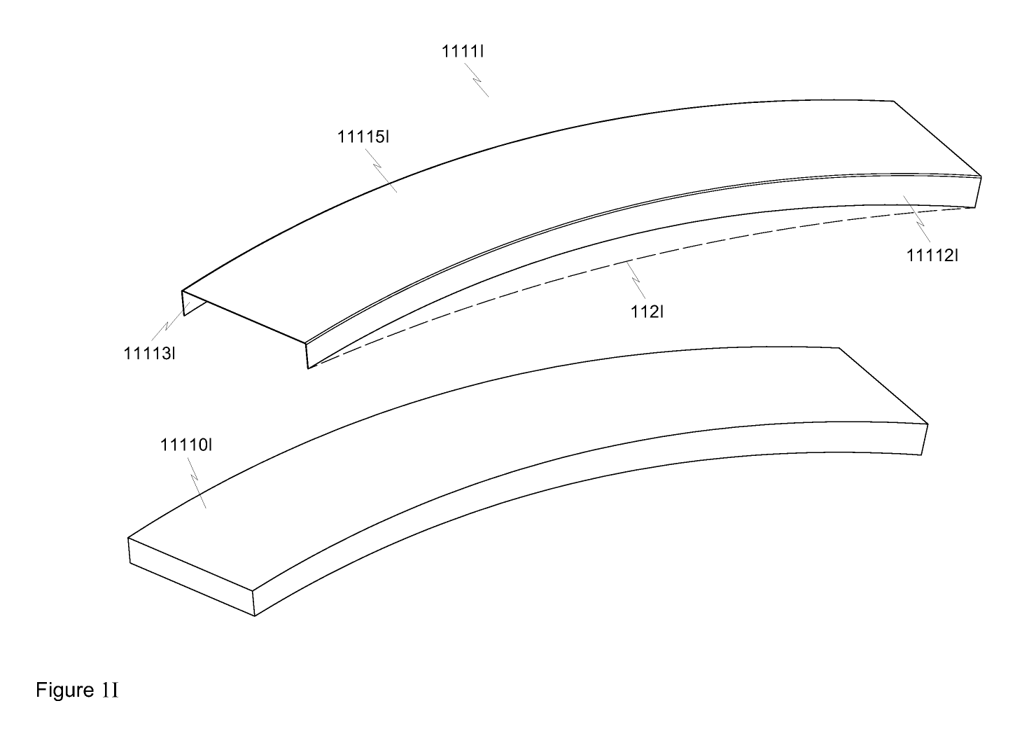

Norman teaches making a relatively low cost reflective panel for very high concentration solar systems without using a mandrel to shape the glass. However, as seen in Prior Art FIG. 1A, Norman maximizes the concentration by using inner reflective panels 11′ and outer reflective panels 11″ that are both true parabolic sections in one dimension of the overall parabolic shape 10. This creates several manufacturing and installation issues. During manufacturing two kinds of reflective panels 11′ and 11″ must be made, using two kinds of reflective panel frames, 111′ and 111″, that are made using four different side sleeves 1111′, 1111″, 1111″′ and 1111′ to shape the mirrors. This requires four times the tooling, and the parts 1111′, 1111″, 1111″′ and 1111^{iv} are similar enough that manufacturing mix-ups will occur. In installation there are two kinds of reflective panels, 11′ and 11″, and each end of each panel is different so the correct panels must be installed in the correct orientation, and again the panels and orientations are similar enough that mix-ups will occur.

However the lower the rim angle of the overall parabolic shape, the more similar the panels 11′ and 11″ and their sleeves 1111′, 1111″, 1111″′ and 1111iv become. A preferred embodiment of the present invention therefore uses panels of similar construction to Norman's, but uses an increased focal length of the overall mirror and thus a decreased rim angle. This allows the inner and outer panels to be made as identical panels, and, as seen in FIG. 1B, this allows the resulting panel 11B to have symmetry such that the panel's frame 111B can use two identical sleeves 1111B (and during installation the ends of panel 11B are identical), at an acceptable impact on the concentration. In an especially preferred embodiment, the rim angle is on the order of 15 degrees so that the focal length is not excessively long yet there is only around a 10% focus-broadening penalty for identical inner and outer panels 11B made with identical symmetric frames 111B that are in turn made with identical side sleeves 1111B.

While it is empirically possible to derive an ideal symmetrical shape for the panel 11B for any given focal length, mirror length and rim angle, the improvement over the best cylindrical section (one class of symmetrical shapes) is so minute as to not be worthwhile. As can be seen in FIG. 1C, the best cylindrical section for any given rim angle, focal length and mirror length can be found empirically by ray-tracing on a cylindrical section mirror 112 positioned as an outer mirror and adjusting the curvature until the panel focus 121 is as tight as possible. Shown are the rays from the center and each edge of the sun's disk impinging on points on the arc of cylindrical section mirror 112 that the race tracing reveals to be key points in how tightly cylindrical section mirror 112 can focus. For clarity other rays of the ray tracing that impinge on mirror 112 are not shown.

Once the optimum curvature of a cylindrical section for this outer mirror 112 is determined, an identical cylindrical section mirror 112ᵢ is positioned as an inner mirror on the overall parabolic shape 10, and is then pushed farther and farther from the overall focus until the focus of that inner mirror 112ᵢ is as tight as the focus from the outer mirror shape 112. The inner mirror 112ᵢ can be pushed even farther from the focus than this, slightly tightening its focus but not tightening the overall panel focus 121, until a distance is reached where its focus broadens again and then becomes broader than the focus from the outer mirror 112. Any distance within this range can be picked without broadening the overall panel focus 121, so the distance can be picked for mechanical reasons (e.g., lowering the center of gravity or center of wind loading, or providing a larger gap 122 for wind to flow through). Using a single type of rotationally symmetric mirror reduces the tooling cost and the manufacturing and assembly complexity, at a very acceptable cost in broadening the focus, as 1000 suns can still be reached in a dish of optimal size. It should be noted that mirrors 112 and 112i are identical, and the subscript ‘i’ is just used for identification during the above discussion.

Norman also teaches holding the glass mirror to a shaped panel frame with metal trim, thus avoiding the need for a mandrel. But such trim blocks a small but noticeable portion of the mirror surface and requires securing the trim after the mirror is in place. While the glass mirror could be fastened to a backing material with adhesive and no trim, as taught in (“Sandwich Construction Solar Structural Facets” and “Further Analysis of Accelerated Exposure Testing of Thin-Glass Mirror Matrix”, NREL 2007) holding the mirror in place while an adhesive sets would tie up an expensive mandrel and the backing takes more material than a frame does.

However as shown in FIG. 1D, by shaping the back of the frame 111B for one reflective panel 11B to match the desired curve for the front of the glass mirror 112 of the panels 11B, the back of each frame 111B can serve as a mandrel for the next mirror 112, allowing the reflective panels 11B to be built by assembling their components into a vertical stack 110 of panels 11B. To ensure that any excess adhesive 114 drips harmlessly onto a back of a mirror 112 rather than onto a front, the stack 110 of panels 11B is preferably assembled with the panels 11B upside-down (mirrors 112 face down). Since the adhesive 114 goes on the back of the mirror glass 112, the mirror glass 112 will come out of an adhesive application machine in this orientation anyway, so this also simplifies handling during assembly. (While panels 11B could be assembled on their sides and pressed together with even pressure, assembling the panels 11B in a vertical stack gives less chance for excess adhesive 114 to get on the mirror surfaces, and gravity tends to hold the parts in place rather than trying to shift them). A number of braces 113 can be clinched to panel sleeves 1111B to give the frame strength. Preferably braces 113 are used at least at the ends of the panel frame and where the panel frame will be attached to a rail of an overall primary concentrator frame. The optimal number of braces 113 depends also on the glass thickness, as thinner glass can be used if more braces are provided since each brace 113 provides support for the mirror glass 112 and adhesive 114 between braces 113 and the mirror glass will help cushion the mirror glass 112 again insults such as hail.

But as shown in FIG. 1E in stack 110 the lowest panel 11BL bears the weight of the entire stack 110, which tries to squeeze the adhesive 114 out more than for the top panel 11BT of the stack. Because the adhesive 114 needs a significant thickness to prevent the thermal expansion difference of the glass 112 and its frame 11B from changing the focal length with temperature (even for highly elastic silicone, on the order of one millimeter of thickness for two-meter-long aluminum-and-glass panels, and on the order of ⅓ of a millimeter for galvanized-steel-and-glass panels), squeezing out too much adhesive 114 from the bottom panel 11BL would be unacceptable. It should be noted that panels 11BL and 11BT are of identical construction and are intended to be identical, and any difference produced by the increase pressure on 11BL is to be minimized or eliminated.

While wires of the right diameter or other discrete spacers could be used, as seen in FIG. 1F, which includes a close-up of one of the sleeves 1111B for mirror sleeves 1111B, protrusions 11111 can be formed in sleeve surface 11112 by stamping bumps of the proper height periodically along sleeve surface 11112 during the sleeve stamping process. For glass of about 3 mm (⅛″) thick, a protrusion 11111 roughly every 10 to 15 centimeters (4 inches to 6 inches) is sufficient. Thinner glass requires more closely spaced protrusions so that the glass does not bend excessively between protrusions. When flanges 11112 have little distortion, the protrusions are preferably wedge shaped with their highest points on the flange away from the sidewall 11115 to simplify one-step stamping.

Stamping the frame's sleeves 1111B from flat sheets of metal on a flat die is inexpensive, but while the concave flange 11112 to which the glass will adhere is stretched slightly, which smoothes out distortions, the opposite flange, which is to serve as a mandrel, is compressed slightly during the stamping onto a flat die. For a one centimeter wide flange on the back of a sleeve 1111B for a panel 11B that spans ¼ of a dish 10′ with a 15-degree rim angle, this compression is only about one part per thousand, but thin materials buckle under compression. Unless the sleeve material is thick this induces noticeable distortions in the flange (and thick material would add cost). Further preferred embodiments of the present invention therefore include outward-facing (toward the next panel's mirror 112 that the flange 11113 will act as a mandrel for) ridges 11114 in the mandrel flanges 11113 of the sleeves 1111B. The extra length of going up and down the ridge relieves the compressive stress accumulated in the material of mandrel flange 11113. The more numerous these ridges 11114 are, the smoother the mandrel-flange 11113's surface will be. The height at the outer edge of the ridge can be quite small; in even 15 centimeters one part per thousand is only 0.15 mm, so a ridge 11114 every 15 centimeters, with 60 degree sides that is 0.15 mm high at the outer edge of the flange 11113, is sufficient for a sleeve 1111B for a panel 11B that spans ¼ of a dish 10′ with a 15-degree rim angle. In especially preferred embodiments there is one such ridge 11114 opposite each protrusion 11111 on the opposite (adhesive) face of the sleeve.

The edge of the flange near a sidewall has greater accuracy than the outer edge of a flange, so greater sleeve accuracy (and thus panel accuracy) can be obtained by a multi-step stamping process in which the rough sleeve shape is formed first and the protrusions are formed second, preferably with cams in the mandrel that push the protrusions into mating cavities in the stamping die and then retract to allow the sleeve to be removed from the mandrel. As shown in FIG. 1G, a multi-step stamping processes allows the protrusions 11111G in flange 11112G and ridges 11114G in flange 11113G to be at the flange edges near the sleeve sidewall 11115G, which is more accurate because near the sidewall the flange is less affected by waviness or inaccurate folding of the flange. The height of ridges 11114G at the inner edge should be at least as high as any residual waviness to ensure that it is the ridge 11114G that presses on the glass of the next panel in the stack. The height of the protrusions 11111G can be the same as protrusions 11111, but the higher edge is near the sidewall 11115G.

With either panels 11B or 11G, the weight of panels in a stack of panels will bear down on the protrusions rather than on the semi-fluid adhesive, thus tending to hold the stack components in place, but the mirror glass for each panel must still be aligned to its frame to start with. As shown in more detail in FIG. 1H, in even further preferred embodiments the sleeves 1111H (which may, for example, be the same as 1111B or 1111G) are made a bit longer than the mirror glass 112 and at the very ends of the sleeves the material is not stamped into mandrel flange 11113H. Instead these ends of the sleeves 1111H are bent as part of the stamping process to form built-in alignment guides 11116 to align and hold the next panel's mirror glass 112 and then align and hold the next panel's frame 111B, thus greatly simplifying assembly.

In especially preferred embodiments the slant of the sides of this guide 11116 is chosen so that when the panels 11H are installed on a substantially parabolic dish in the field, the outer corner of the guide 11116 of one panel just touches the neighboring panel's guides 11116 or frame 111H rather than the glass of one panel touching the glass of the next panel, protecting the more fragile mirror glass 112 during installation and during high winds. In exemplary embodiments such guides are combined with the increased-accuracy sleeves 1111G.

As shown in FIG. 1I, alternative preferred embodiments use a die 11110I that is not flat but whose surface is curved to the same radius as the desired curvature of mandrel flange, and accept that the resulting mandrel flanges 11112I and 11113I will bend the sleeve sidewall 11115I as well as the flanges themselves bending. To help visualize the resulting curve in two directions of the sleeve 1111I, a dashed line 112I shows where the edge of the mirror glass will lie, which curves only one direction (for clarity, only the position of the edge of the mirror glass is shown).

However while this double curve eliminates the distortion in the flange 11113I, the resulting sidewall 11115I curves relative to the edge 112I of the mirror glass. Preferably the sidewall curves inward as shown relative to the glass edge inward as this allows the sidewalls to protect the corners and serve as alignment guides (not shown) as taught above. However, the curve causes the distance between the sleeve sidewalls 11115I in a panel frame to not be constant, which slightly complicates the panel frame because the cross braces cannot all be the same length. Since the stamping die 11110I and the corresponding stamping cavity are also more expensive, this alternative is generally less preferred than the previously taught ridges 11114 in the mandrel flange 11113.

### Second Family of Preferred Embodiments

### Improvements in Frames for Large-Tracker Solar Energy Systems with One or a Few Foci Per Tracker

Norman teaches a low-cost parabolic frame embodying hybrid ribs with integrated rails, and teaches using a reflective secondary concentrator to even out in one direction the focus from using mirrors curved in only the other direction, but Norman's focus is still not even enough to completely eliminate the need for bypass diodes with the current/voltage tradeoff of today's solar cells. The innermost mirrors along a rail normally concentrate their light onto the center of the receiver, contributing significantly to the unevenness of the focus. While Norman teaches increasing the overall geometric concentration slightly by slanting these mirrors so that their light reaches the very edge of the secondary concentrator, thus forming the rail into a concentration-maximizing compound parabolic curve, the light reflected from the secondary would spread across the whole receiver rather than falling mostly near the edge of the receiver where Norman's intensity is weakest. Lowering the rim angle of the primary mirrors and obtaining more concentration from the secondary concentrator also helps to even the focus, but even that is not sufficient to make every row of cells productive (and eliminate the need for bypass diodes for uneven focus) unless the focal length is too long to be practical.

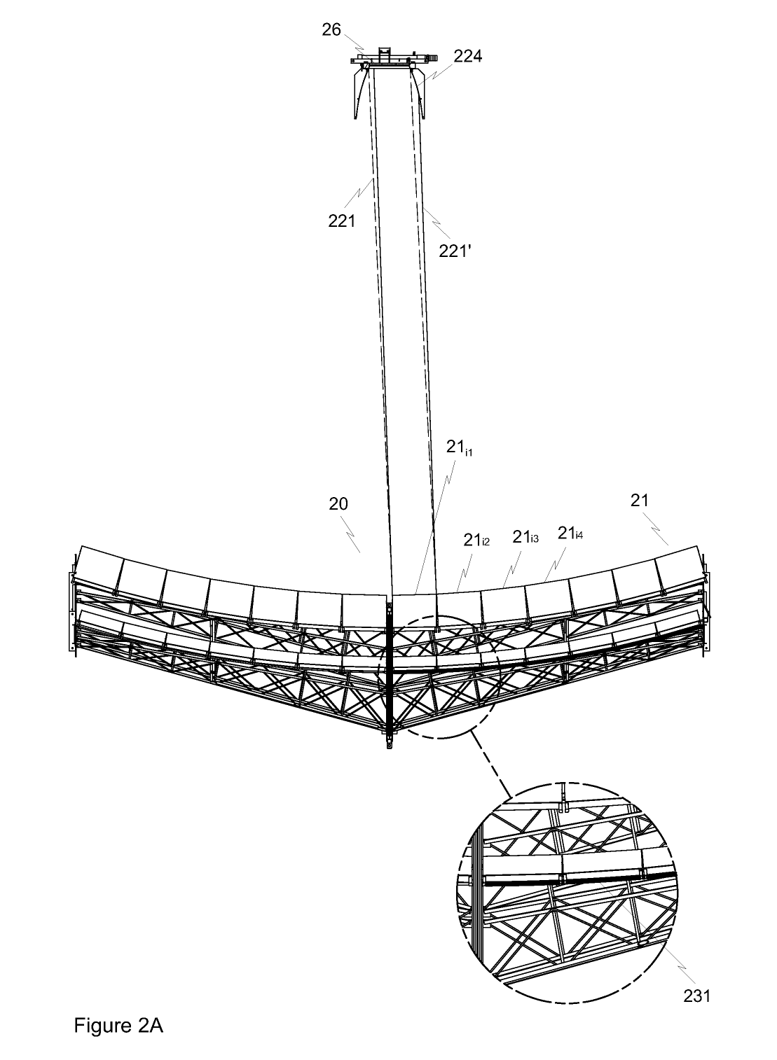

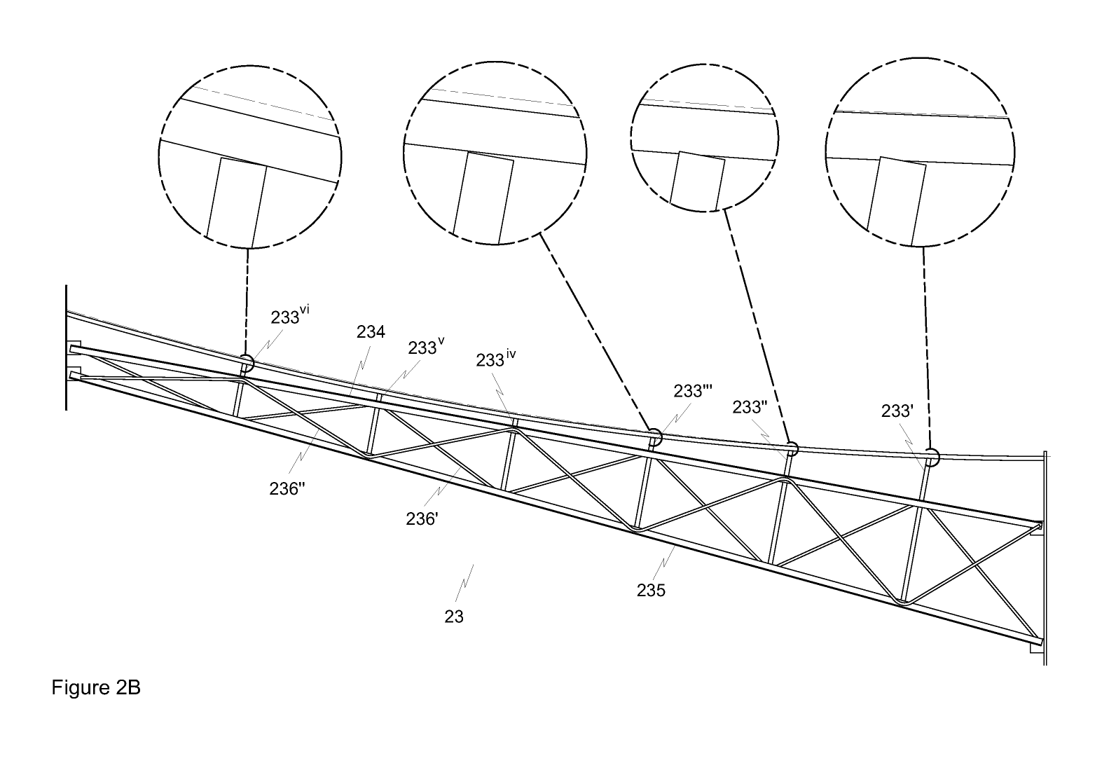

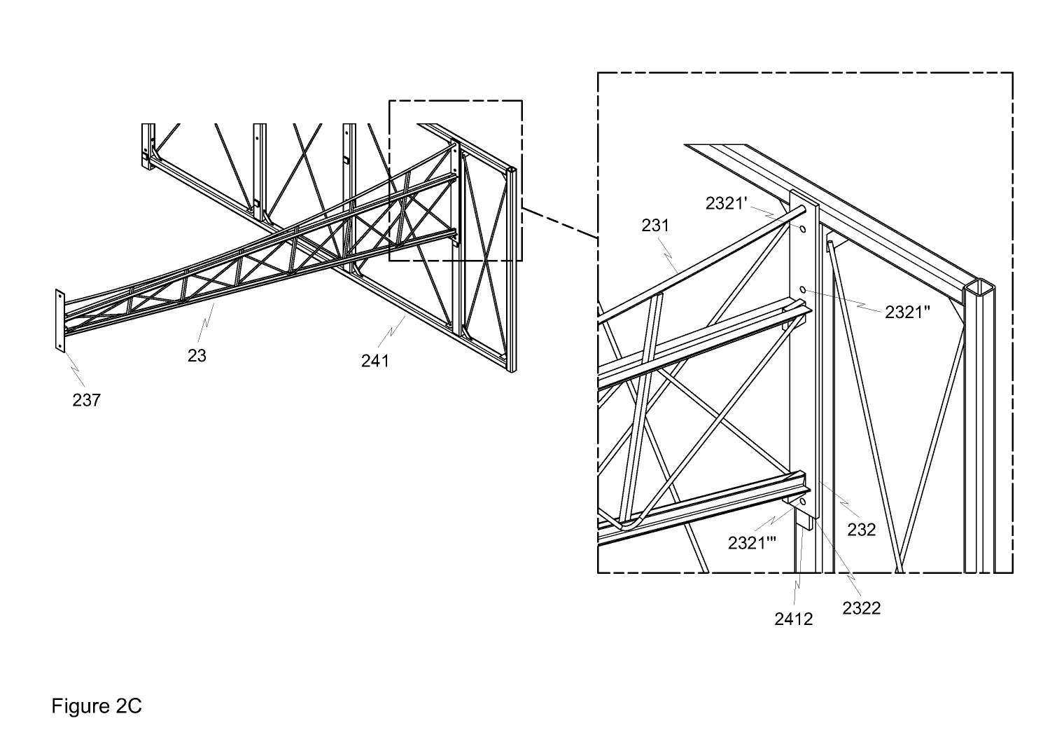

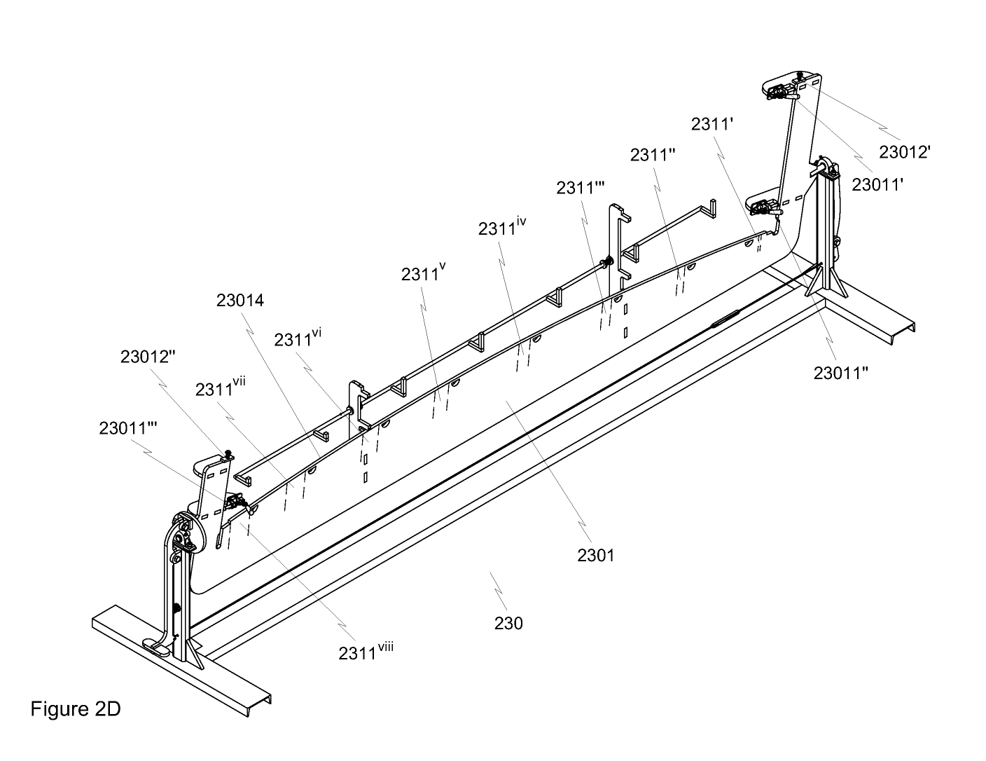

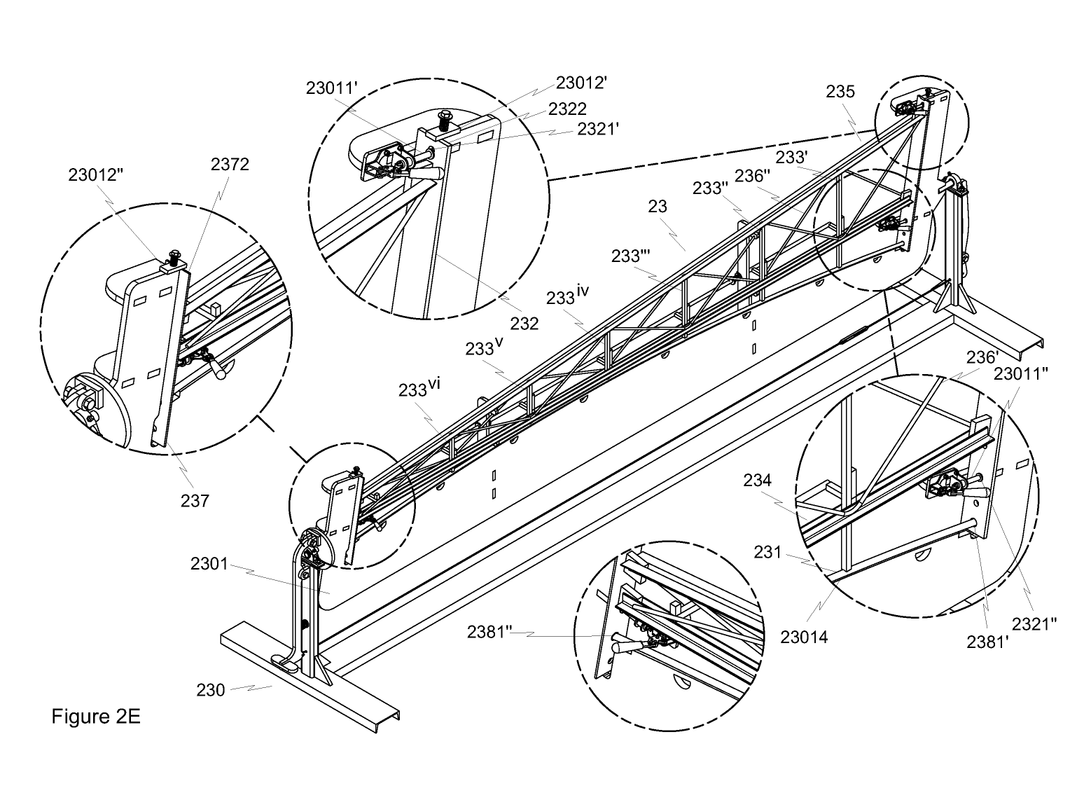

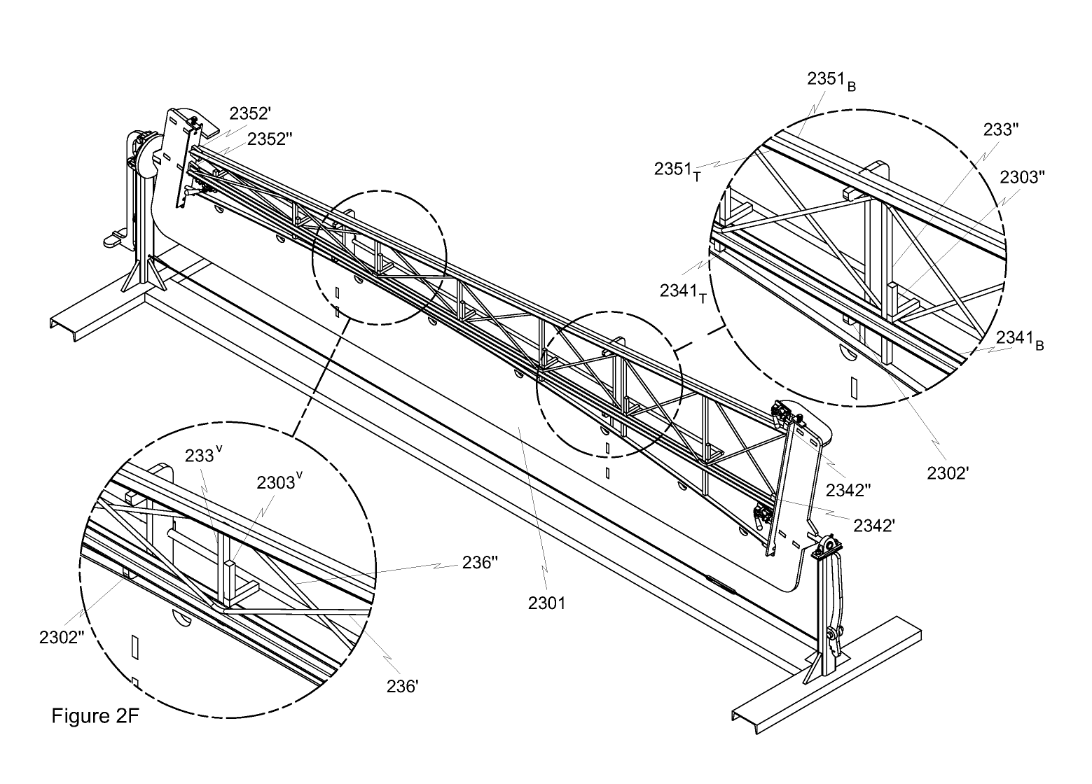

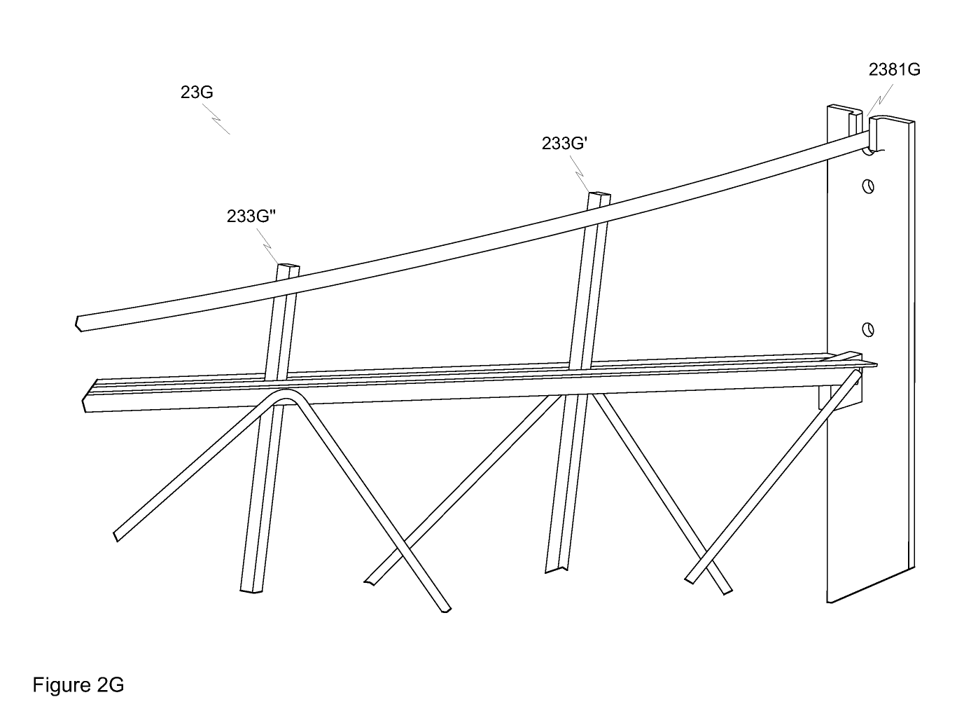

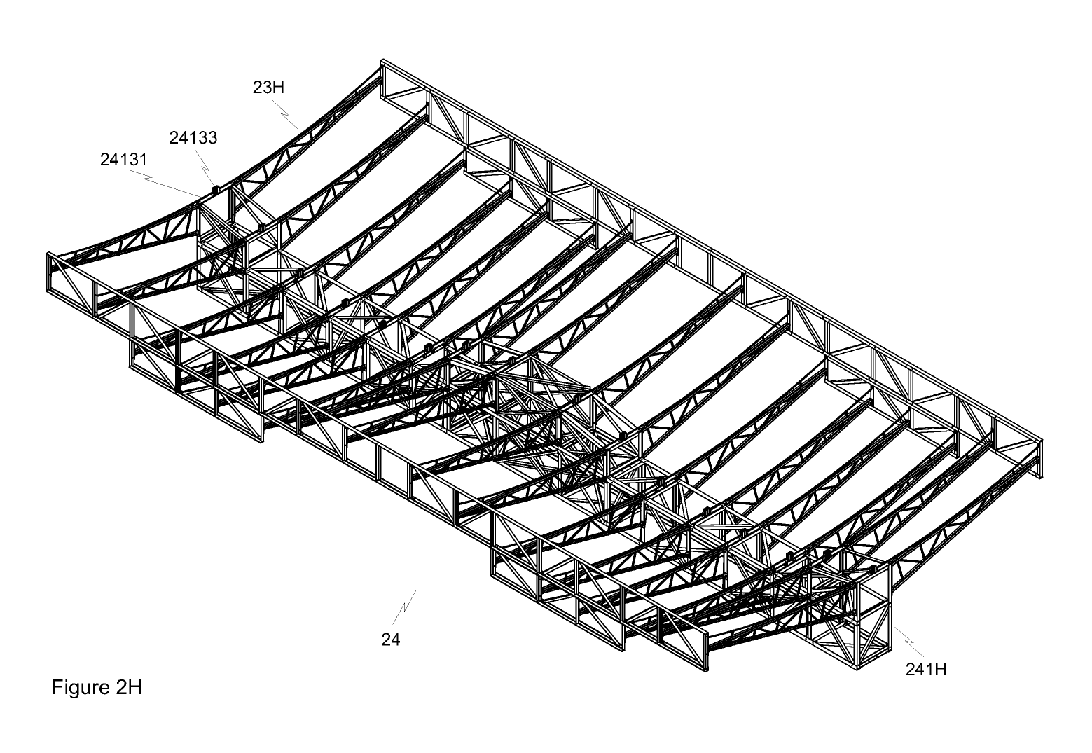

As shown in FIG. 2A (and in more detail in FIG. 2B), a preferred embodiment of the present invention therefore slightly lowers the curve of rails 231 for one or more of the innermost panels 21 along the rails 231 to shift those panels' foci both onto the edge of the receiver 26 onto the near part of the secondary concentrator 224 where it will be reflected near the edge of the receiver 26, thus adding light where the intensity had been weakest. Identical panels 21 are labeled 21ᵢ₁ for the innermost, followed by 21ᵢ₂, 21ᵢ₃, and 21ᵢ₄, for clarity in the discussion, and for clarity in the figure, only for panel 21ᵢ₁ is the shift shown, from the original centered focus 221 of panel 21ᵢ₁ to the panel's shifted focus 221′ (a given panel only focuses in the direction that it is curved, which perpendicular to the width of the panel and hence does not show in this view). Combined with lowering the rim angle of the overall dish 20, this lowering of the rail to shift the light can even out the final focus 223 sufficiently to avoid the need for bypass diodes for focal intensity variations in a properly designed receiver placed at the final focus 223.

It will be appreciated that the width of the primary reflector panels 21 gets divided by the cosine of twice the rim angle in that direction as light is reflected on the receiver. In the case of panels being 508 mm wide, this increased them by about 15% to 585 mm. Then the sun's diameter increases the width by about 1% of the farthest distance from mirror to receiver, which in our case adds another 83 mm, for 668 mm. Then a 60 mm tolerance budget yields a 728 mm wide focus. But the curved secondary 224 then sharpens this focus to 460 mm, which is approximately the width of the primary reflector. It would be hard to go below about ¾ of the width of the mirrors, and sub-optimal to be about twice the width of the mirrors (or above 1.3× to 1.5× for an even focus (as opposed to proportional cells or final optical element apertures).

In the example shown in FIG. 2A, in a 16.5-degree rim angle dish 20 with seven reflective panels 21 widthwise spanning each side of the dish 20, and a 95% reflective compound-parabolic-curve secondary concentrator 224, the inner panels 21ᵢ₁, 21ᵢ₂, 21ᵢ₃, and 21ᵢ₄ on each pair of rails 231 are slanted so that their foci are shifted off-center, and more onto the near end of the receiver and onto the secondary concentrator near the near end of the receiver, by 5, 20, 25 and 12 millimeters respectively to achieve a focal unevenness of less than 3%. Given the receiver being very close to 12 panel-widths away from lower part of the secondary concentrator, this requires lowering the rail where the outer edges of the four panels will attach to the rail by 0, 5/12=0.42 mm, (5+20)/12=2.1 mm, (5+20+25)/12=4.2 mm respectively, and all regions further out on the rail where panels will attach by (5+20+25+12)/12=5.2 mm, from the true parabolic curve shown by the dashed line. As shown in FIG. 2B, this can be achieved simply by having the verticals 233′, 233″, 233′″, 233^{v}, 233^{vi}, and 233^{vii} meet the modified curve of the rail, and by adjusting the height at which the rail meets the end plate. (While each panel is supported on the rails of two ribs, for clarity only one rib 23 is shown in FIG. 2B).

Norman also teaches minimizing the rim angle to maximize the concentration by shifting the foci of inner mirror segments to the edge of the secondary concentrator far from the receiver. But that is a much bigger shift than is needed to even out the focus, and light reflected from the edge of the secondary concentrator far from the receiver gets redirected toward the middle of the receiver, thus adding to the unevenness rather than correcting it.

It is also possible to raise the curve of the rails to push the light from one or more mirror segments on each rail onto the far end of the focus and onto the secondary concentrator near the far end of the receiver. This has an effect similar to lowering the rail, except the greater angle of the secondary near the far end of the receiver spreads the light out farther from the edge of the receiver. While the light increase is at the far end of the receiver rather than the near end, the use of substantially identical rails and mirror segments on the far side of a central truss will, by symmetry, provide a corresponding broader increase on the near end of the receiver.

Slanting inner mirror segments to shift light to the near end and the far end of the receiver can be used cooperatively by slanting some inner segments on a rail toward the near end where the increase of light in a narrower region near the end of the receiver is desired, and slanting some inner segments on the rail toward the far end. For any given design, the optimal shifting of the foci of these innermost reflective panels can be determined empirically to any level of accuracy desired by using a ray-tracing program. For a dense receiver array with rows-of-cells in series in the direction the light will be shifted, the intensity only has to be even in this one dimension. Optimizing the pattern of shifts can be done faster by first finding the optimum for ray tracing in two dimensions onto a one-dimensional receiver. Because the ribs and panels are all substantially identical, this differs only slightly from the full optimization of three-dimensional ray tracing onto a two-dimensional receiver surface (the biggest difference is that the sun is not a point but has an angular diameter of around half a degree, so the sun's rays spread slightly more from the mirrors that are farther in the direction of the row of cells themselves).

Ray tracing in one direction is very fast both because the calculations for each ray are simple and because far fewer rays are needed (hundreds for a reasonable approximation instead of tens of thousands). The sun can also be treated as a point for an initial coarse optimization. The range of potentially beneficial shifts of the focus for each mirror is also limited by the amount that its focus can be shifted before its focus goes farther out on a secondary concentrator than the focus from the outer most mirror segment, which would start decreasing the system's acceptance angle). Dividing the range for each mirror by a convenient shift increment (for example, five millimeters) produces a modest number of potential shifts even for the innermost mirror (on the order of ten choices for the example of a 16.5-degree rim angle dish with a six-meter focus, where the dish is spanned by the widths of seven reflective panels curved only in the opposite direction), and fewer choices for each mirror father out along the rib. With a manageable set of simple ray traces to perform, a modern computer can simply try a ray trace of a few hundred rays evenly distributed across the one-dimensional ‘dish’ for every combination of shift, and find the best few patterns of shifts in seconds.

The range of shifts around these best patterns can then be explored with a smaller shift increment (for example, two millimeters). This produces an even smaller number of candidate shift pattern, so the sun's diameter can be included (with, for example, ten rays at each position whose initial angles are spread across the sun's diameter), and a computer can simply try a ray trace of a few thousand rays for each candidate shift combination. Again the best few patterns of shifts for a given dish will emerge in seconds.

At this point in the optimization process the higher accuracy of a three-dimensional ray trace is needed. With the range of shifts in which to search for the optimum greatly narrowed down, numerous other factors can be included without introducing excessive computational demands. Such factors include the reflectance of the mirrors and absorption of the receiver itself as a function of angle of incidence of a light ray and even as a function of wavelength of the light ray, and these can also be used to maximize the receiver's efficiency within an acceptable range of evenness of focus (the evenness required depends on the cells' ability to trade voltage for current to maintain current under lower illumination, and this differs from cell to cell with typically a few percent variation in intensity being acceptable). If the manufacturing tolerance of the system and/or the tracker tolerance are known, these can even be included in the optimization to produce a focus whose evenness is robust to minor manufacturing and tracker alignment errors (additional ways of achieving such robustness will be discussed later in the present application).

Norman also teaches a variety of hybrid ribs with integrated rails and teaches that such ribs can be made with a jig that ensures accuracy of the critical features, which, as shown in FIG. 2C, are the curve of the rail 231 at the top of the hybrid rib 23, and its position and angle relative to the end 2322 of the mounting plate 232 which will set the height of the rib 23 and thus the rail 231 when the rib is mounted on a truss 241 that has a stop 2412. The accuracy of end plate 237 is also of some importance as it allows an end truss to provide better leverage in ensuring that ribs deflect together under wind loads.

A suitable jig 230 is first shown separately in FIG. 2D for clarity (FIG. 2D will be described in detail shortly), and its use in building a rib in accordance with a preferred embodiment of the present invention is shown in FIG. 2E.

A preferred method of using the jig is as follows: First, the parts for a rib are cut in large quantities. None of the pieces need precise lengths, allowing the pieces to be cut in bundles with ordinary equipment. Next, as shown in FIG. 2E, the mounting plate 232 has bolt holes 2321′ and 2321″ punched or drilled in it. These are positioned relative to the end 2322 of the mounting plate 232, and do not need high precision (because, as was seen in FIG. 2C and discussed above, the height of the rib truss it is mounted on will be determined by a stop affixed to the truss that will support the mounting plate (and thus the rib) at the right height. Bolt holes 2321′ and 2321″ can thus be made enough bigger than their bolts to cover potential inaccuracy in their placement, allowing the holes to be drilled through a stack of mounting plates to save time.

The verticals 233′, 233″, 233″′, 233^{iv}, 233^{v}, and 233^{vi} also do not need high precision because they have at least the depths of the angle iron pairs 234 and 235 of positional tolerance. The diagonals 236′ and 236″ can be longer pieces (preferably of steel rod) bent (as is shown in FIG. 2E), or separate shorter straight pieces can used, and again precision is not needed as the diagonals 236′ and 236″ just need to come to the angle iron pairs 234 and 235 near where the verticals 233′, 233″, etc. pass between the angle irons of each pair.

When the rib parts are placed in the jig 230, the rail 231 is placed first and clamped to the jig body 2301 at a sufficient number of points to hold it tight against the curve 23014 of the jig body 2301 (curve 23104 can be more clearly seen in FIG. 2D). Then the end 2322 of mounting plate 232 is placed against stop 23012′ (just as it will be placed against a stop when the rib is mounted on a truss as was shown in FIG. 2C). Continuing with the method illustrated in FIG. 2E, the mounting plate 232 is clamped against the jig body 2301, which optionally has pins 23011′ and 23011″ to ensure that the mounting plate bolt holes 2321′ and 2321″ are placed to within their generous tolerance allowance. An end alignment plate 237 (which with the rib 23 of the present example can be used to align the ends of multiple ribs 23 to an end truss) is placed against a stop 23012″, with an optional pin to ensure similar loose-tolerance positioning for its bolt hole 2321″′, and is then clamped to the jig body 2301.

In further preferred embodiments the holes 2381′ and 2381″ through which the rail passes are intentionally made larger than the rail to leave gaps between the rail 231 and the mounting plate 232 and between the rail 231 and the end alignment plate 237 respectively. This makes the positions of these holes less critical (or if the plates are cut to a length such that the rail will be welded to the end of the plate, it makes the lengths of these the mounting plate 232 and the end alignment plate 237 less critical). A tight fit is not needed because during welding weld material will fill the gaps.

Thus no parts have tight tolerances and the only positions that have tight tolerances are placing the mounting plate 232 and end plate 237 against their respective stops 23012′ and 23012″, which are built into the jig body 2301, and ensuring that these parts 232 and 237 and the rail 231 are clamped tight against the jig body 2301. Placing parts against stops and clamping them tight to a rigid body are easy to do to very high accuracy. Since the entire jig body 2301 can be accurately laser cut from a single sheet of ⅝″ (approximately 1.5 cm) thick steel at a cost of a few thousand dollars, and can be reused an essentially unlimited number of times, this method ensures the accurate placement of all parts that need accurate placement at extremely low cost.

Laser cutting steel sheet typically achieves an accuracy of around 125 microns, which is sufficiently accurate for all parts of the hybrid rib/rail 23. Even if not essential, greater accuracy is still beneficial, but while laser cutting accuracy can be improved to around 50 microns by cutting more slowly, this costs more. However all of the benefit of greater accuracy can be obtained by just ensuring that a few regions of the jig body 2301 have that greater accuracy. In particular rails 231 only benefits from accuracy where the reflective panels will be clamped to them. Returning to FIG. 2D, in this example there are eight regions 2311′-2311^{viii} on each rail 231 where panels' sleeves will be attached to the rail. Due to the varying twist of the mirrors to align their foci, the attachment regions range from about 2 centimeters wide for the attachment region 2311′ closest to the dish's axis of symmetry to about 8 centimeters wide for the attachment region 2311^{viii} farthest from the dish's axis of symmetry. The critical regions thus total just 40 centimeters of the rail's several-meter length.

The length of critical area can be reduced even further by noting that the desired shape of rail 231 is extremely close to a spline curve even within these critical regions, and by simply having a half-centimeter at each end of each panel attachment region be held accurately, the whole region will be within a few microns of the ideal shape. This reduces the total length of critical regions of the jig body 2301 for shaping rail 231 to a total of eight centimeters. Additional critical regions of the jig are for the mounting plate and end plate. For these the jig body 2301 needs accuracy only in centimeter-wide regions around stops 23012′ and 23012″, and in two-centimeter-wide regions around pins 23011′, 23011″ and 23011″′, for an additional eight centimeters in total. Non-critical regions of the jig body 2301 simply need to not protrude enough to interfere with the rail 231, the mounting plate 232 and the end plate 237, and should be cut further away from where these parts will go by a distance at least equal to the tolerance of the jig cutting process.

While as mentioned before low-cost laser cutting's 125 microns of tolerance is sufficient even in the critical areas, slowing down the laser cutting speed when cutting the 48 centimeters of critical region or the 16 centimeters of reduced critical region (a few percent of the circumference of jig body 2301) can produce even tighter tolerance (roughly 50 micron accuracy) at almost no extra cost. These critical areas can even be cut slightly protruding from the desired curve and then polished to the desired curve to reduce the error of ribs 23 made with jig 230 to a few microns if desired. Again, since jig 230 can be used almost indefinitely for making a very large number of ribs 23, the per-rib cost of this extra accuracy is negligible, and even the one-time tooling cost is very modest.

In addition to reducing the extra cost of higher accuracy when cutting the jig body 2301 with a laser cutter, the above discussion also provides for easily attaining sufficient accuracy in a jig 230 when a laser cutter is not available (for example, in some 3^{rd}-World countries). A simple angle-iron outline of the jig body 2301 could be welded, leaving space around where the rib parts will go, and then stops made of steel flat-bar carefully positioned and welded on for each critical region (or less carefully positioned and then ground to the required precision).

Referring again to FIG. 2E, it should be noted that even if the rib parts themselves have less accuracy than the jig body 2301, the critical surfaces of those parts are positioned by the jig body 2301 and will therefore attain the accuracy of the these regions of the jig body.

However there is a limit to the accuracy of ribs that will be made of steel that will be galvanized after fabrication, and that is the accuracy of the control of the thickness of the zinc coating obtained in the galvanizing process. This is especially true if hot-dipped galvanizing is used, and hot-dipped is a very cost-effective way to provide a very durable coating. Jig accuracies much better than the galvanizing inaccuracy quickly reach a point of diminishing returns because the total inaccuracy will be dominated by the variation in the thickness of the galvanizing coating. As known in the art of hot-dipped galvanizing, care should be taken to use attachment points for supporting chains that are not on critical rib surfaces (which correspond to critical jig surfaces), and to avoid having any drip-off points on critical surfaces. The speed at which the ribs are removed form the galvanizing bath can be controlled, and an ‘air knife’ can also be used to remove any excess zinc while it is still liquid. Finally, since consistency between pairs of ribs is more critical than precision of the ribs, hot-dipped galvanizing should be done in bundles of ribs that will end up being shipped together and installed in the same area of the same dish.

The other parts of rib 23 have very relaxed placement tolerances. The jig 230 has support means for them, but these support means do not need high accuracy and can thus be welded or bolted to the jig body while still ensuring accurate enough rib component placement. As shown in FIG. 2F, in jig 230 bottom-face angle irons 2341_{B} and 2351_{B} are placed on supports 2302′ and 2302″, then tabs 2342′, 2342″, 2352′ and 2352″, then the vertical members (for clarity only 233″ and 233^{v} are labeled), etc., and diagonals 236′ and 236″ are all placed between their alignment posts (for clarity, only posts 2303″ and 2303^{v} are labeled). The top face angle irons 2341_{T} and 2351_{T} are placed last, between the same sets of pins as bottom-face angle-irons 2341_{B} and 2351_{B} were. Minor modifications, such as combining tabs 2352′ and 2352″ into a single larger tab, can be made based on cost optimization between labor and materials.

Welding can be either automated or manual. While gravity and the alignment pins and posts will hold the pieces accurately enough for welding with a robot that can reach both sides of the rib, additional clamps can be set to hold all of the pieces firmly in place while the parts are welded. This is especially useful for manual welding, for which in still further preferred embodiments of the present invention, the whole jig 230 is easily rotatable about its long axis for convenience of the welder. As is known in the art of welding, patterns of welding that reduce distortion can be used. For example, every second weld to the angle irons on a first face of rib 23 can be made, followed by all welds other face, followed by the remaining welds on the first face; this causes the shrinkage of the angle iron on cooling from welding temperatures to balance out, producing a straighter rib.

It is also possible to avoid the use of added material in manufacturing the ribs, allowing rod-free welding. This allows welding techniques such as spot welding, laser welding, and magnetic pulse welding to be used. As shown in FIG. 2G, the vertical members such as 233G′ and 233G″ (and other verticals which for clarity are not shown) in the rib 23G also do not need high precision because by crossing the rail next to the panel attachment areas, the vertical members can overlap the rail. This allows contact between the vertical members and the rail without requiring precise positioning of the vertical members. Similarly punched slot 2381G on the mounting plate (and a similar slot on the end plate) allow contact with the rail without requiring precision cutting of these plates. All the other rib components already had contact where welding was needed, and already did not require precision cutting of the components.

Norman teaches mounting ribs on a thin central truss, and using diagonal bracing to tie the central truss, ribs and end trusses into a compound truss. While with proper bracing this produces very high strength-to-weight and stiffness-to-weight ratios, this requires complex bracing including field-adjusted bracing between ribs parallel to the center truss. Using a classic lattice box truss as the central truss is less efficient in terms of materials, but more efficient in terms of both total labor and in having less in-field labor. As shown in FIG. 2H, a preferred embodiment of the present invention uses a primary concentrator frame 24 comprising hybrid ribs 23H adapted to a central box lattice truss 241H. In further preferred embodiments the width of the central truss 241H is made to support an integral number of widths of reflective panels such as the panels disclosed in the first family of preferred embodiments of the present invention.

If said integral number of widths is even, the width of central truss 241H should include any central width to be left empty because it would be shaded by receiver supports and the receiver and secondary concentrators. In FIG. 2H this is two panel-widths, plus 12 centimeters (around 5 inches) for a central width that would be mostly shaded. This central width is convenient for securing the middle of short truss-rail 24131, such as with truss-rail vertical 24133. In exemplary embodiments the panels are slightly twisted to align their focal lines as taught by Norman, and the central truss width's allowance for the panel widths include the twist. This arises because slanting in two directions a mirror that curves in one dimension twists the orientation of the mirror's focal line by an angle substantially proportional to the inverse sine of the product of the sines of the slant in each of the two directions. Thus the extra width needed to include the panel twist is substantially proportional to the slant in each dimension of the middle of the outermost mirror on the truss. For a dish spanned by four mirror lengths and 14 mirror widths as used in the above examples, the slant along the length of the mirrors is ¾ of the rim angle in that direction and the slant along the width of the mirrors is 1/14 of the rim angle in that direction. The extra width needed is the sine of the twist angle times the length of the mirror, so for a 16.5 degree rim angle, the twist angle of the farthest mirror on the truss is L*sin(12.4)*sin(1.18)=L*(0.214*0.0206)=0.0044*L. With a 6-foot (915 mm) long mirror, this is an extra four millimeters in addition to the width of the panels themselves.

### Third Family of Preferred Embodiments

### Improvements in Dense Receiver Arrays for Very High Concentration Photovoltaic Solar Energy Systems

While straight, single-channel cooling tubes as taught by Norman are the simplest high-efficiency cooling system, the heat transfer coefficient of copper to flowing water is barely sufficient to cool cells into their safe operating temperature range at 1000 suns insolation in hot climates, and this provides sub-optimal cooling. Using multiple very narrow, relatively thick-walled tubes in parallel per row of cells is a considerable improvement, but the smallest commercially available thick-walled tubes are around 2.5 millimeters wide, which offers adequate but not great cooling for 1000 suns insolation.

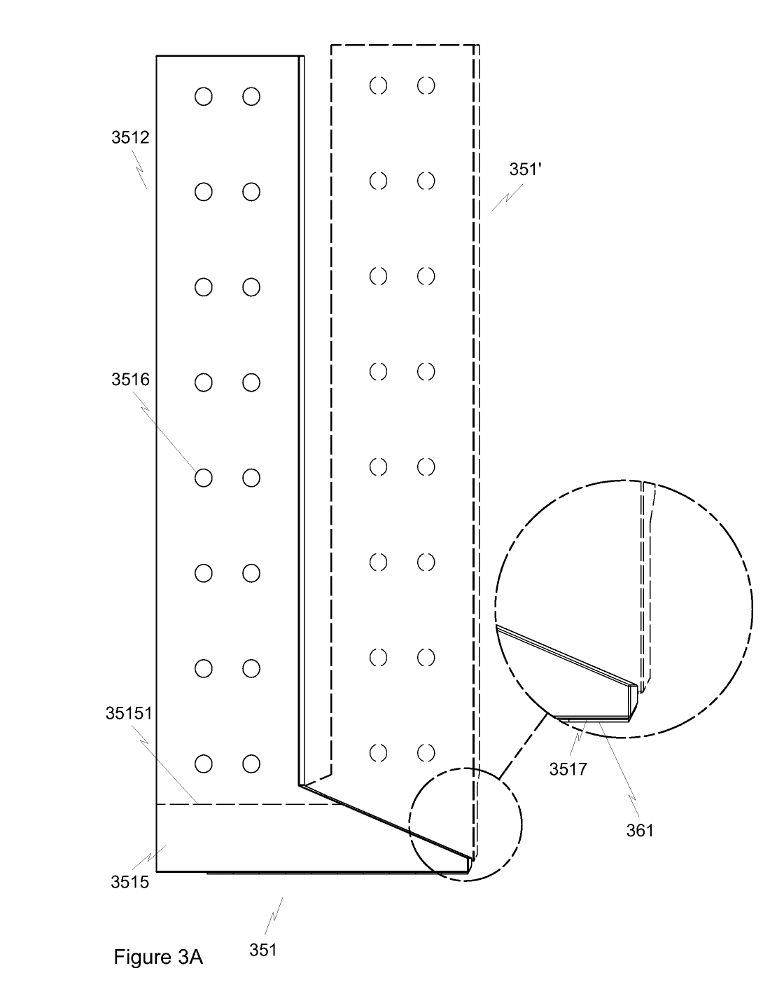

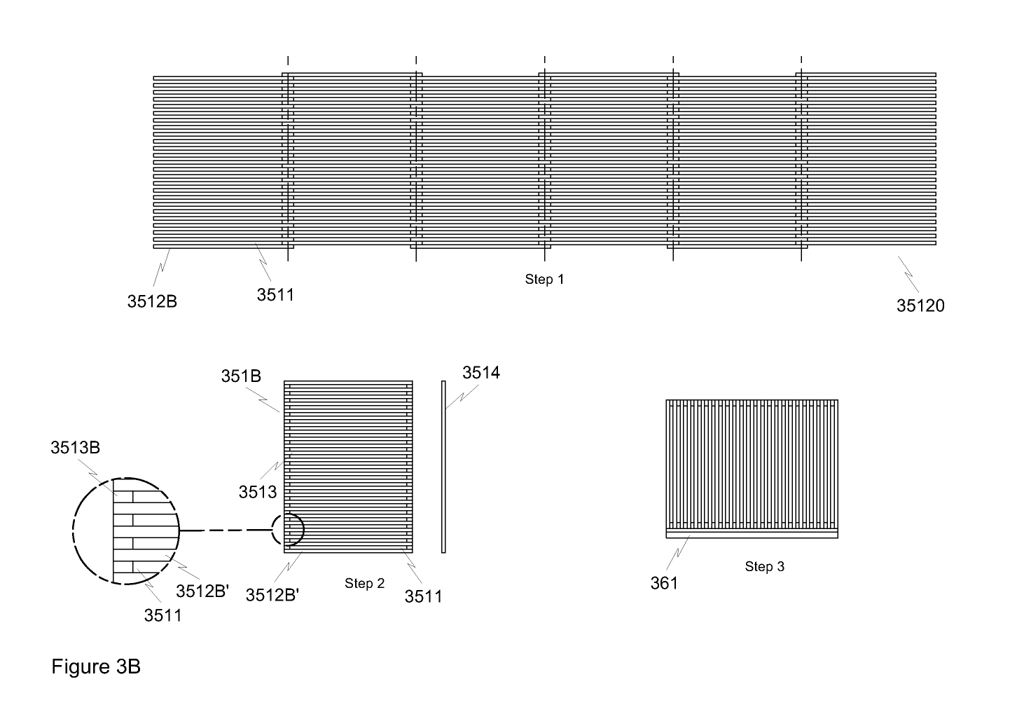

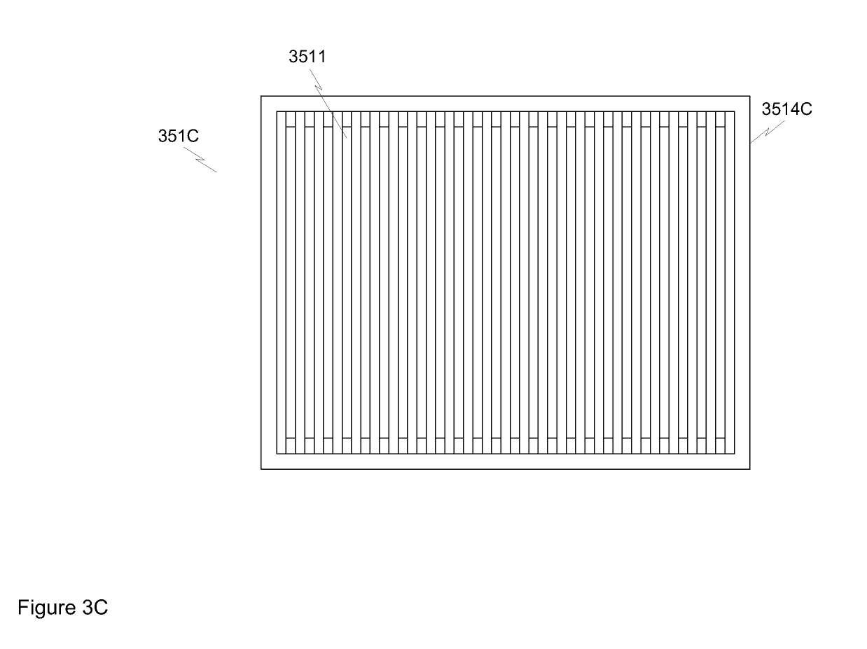

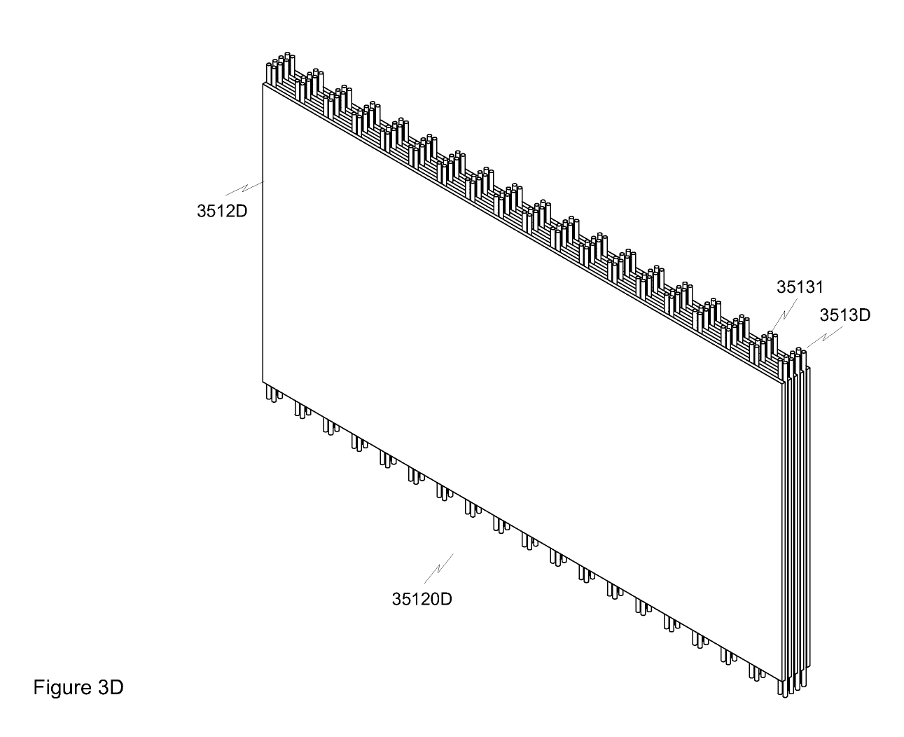

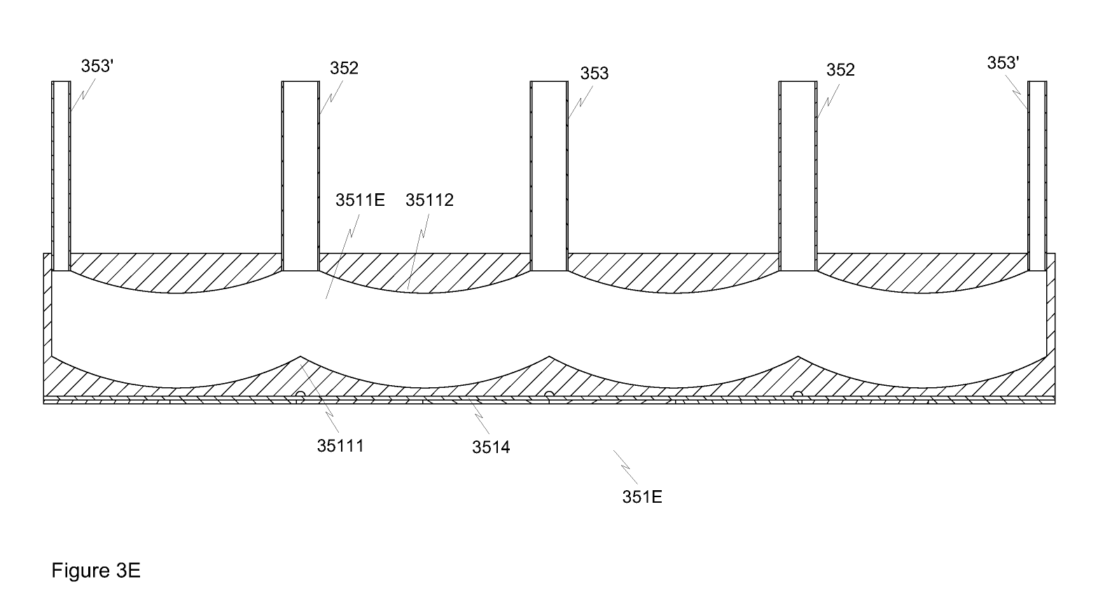

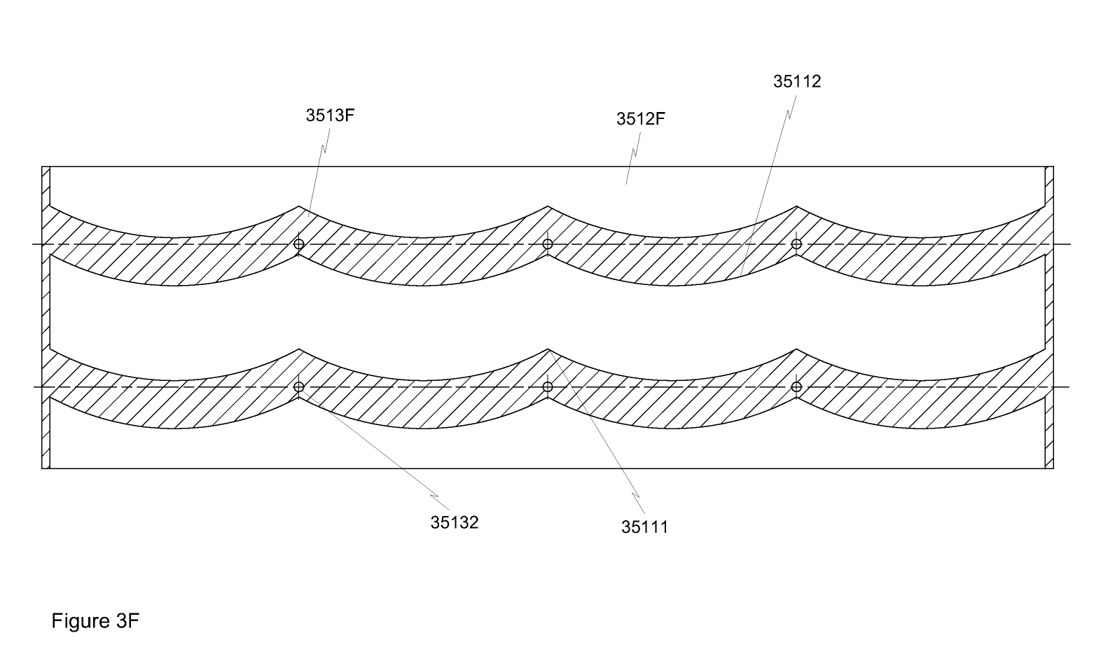

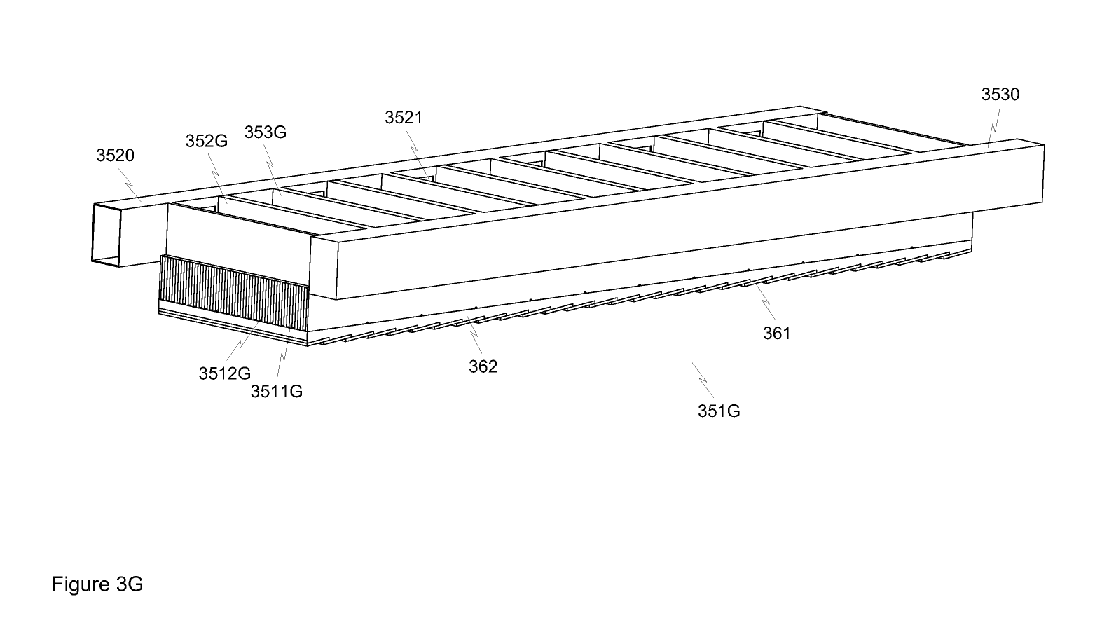

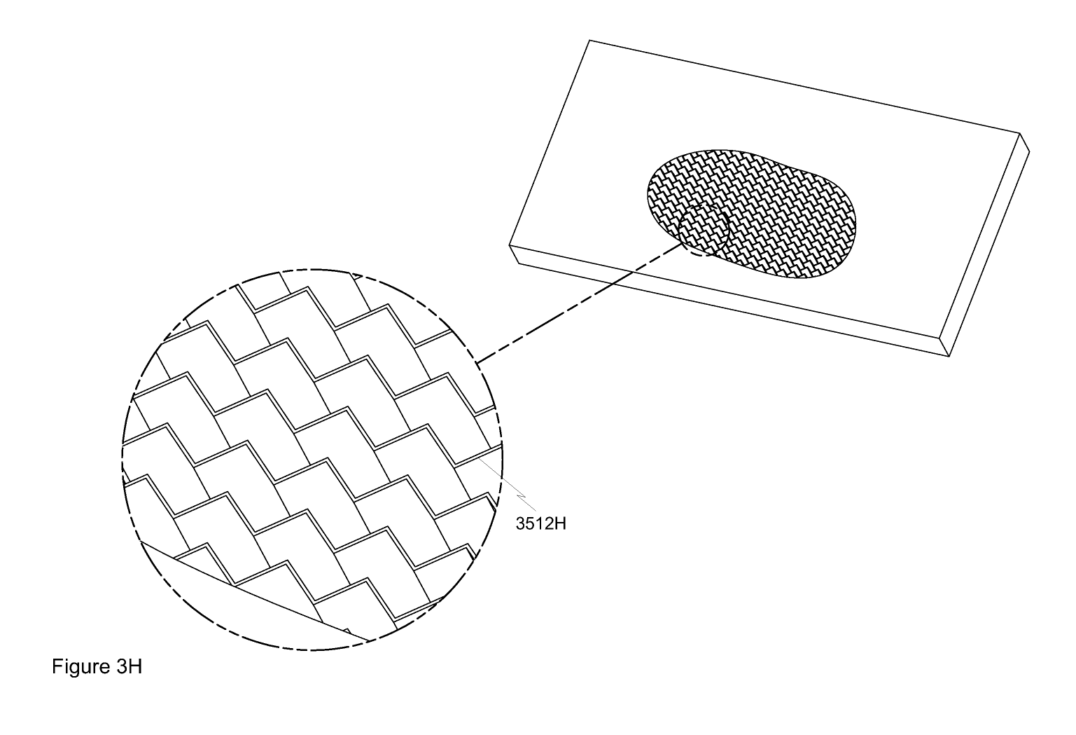

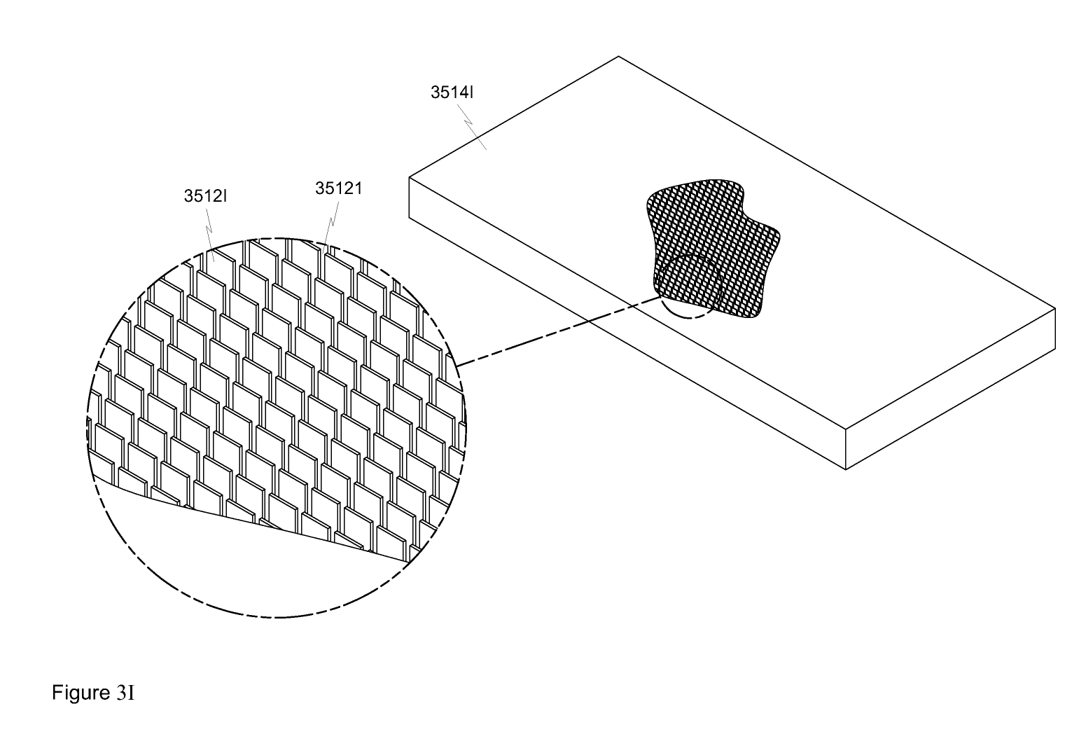

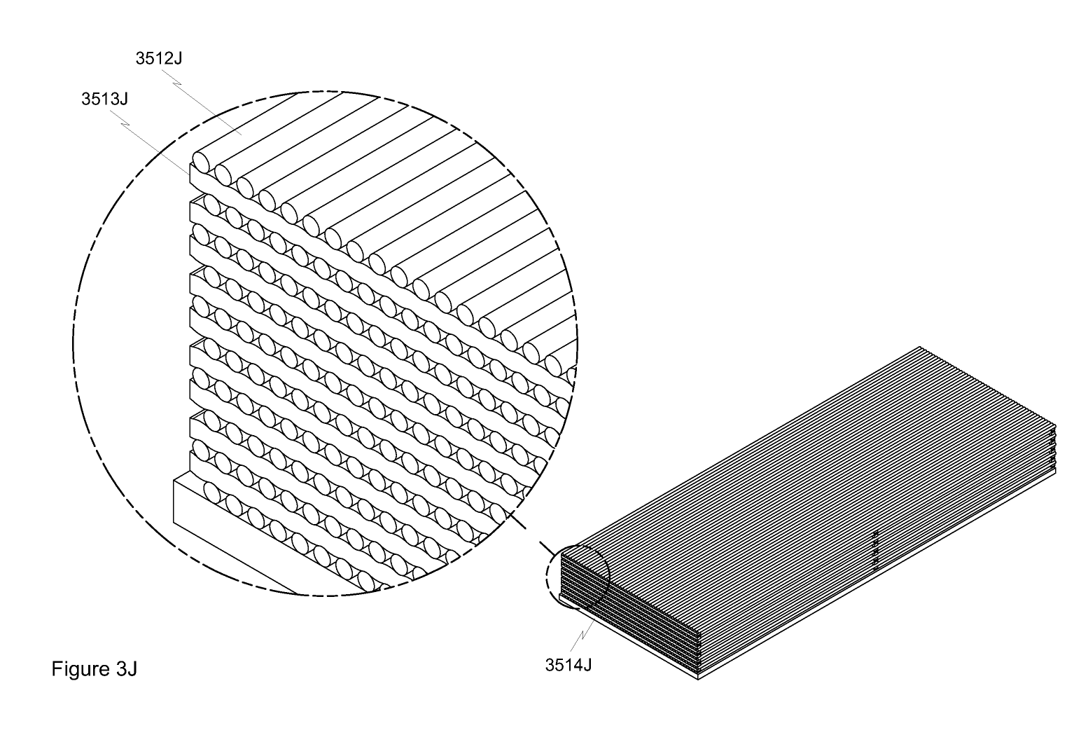

Evaporative coolers, also known as heat pipes, have much higher heat transfer coefficients to the boiling liquid than pumped-liquid cooling tubes have to the flowing liquid, and can thus provide superior cooling from a given surface area. A preferred embodiment of the present invention as shown in FIG. 3A uses gravity return for condensed coolant 3515, with the body of the heat pipes 351 angled to the plane of the cells 361 so that in tracking the sun's altitude from zero degrees to ninety degrees, the pipe's liquid return path goes from slanting to one side of vertical at dawn and dusk to slanting to the other side of vertical at noon, rather than ever going horizontal. Slanting 45 degrees one way to vertical to slanting 45 degrees the other way would work, but further preferred embodiments improve upon this by providing more fluid return, and thus more cooling, at noon than at dawn or at dusk. This is accomplished by slanting from 50 to 60 degrees to one side of vertical at dawn and dusk to slanting 30 to 40 degrees to the other side of vertical at noon. This can also be still further optimized for non-tropical zones where the sun is never at 90 degrees altitude.

While a single large heat pipe and condensing chamber could be used (as long as the cells are insulated from the heat pipe by an electrically insulating thermally conductive material such as taught above), in a heat pipe that changes slant a large chamber would have a significant depth of liquid above some cells at some angles, and the pressure from the weight of that liquid would raise the boiling point temperature of the liquid nearest those cells considerably, thus causing the lowest cells to be hotter and thus suffer from degraded efficiency. Returned liquid (condensed from vapor) could flow over one or more baffles that would keep some fluid on each cell at all slants without a deep pool of liquid, but this is more complex than the embodiment shown in FIG. 3A, in which the entire boot-shaped tube 351 can be formed from two simple stamped metal part soldered together.

In FIG. 3A, every other boot-shaped heat-pipe cooling tube faces the opposite direction. Because the cells 361 at the bottom of a heat pipe cooling tube 351 all need to slant in the same direction, boot-shaped heat-pipe cooling tube 351′ (shown as a dashed outline) is a mirror image of boot-shaped heat-pipe cooling tube 351, but is otherwise identical.

Boot-shaped heat-pipe cooling tube 351 has inward dimples 3516 on both faces that meet within the tube to keep the broad faces from collapsing due to the heat pipe's internal partial vacuum at lower temperatures (as is well known in the art of heat pipes, the internal pressure is equal to the vapor pressure of cooling liquid 3515 at whatever temperature the cooling liquid 3515 and its vapor are then at). The level 35151 of the cooling liquid 3515 (for which a mixture of water with enough methanol to prevent freezing under local climate conditions is preferred) is chosen so that the hot face 3517 remains covered when the receiver is at its greatest slant at dawn and at dusk.

The ‘legs’ 3512 of the boot-shaped heat-pipe cooling tubes 351 and 351′ are narrow enough (less than half the length of the row of cells 361) to allow a secondary coolant to be pumped around and between the boot legs 3512. Because the heat transfer coefficient (heat transfer per unit area per degree of temperature difference) of boiling water inside a heat pipe is roughly ten times higher the heat transfer coefficient of pumped non-boiling water inside a tube, the cells 361 heating the hot face 3517 can be cooled much better than with simple thick-walled cooling tubes. And while the heat transfer coefficient of condensing water vapor is only about ⅓ as great as the heat transfer coefficient of pumped non-boiling water, the area of the faces of the leg 3512 of each ‘boot’ 351 or 351′ can be far larger than the area of the hot face 3517 at the bottom of each ‘boot’. With the walls of each ‘boot’ preferably stamped from a ductile high-thermal conductivity material such as copper sheet, and with a pumped secondary cooling fluid flowing around the large wall area of the legs 3512, excellent cooling can be provided.

While in sparse receiver arrays heat pipes with appropriate fin tubes can be passively cooled, in dense receiver arrays heat pipes have the disadvantage of needing active secondary cooling such as from a pumped fluid. It is simpler to use a pumped liquid to cool the receiver array directly, but to do this requires greatly increasing the area for heat transfer to the cooling liquid. While making the cooling tubes much taller would increase their internal surface area for heat transfer, the heat would have to flow much farther within the walls to reach the additional area, and even copper is only sufficiently thermally conductive to make this a barely adequate solution for cooling the cells at 1000 suns.

While diamond has a roughly six times higher thermal conductivity than copper, which would allow much taller tubes with much greater surface area, making cooling tubes from diamond would not be cost effective at this time. Single-walled carbon nanotubes have a thermal conductivity along their length even greater than diamond (with perfect single-walled carbon nanotubes calculated to have a thermal conductivity 15 times greater than pure copper or 2.5 times greater even than diamond). Carbon nanotubes are also too expensive to be cost effective at this time. However, since both diamond films and carbon nanotubes are decreasing in price, in the future cooling tubes made from these materials may be cost-effective for 1000-suns cooling.

Another way to greatly increase the internal surface are of the tubes for transferring heat to the pumped liquid is to have multiple channels per tube for the coolant to flow through so that the liquid can pick up heat from each of many walls. Commercial very high performance mini-channel tubes with multiple very narrow channels (on the order of a half a millimeter wide) per tube offer very good cooling, but are more expensive than desirable for cost-effective solar systems that can compete with fossil fuels on cost. Micro-channel chillers with channels on the order of 100 microns wide offer excellent cooling performance, but require complicated plumbing to minimize the length that coolant must travel through the narrow tubes, and are more expensive than mini-channel cold plates. There is thus a need for an inexpensive method for fabricating very high performance cooling tubes or cold plates.

Rather than machining the multiple channels of mini-channel tubing from solid copper, a preferred embodiment of the present invention therefore forms low-cost mini-channel tubes by stacking layers of sheets of very high thermal conductivity material whose thickness is equal to the desired wall thickness, with spacers (preferably also of very high thermal conductivity material) whose thickness is equal to the desired channel width. As shown in FIG. 3B, cooling tubes 351B with channels 3511 that are, for example, 10 millimeters tall by 0.3 millimeters wide can be made by stacking 12 mm wide by 0.3 mm thick strips 3512B of copper sheet in alternating layers that overlap each side (in this example by one millimeter). As will be seen, heat will largely flow within the strips rather than between the strips, so the strips can be adhered to each other with a very thin layer of almost any adhesive (although a thermally conductive adhesive is more preferred), or the strips can be soldered, brazed, welded or direct thermo-compression diffusion bonded, etc. The stack 35120 of strips 3512B can then be cut through the overlap regions (as indicated by the dashed lines) to produce a number of multiple-channel tubes 351B. The strips 3512B′ in the tube 351B will be a bit shorter than the original strips 3512B were due to their ends having been cut off to serve as spacers 3513B for the strips 3512B′ of other tubes 351B.

If desired, one or more of the cut faces of tubes 351B can be reinforced with additional thin strips 3514 of thermally conductive material. For the face that the cells 361 will be attached to, this will provide a smoother, stronger surface for the attachment of photovoltaic cells 361. Since heat will be conducted from strip 3514 to strips 3512B′, the attachment of 3514 to tube 351B should be through high-thermal-conductivity means such as soldering, brazing, welding, direct thermo-compression diffusion bonding or a thin layer of thermally conductive adhesive. To further reduce the thermal resistance, the face of the multi-channel tube 351B that will be bonded to the thermally conductive thin strip 3514 can be milled down so that only a fraction of a millimeter of the spacers 3513B will be left. Even if milling continues until the tube face starts becoming perforated where the sheet edge roughness of the spacers 3513B (which is formed from the cut ends of other strips 3512B) makes the spacers the narrowest, these perforations will be sealed by bonding to reinforcing strip 3514.

While any high-thermal conductivity material can be used for thermally conductive strips 3512B, copper is currently preferred because it offers the best balance of high thermal conductivity, low cost and machinability. Where a thermal coefficient of expansion lower than that of copper is desired (e.g., for matching the thermal coefficient of expansion of cells 361), a material such as a tungsten/copper, molybdenum/copper, copper/graphite, or aluminum/silicon-carbide composite becomes preferred when affordable, and diamond strips coated with copper can have an overall thermal coefficient of expansion matching today's ultra-high-efficiency cells while having exceptionally high thermal conductivity, and will become exceptionally preferred if diamond films become affordable.

Thermally conductive strips 3514 are also currently preferably copper unless properties such as electrical insulation and low thermal expansion as desired, in which case aluminum nitride is a preferred material. Other materials can also be used, and coatings can be used for optional strip 3514; for example a coating of CVD diamond film could be deposited for strip 3514 to provide exceptional thermal conductivity, low thermal expansion, and great strength, and the deposition of diamond films is becoming less expensive and in the future may be cost effective (since CVD diamond is hard to deposit on copper, an interface layer, as is known in the art of diamond deposition, would be used).

A way to provide a thermal coefficient of expansion other than that of the strips 3512B is to have reinforcing thin strip 3514 be of the desired thermal coefficient of expansion. In such embodiments it is preferred for milling to continue until the tube face that will be bonded to the thin strip is perforated to provide stress relief for the difference in thermal coefficients of expansion, and even further preferred for the edge to be contoured to provide regular perforations. As will be discussed later, it is even further preferable for strips such as 3512B to be corrugated or slit so that the remaining strips 3512B′ have built-in stress relief for both tensile and compressive stress.

As shown in FIG. 3C, to ensure a water-tight seal a multi-channel tube such as 351B can also be encased in an outer tube 3514C, such as by using a thin layer of a reasonably high thermal conductivity bonding material like solder, thermally conductive adhesive, etc. This produces an extremely robust cooling tube 351C, for even if the inner channels 3511 leak, the outer tube 3514C will contain the fluid.

A further preferred method for making mini-channel tube is more scalable to high-volume production and also allows the channel width and the sheet thickness to be different. In general the higher the thermal conductivity of the sheet material, the thinner the optimum sheet thickness relative to the spacer thickness becomes as less sheet thickness is needed to carry the same heat. Also the farther between inlet and outlet, the wider the optimum channel width (and thus spacer thickness) becomes.

As shown in FIG. 3D, flat sheets 3512D of copper (or other thermally conductive material such as aluminum nitride) can be stacked with layers of pairs 3513D of taut wires 35131 between them. The wires 35131 can be coated with adhesive or solder, or the whole stack 35120D can be fused under pressure in thermo-compression diffusion bonding, after which the stack can be sawn between the wires 35131 of each pair of wires 3513D (which may be done with wire saws the way wafers are sawn from a silicon ingot) to produce cooling tubes (not shown but similar to 351B). While taut copper strips could be used instead of pairs 3513D of copper wires 35131, wires are more preferred than plain strips because in milling down the face to minimum thickness, more and more of the wire becomes exposed and milling can be stopped when the desired amount remains (typically near the middle of the wire). Just as with tubes 351B as was shown in FIG. 3B, such multi-channel cooling tubes can be made sturdier and their water-tightness ensured by bonding the cut and milled face to a thermally conductive sheet (preferably copper or aluminum nitride). Such a multi-channel cooling tube could also be encased in an outer tube as was shown in FIG. 3C.

The thinner strips 3512B or sheets 3512D are, and the thinner spacers 3513B or wires 35131 are, the more surface area there is exposed to coolant for removing heat, and the smaller a distance the heat averages flowing in the walls cut from strips 3512B or sheets 3512D before being absorbed by the fluid flowing through the channels. While the thinnest commercial thick-walled copper tubes found would provide eight copper faces per centimeter of cell width, 0.3 mm thick strips and spacers would provide 32 faces, for four times as much surface area to transfer the heat to the fluid per distance that the heat is conducted.

However as the channels get narrower, the friction resisting fluid flow rises more and more rapidly (much faster than linearly) until not enough fluid can be pumped at a reasonable pressure (and pumping at high pressure takes increased energy as well as stronger tubes and more expensive pumps). Cooling tubes with very fine channels therefore typically have fluid fed into them and withdrawn from them at multiple points along their length. Even a single central feed and withdrawal at both ends means that only half as much fluid needs to be pumped through a given cross-section of each tube, while the total distance that fluid is pumped remains constant. This dramatically reduces the pressure required to pump the fluid (typically five to ten times less pressure in narrow channels), or allows twice as much fluid to be pumped at the same energy cost. If additional flow is needed, additional inlets and outlets can be added until the desire volume of fluid can be pumped at a reasonable pressure; for example, for the same pumping energy ten times as much fluid can be pumped with five inlets and six outlets as can be pumped with one inlet and one outlet.

The cooling tubes 351B and 351C, and the cooling tube that would be produced from cutting stack 35120D of FIG. 3D, can have multiple inlets and outlets along their lengths. However a dead zone would occur under each intermediate inlet and outlet where forces on the fluid balance, and these dead zones would reduce the fluid flow in area nearest the cells that would normally be the most effective in removing heat. This would produce warmer (and thus less efficient) areas on the cells being cooled. The pumped fluid would also have some tendency to short cut across the shortest distance from inlet to outlet, producing the highest fluid flow in the area farthest from the cells, and thus least effective in removing heat, which would use the pumping energy inefficiently.

An even further preferred method of making mini-channel tubes as shown in FIG. 3E creates low-cost but even higher performance cooling tubes 351E by contouring the walls of the channels 3511E. The dead zones under each inlet 352 and outlet 353 are greatly reduced by replacing the area where fluid would have stagnated by cusps 35111 of highly thermally conductive spacer material, and the tendency of the fluid to short-cut across directly between inlets 352 and outlets 353 and 353′ is reduced by spacer material scallops 35112 into the coolant channel 3511E being in the way of the shortest path. Again, a tube 351E may be reinforced with a strip 3514.

As shown in FIG. 3F, the cusps 35111 and scallops 35112 can be created by using contoured spacers 3513F between thermally conductive sheets 3512F (which may be the same as 3512D) in a stack of sheets and sawing the stack through the spacers 3513F (as shown by the dashed lines). FIG. 3F also shows milling depth guide marks 35132 punched into spacer 3513F. Referring again to FIG. 3E, the bottom face of cooling tube 351E has been milled down until these milling depth guide marks are reduced to substantially just their top points, indicating (in this example) that the bottom of the resulting cooling tube (351E, for example) is at the desired thickness. If a reinforcing strip such as 3514 as was shown previously is used, milling could even continue until only cusps 35111 are left.

In addition to the cusps and scallops discussed above, any desired bottom contour or top contour of the channel, such as bumps for increasing turbulence, can be created by cutting the appropriate profile into the spacers. Many of the enhancement techniques taught by Steinke can be used directly, and even Steinke's secondary channels could be included by stamping holes and thin regions in the sheets. The side-walls can also be enhanced while still in the form of a sheet, such as by texturing areas to increase turbulence, or even selectively growing ultra high surface area features such as carbon nanotubes. Also, the sheets 3512F may be slit or may be corrugated (preferably with at least one corrugation between each cusp) to reduce thermal stress if a reinforcing strip (such as 3514 of FIG. 3E) with a different thermal coefficient of expansion is used.

When multiple cooling tubes, each with multiple inlets and outlets, are to be placed side by side in a dense receiver array, preferably an electrically insulating but thermally conductive reinforcing plate is used. This not only insulates the cells from the cooling fluid, allowing electrically conductive cooling fluids to be used, but also allows easily solderable copper pipes (not shown) to be used to feed multiple inlets and drain multiple outlets. While insulating tubes could be used for connecting multiple inlets or outlets, the electrical insulation afforded by reinforcing strip also allows an assemblage of multiple inlets and outlets and feeder and drain plumbing to be stamped from a single sheet of metal, increasing strength and decreasing cost.

When the photovoltaic cells are insulated from the cooling system by one or more highly thermally conductive electrical insulators, the cooling system components no longer have to match the width of the cells. As shown in FIG. 3G, an exemplary embodiment of the present invention shapes the cell-face of a thermally conductive interposer 362 to match the profile of shingled cells 361, and has the opposite face of the interposer flat so that the interposer decouples the cooling system from the width and thickness of cells 361, which allows the cooling tubes to be as wide as desired rather than restricted to the cell width. As shown in FIG. 3G, a single ‘cooling tube’ 351G with inlet manifold 3520 and outlet manifold 3530 can even be the size of the whole array of cells 361, and is more properly called a ‘cold plate’ (for clarity, shown without a top cover). The direction of the internal strips 3512G and channels 3511G (for clarity, shown without an end cover) within the cold plate 351G is rotated 90 degrees so that the stack of copper sheets from which the cold plate 351G is sawn is as high as the cold plate 351G is wide rather than as high as the cold plate 351G is long.

Because there are multiple inlets and outlets along each channel 3511G, cusps in the bottom and scallops in the top of channels 3511G of FIG. 3G (similar to those shown in FIG. 3E but are not shown for clarity in illustrating the overall structure of cold plate 351G) are preferable. Since the face with scallops needs to be opened above every cusp where the spacers of that face are thinnest, and since that face will be covered by the manifolds anyway, openings for coolant to flow from inlet manifold 3520 through manifold openings 3521 into inlets 352G and into channels 3511G, and from channels 3511G into outlets 353G and into outlet manifold 3530 (through manifold openings that are not visible due to being on the hidden inner face of outlet manifold 3530), can be formed simply by milling the scalloped face, before attaching the manifolds, until the openings above the cusps are the desired size. It be noted that modest amounts of leakage between channels 3511G and manifolds 3520 and 3530 can be rendered harmless by sealing the exterior of the cold plate (and a copper sheet can also be soldered on before the interposer 362), so it is not necessary for all of the numerous internal connections to be water tight.

As shown in a cutaway view in FIG. 3H, even more preferably the sheets that get cut into strips 3512H are corrugated to minimize thermal stress. Corrugation provides pre-buckling so that contraction of the copper strips relative to the cold-plate face upon cooling from bonding temperatures merely straightens out the strips somewhat rather than trying to stretch the strips.

Still more preferably, as shown in FIG. 3I, thermally conductive strips 3512I can have slits 35121 in them to decouple the expansion of the bulk of the strips 3512I from the cold-plate face. The spacing of such slits 35121 should typically be slightly farther apart than the thickness of the strips 3512I so that the strength of the cold plate is not significantly reduced. Such slits 35121 can be extremely narrow, typically less than a micron wide if not limited by the manufacturing process. A slit 35121 every 200 microns in one-centimeter-tall strips 3512I will reduce the force from CTE mismatches by roughly two orders of magnitude, allowing a much thinner (and thus lower thermal resistance) thermal expansion constraining layer 3514I to be used. Even slits tens of microns wide are acceptable, as a 20-micron slit every 200 microns removes only 10% of the a strip's thermal conductivity and heat transfer surface

As shown in FIG. 3J, reduced-CTE-mismatch-force cold plates can also be made by stacking highly thermally conductive wires 3512J and spacers 3513J. A stack whose height is equal to the width of the desired cold plate can be cut on the planes indicated by the dashed lines to form multiple cold-plate cores whose fins are not strips but are rows of high-thermal-conductivity wires. Again the spacers can be milled down to minimal thickness (and can have milling guide marks, cusps and scallops as taught earlier in the present application), and the core can have a reinforcing and CTE-constraining face added; these are not shown for clarity. Since the sides would otherwise be porous, a separate reinforcing sheet 3514J is added to the bottom of the stack and to the top of the stack.

Preferably the CTE-constraining reinforcing plates are a tough, highly thermally conductive material such as molybdenum, which can be copper-clad to allow diffusion bonding to copper fins, or a copper/carbon fiber matrix or other highly thermally conductive low-CTE material. The constraining sheet can also be made of a tough, electrically insulating but thermally conductive material such as copper-coated aluminum nitride or silicon nitride (both of which avoid the toxicity of beryllia).

Because these CTE-constrained cold plates with reduced CTE-mismatch forces provide excellent cooling and are inexpensive to fabricate in quantity, and because the interposer and this cold plate together ease the use of different width cells as cell voltages change (and thus maintaining a constant overall receiver voltage), and ease the use of cells of different thickness from different manufacturers (or of different cell generations from a given manufacturer), this embodiment of the present invention is exemplary.

It should be noted than even cold plates machined from solid copper blocks can use fins that are corrugated or slit as taught above for stacked-sheet cold plates.

### Fourth Family of Preferred Embodiments

### Improvements in Cell Placement for High-Efficiency Photovoltaic Cells for High-Concentration Solar Energy Receivers

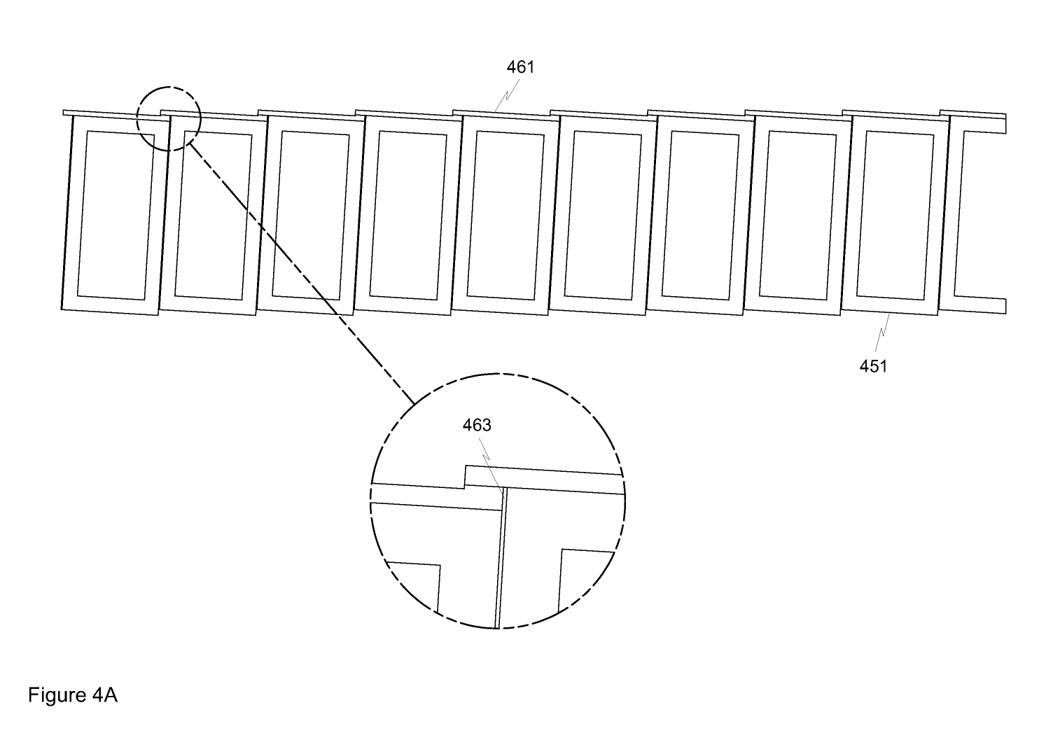

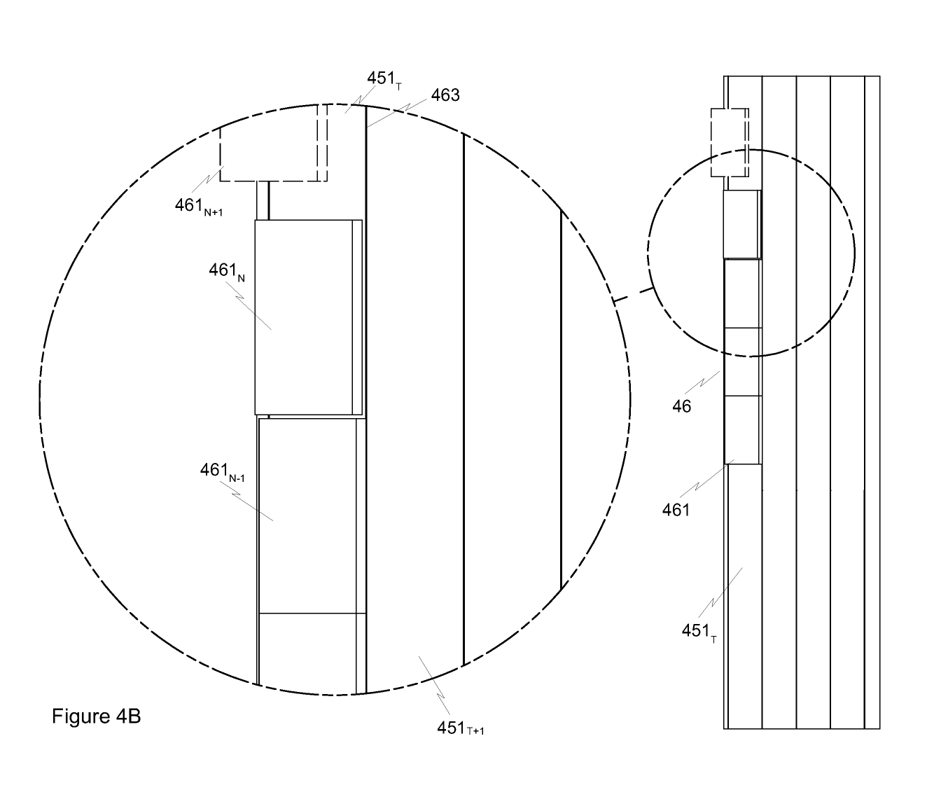

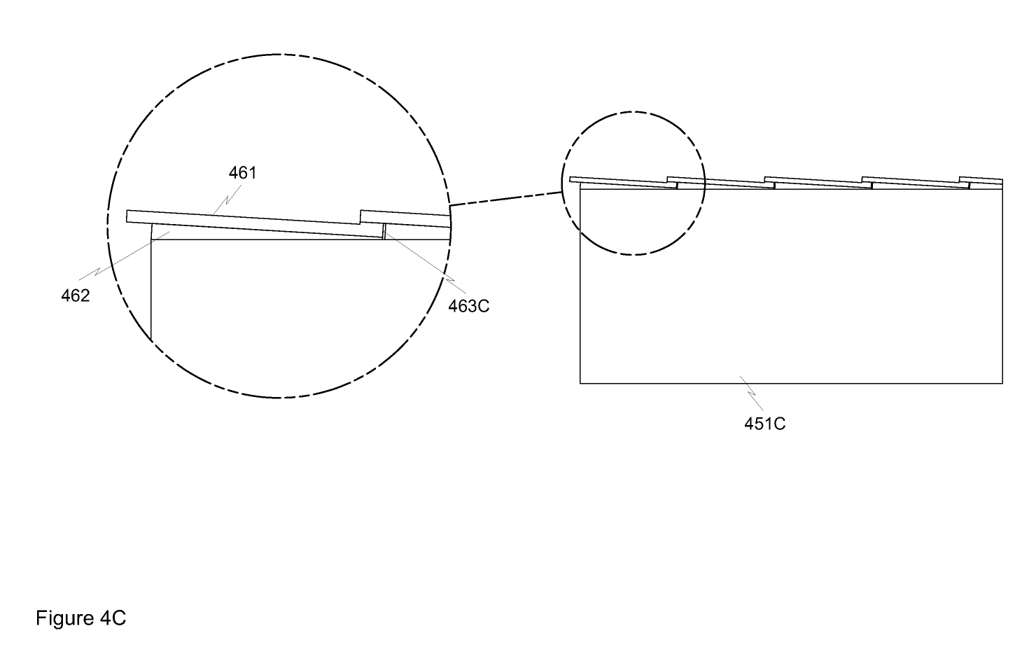

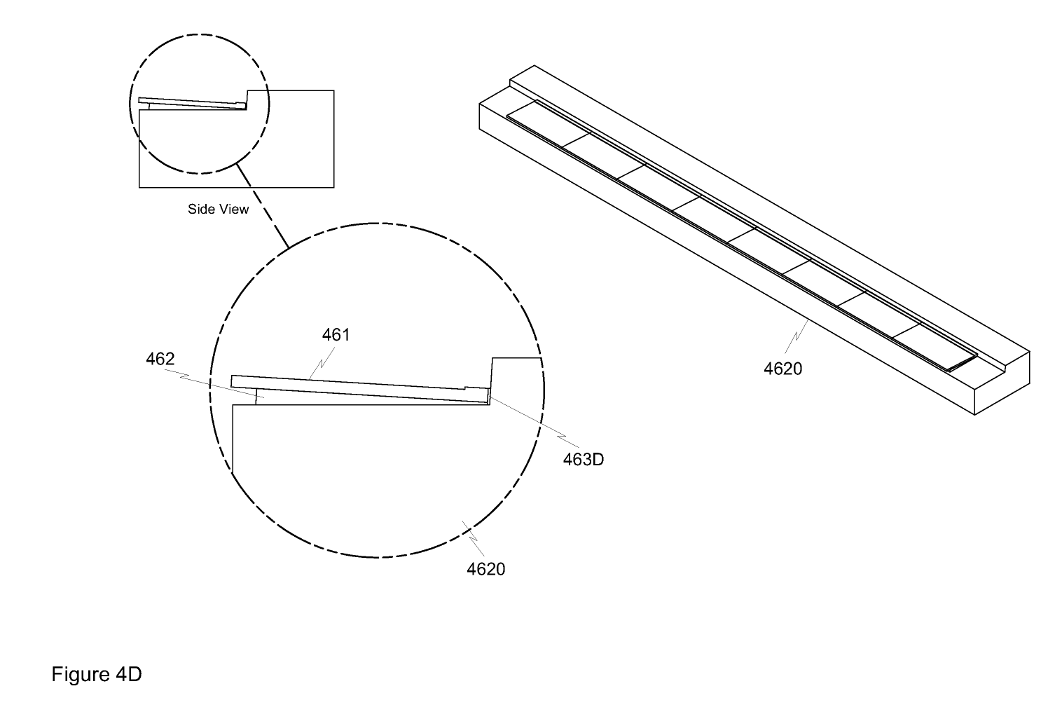

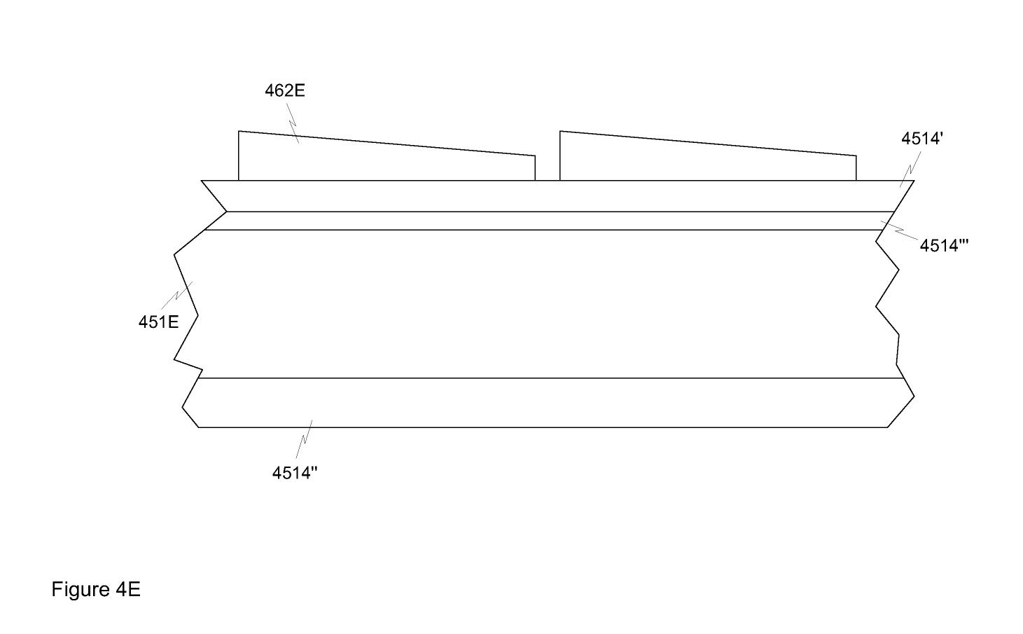

Norman's placing of the cells can be improved upon, too. In Norman's design the copper tubes need to be insulated from one another anyway, so as shown in FIG. 4A, in a preferred embodiment of the present invention the tubes 451 (which may be any of tubes 351, 351B, 351C or 351E or that which would be obtained by cutting stack 35120D, or may be other cooling tube designs) are separated by insulating two-sided sticky tape 463. In addition to holding tubes 451 in place during placing of additional tubes and in placing an array of cells 461 (which may be the same as cells 361 or may be different), by having tape 463 go to the top edges of tubes 451, a cell's-thickness of the tape 463 remains exposed.

Commercial pick-and place machinery generally achieves only 50-micron accuracy, which would equate to a few percentage points of packing factor loss with typical-sized multi-junction concentrator solar cells. Robotic equipment with force feedback sensors is therefore preferred for cell placement because, as shown in FIG. 4B, this allows cells 461 to be placed within 50 microns and then snugged up to a stop in each direction. In further preferred embodiments a cell 461_{N} is placed within 50 microns of its final position using standard geometric placing or optical feedback, and is then snugged against its neighboring cell 461_{N-1} on the same tube 451_{T} using force feedback. The cell is then slid along its neighboring cell 461_{N-1} for up to 50 microns until it is snugged against the tape 463 on the neighboring tube 451_{T+1}, which acts as a stop. Tape 463 then holds the cell 461_{N} in place while additional cells 461_{N+1}, 461_{N+2}, etc., are being placed, and also while the cell array 46 is being soldered in a soldering oven (using a commercial polyimide tape that can take soldering temperatures, a sample assembly of cooling tubes and cells was knocked sharply on a desk as an experiment and no cells came loose).

As shown in FIG. 4C, when a cold plate 451C is used the interposer may be made up of numerous bars 462 a highly thermally conductive but electrically insulating material such as aluminum nitride. In this case it is the interposer bars 462 that are stuck together with two-sided sticky tape (or other tacky material) 463C, again leaving a cell's-thickness of tape 463C exposed at the top to aid in holding the cells 461 after placement.

As shown in FIG. 4D, it is also possible to place and pre-solder multiple cells on interposer bars 462. This has the advantage of easing the use of conductive adhesives by making solvent evaporation easier, and of allowing testing the bars of pre-soldered cells before final assembly, as well as simplifying final assembly. However while two-sided tape or other tacky material can still be used to hold the bars in place, the same tape will generally not be used in holding the cells in place during cell placement and pre-soldering. Each bar can be pressed against a small jig 4620 with a sticky tape face 463D, and then the cells 461 placed and snugged against one another and then slid until snug against tape 463D, very much as was described in the description of FIG. 4A. This jig 4620 can then be run through a soldering oven or an adhesive curing process with the cells 461 held firmly but releasably in place by the tape 463D. Interposers 462 with attached cells 461 can then be bonded to a cold plate.

Using electrically conducting interposers on an electrically insulated cold plate allows thinner insulation and provides a wider choice of thermal-expansion-matched interposer materials. An exemplary way to make a balanced cold plate with thermal expansion-matched interposers, as shown in FIG. 4E, is to start with a cold plate 451E and bond insulating reinforcing plates 4514′ and 4514″ of an electrically insulating material with a thermal coefficient of expansion near, and preferably slightly below, that of the desired interposer material. These reinforcing plates allow the cold plate 451E, which may be made from stacking sheets as shown in FIG. 3G or may be formed traditionally through electron discharge machining or other micro-machining, to have very thin or even perforated surfaces against the insulating plates, thus allowing inexpensive and highly thermally conductive materials such as copper to be used with minimal thermal stress on the insulating plates. Interposers 462E of the desired material are then bonded to one insulating plate with low thermal resistance means (e.g., solder, diffusion bonding, or thermally conductive adhesive). Interposers can have cells pre-attached or adhered afterward, as taught earlier in the present application.

Preferably the cold plate material is copper, and preferably its channel walls are corrugated or even more preferably slit to minimize thermal stress. For today's high-efficiency solar cells (which are based on Germanium or Gallium Arsenide substrates), preferably the insulating plates are of aluminum nitride and they are pre-metalized with copper so that they can be diffusion bonded to the cold plate. If the thermal stress produced by restraining the CTE of the cold plate is high, then preferably a layer of a tough, high-thermal conductivity, low-CTE material such as a molybdenum or tungsten plate 4514″′ can be used between the cold plate and the insulating plate 4514′. Reinforcing plate 4514″ is not in the thermal path and just balances restraining the cold plate to prevent warping, and so can be made of any tough low-CTE material regardless of thermal conductivity (preferably a low-cost material). Preferably the interposers are copper tungsten, copper/graphite or are aluminum silicon carbide, either of which can have its thermal coefficient of expansion tailored to match any desired coefficient near that of either germanium or gallium arsenide, and preferably the interposers have a thermal coefficient of expansion just slightly higher than the cells. The interposer material can also be attached as a sheet and then machined in-situ into separate interposers, such as through electron discharge machining

### Fifth Family of Preferred Embodiments

### Improvements in Contacts for High-Efficiency Photovoltaic Cells for High-Concentration Solar Energy Receivers

While Norman teaches an improvement to the top-surface cell contacts by shaping these so that they have smooth sidewalls angled to reflect light onto the active cell surface between the contacts, thus utilizing the few percent of the light that is traditionally lost due to hitting the contacts, Norman's multi-step process for forming these shaped contacts directly on the cell surface is not the simplest process for forming such contacts. In preferred embodiments of the present invention, shaped cell top contacts are created by forming the shaped contacts separately and then transferring those contacts to the cell surface, or by creating the contacts in a reusable mould in contact with the cell surface. In further preferred embodiments such contacts are created on a wafer full of cells before the wafer is diced into individual photovoltaic cells.

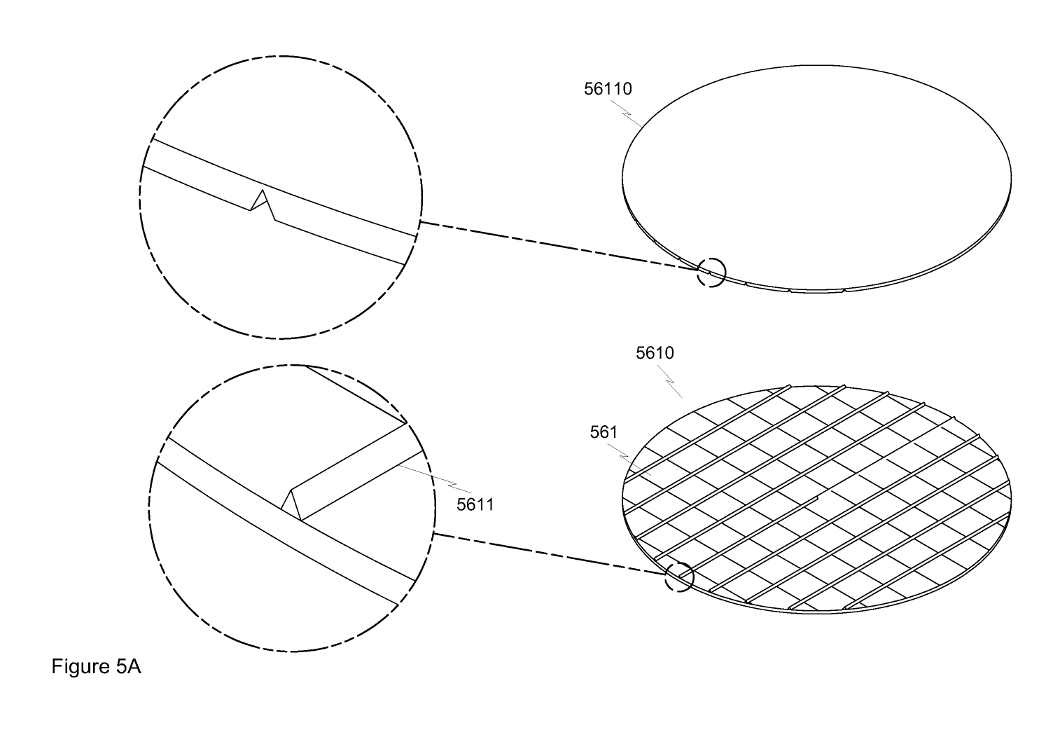

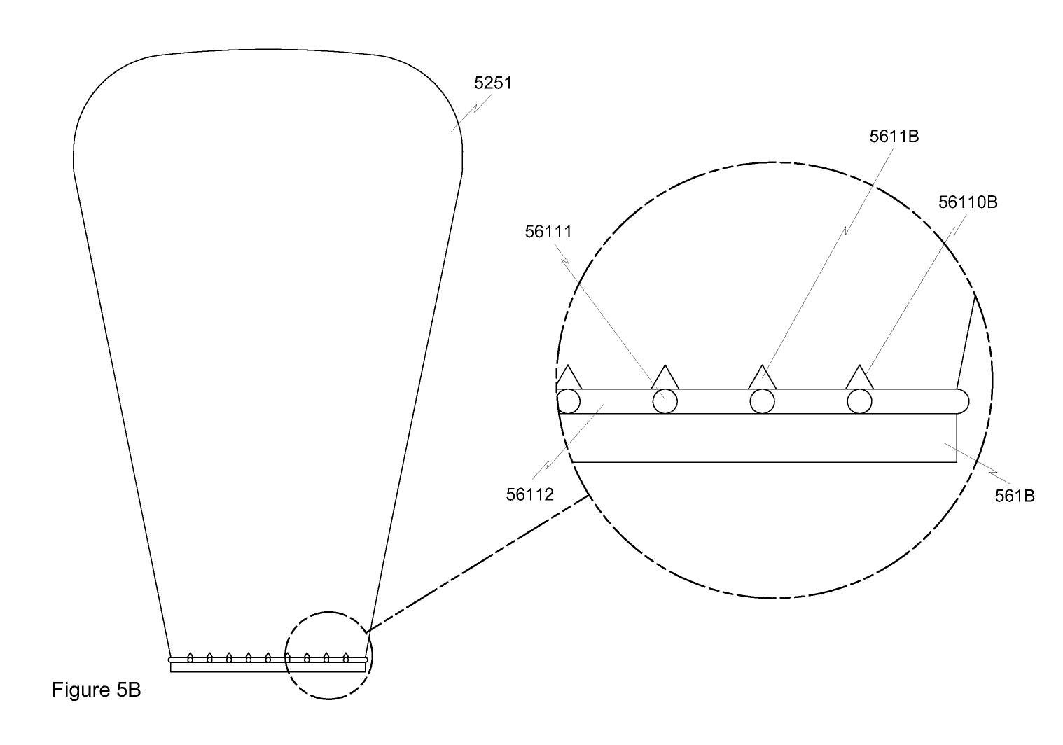

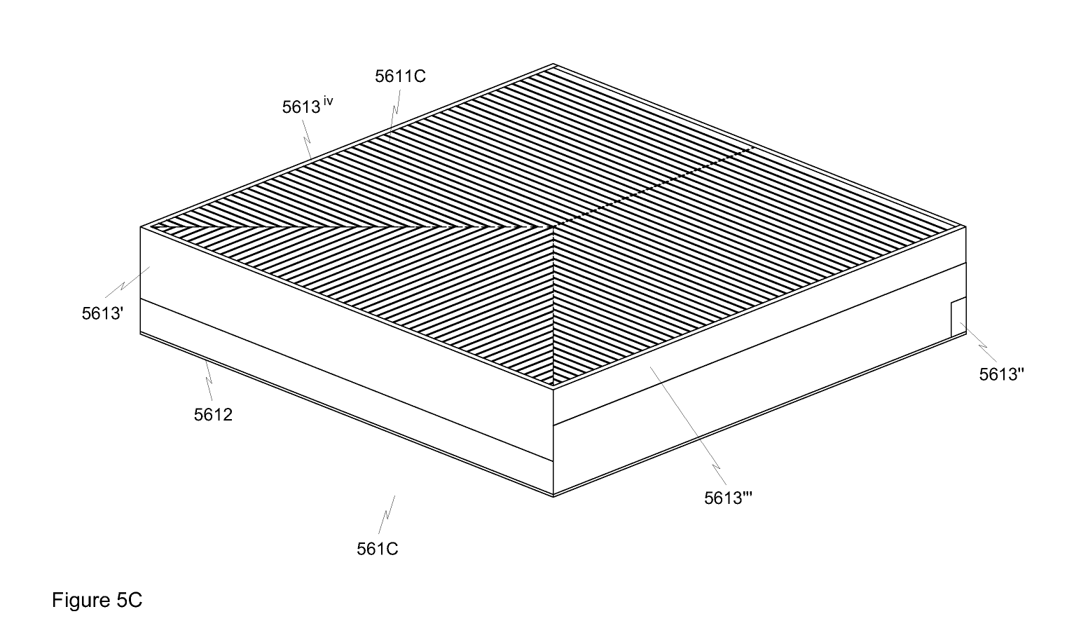

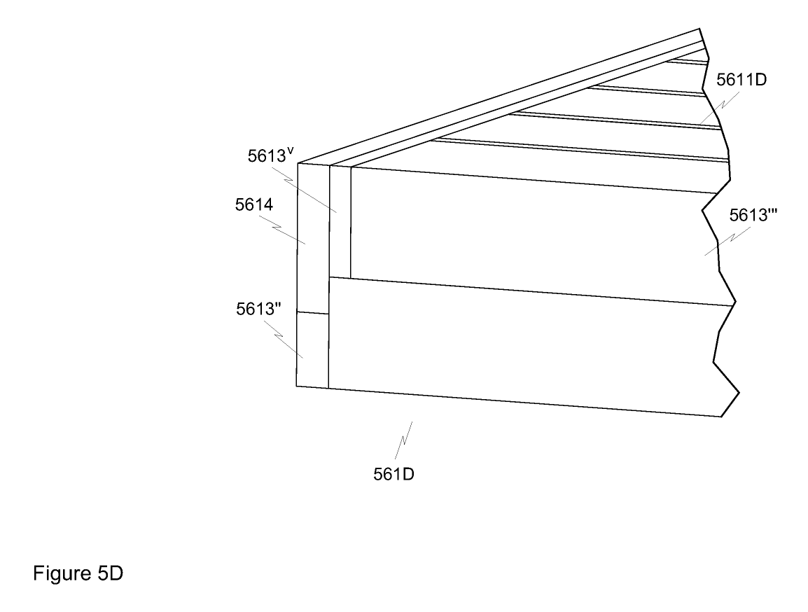

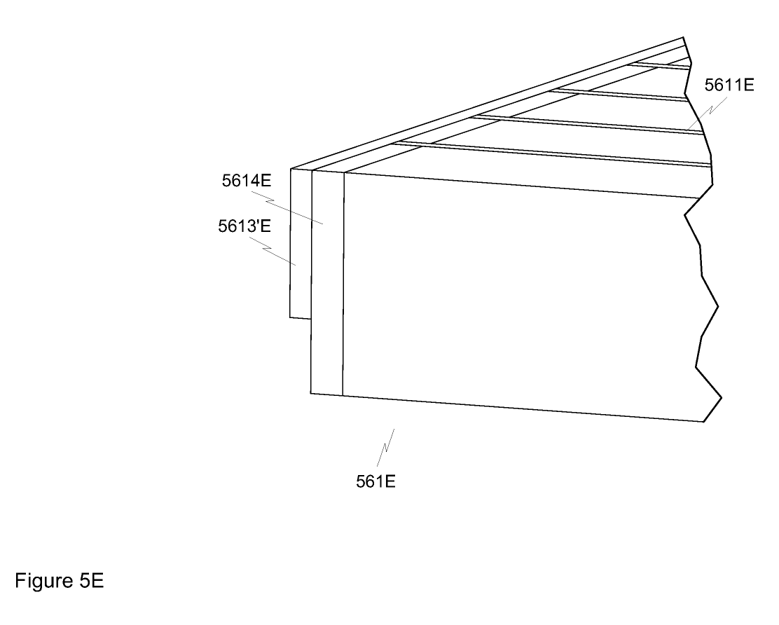

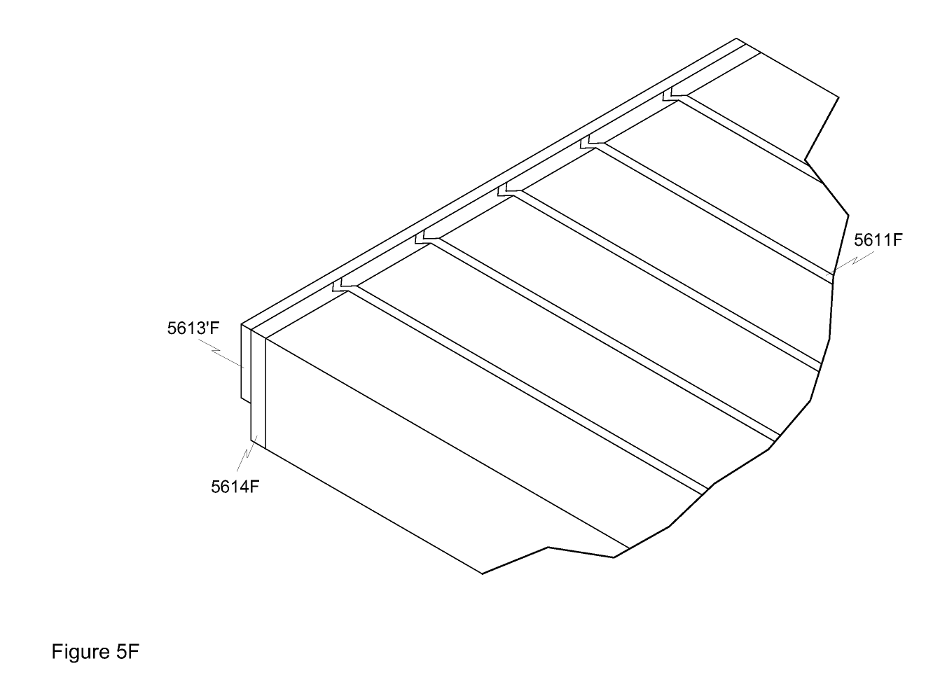

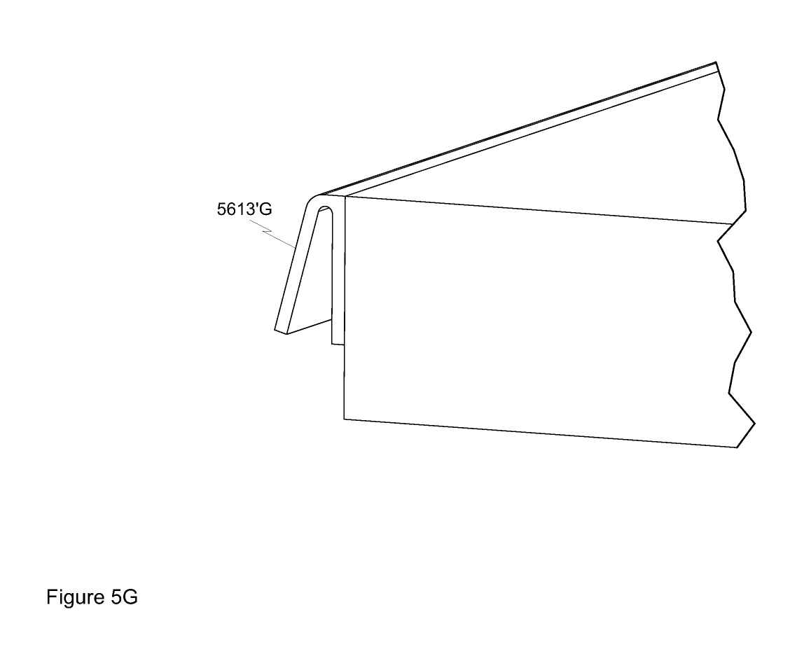

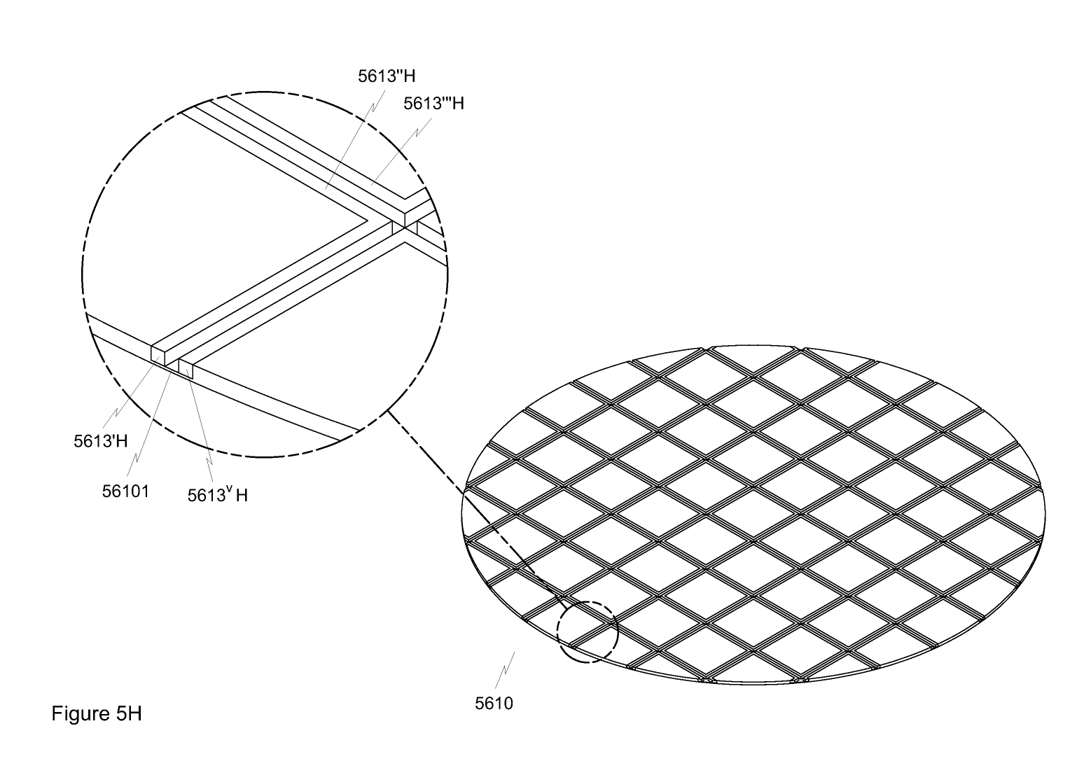

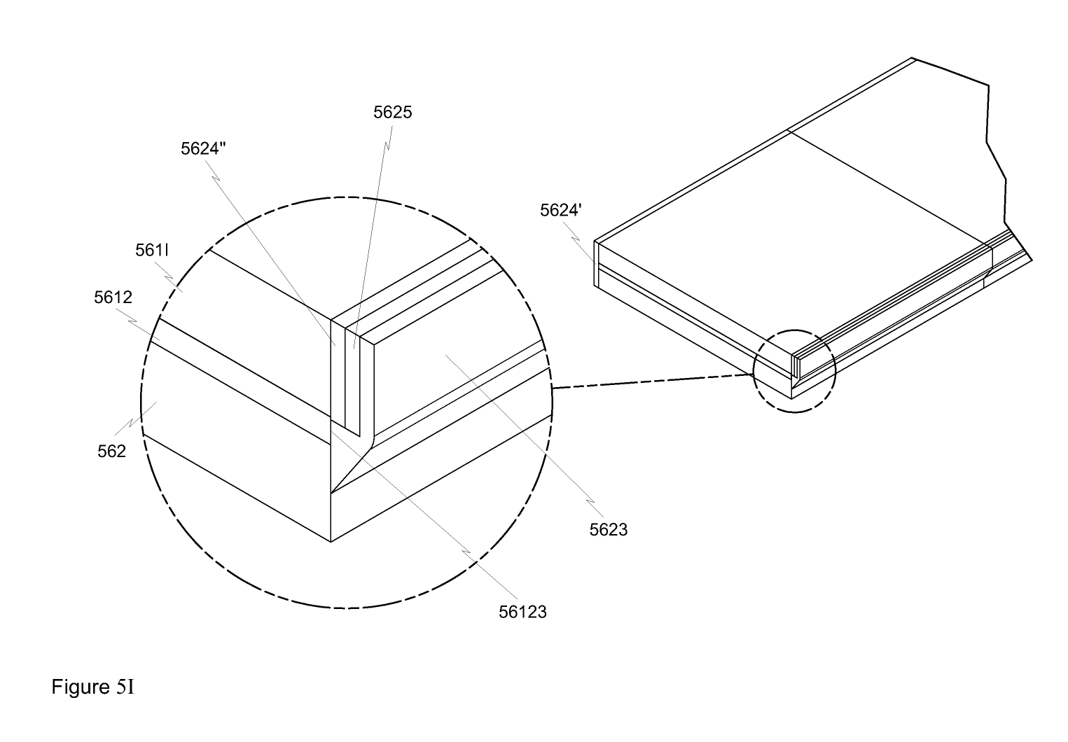

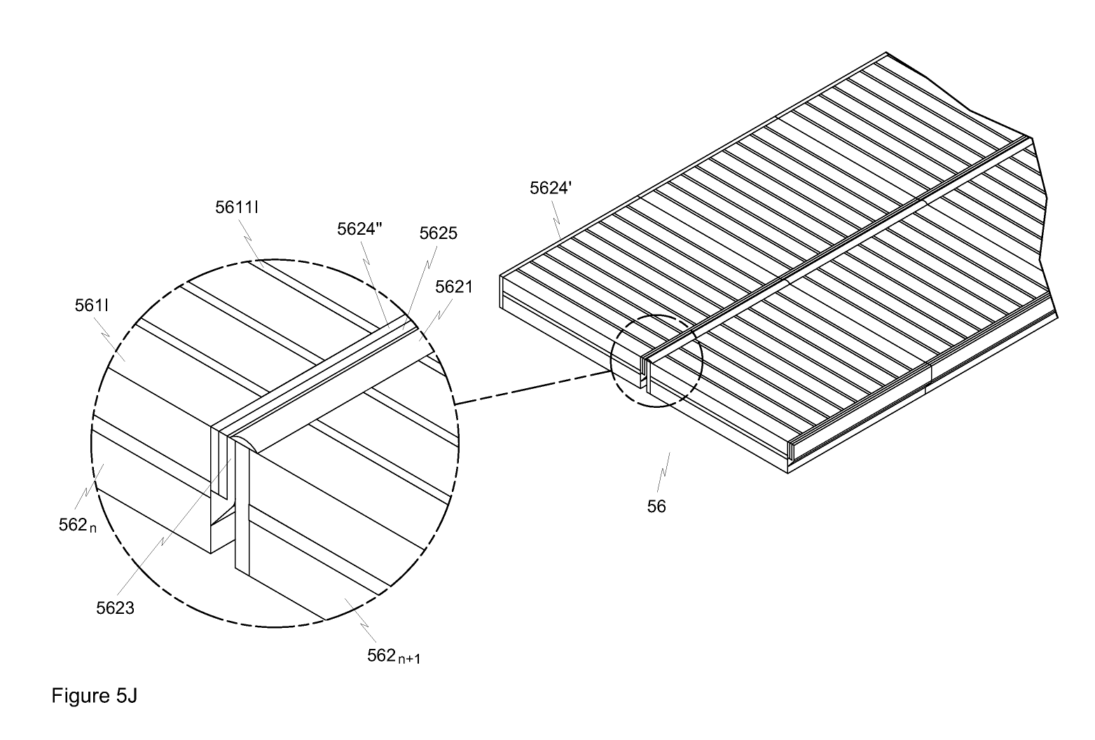

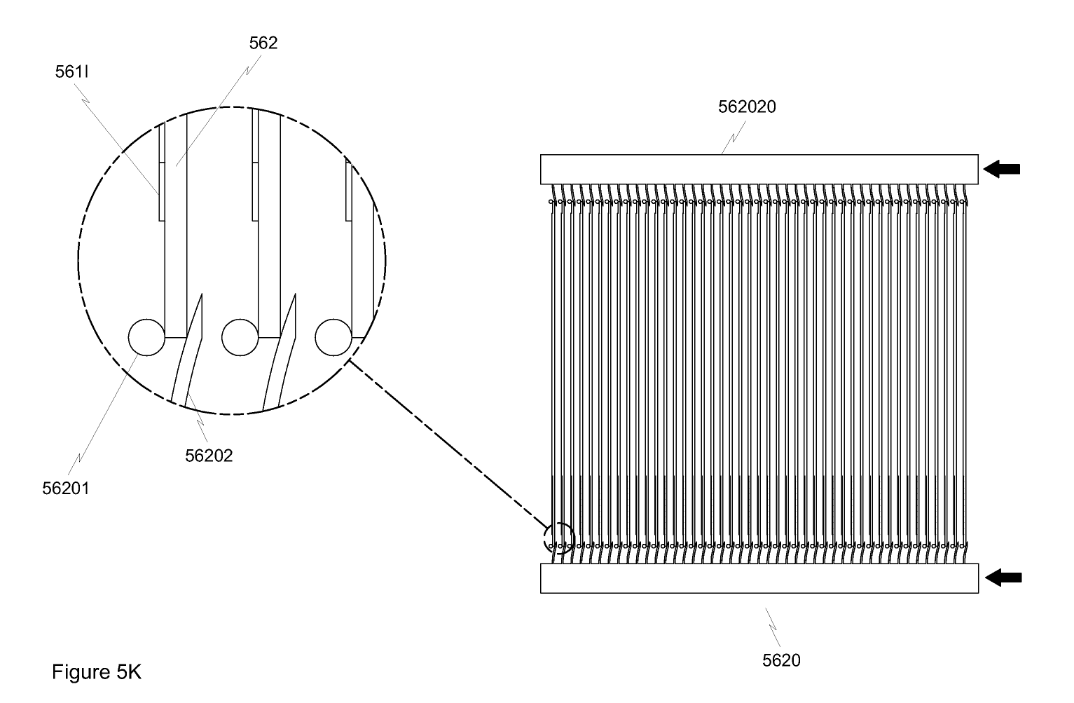

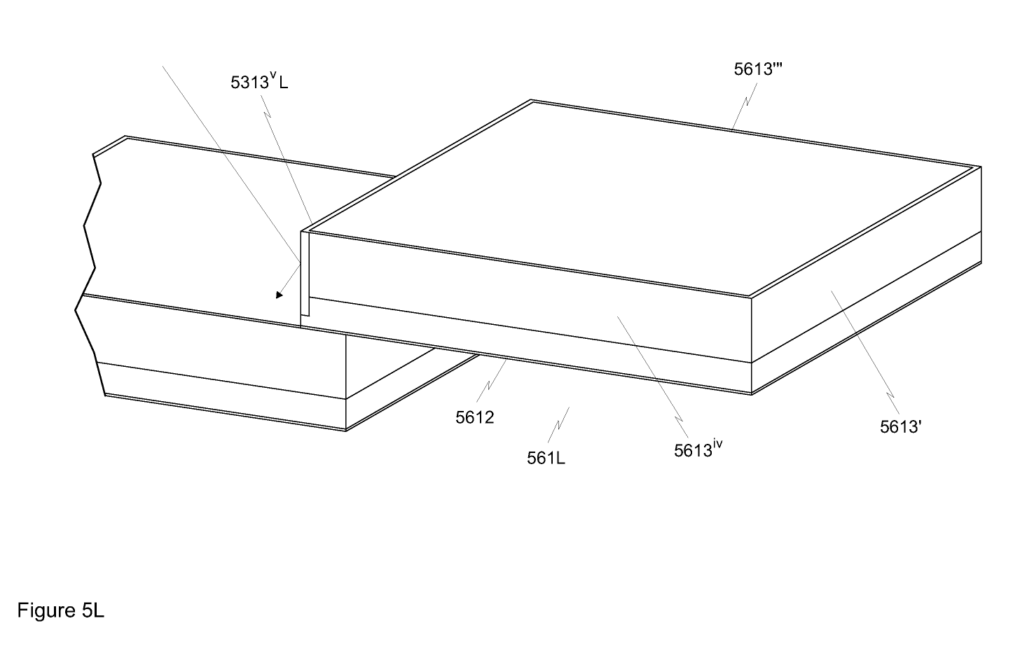

As shown in FIG. 5A, in even further preferred embodiments contacts 5611 are formed in a template 56110, preferably of a high-temperature silicone, and then transferred to a wafer 5610 of cells 561 by pressing the silicone template 56110 onto the wafer 5610. The contacts 5611 may be made by pouring a liquid conductor or pressing a paste conductor such as solder paste into grooves in the template 56110 that are complementary to the desired pattern of contacts 5611, and the liquid or paste can be cured in the template 56110 prior to transfer (e.g., by heat, UV light, catalyst, etc.), or can be cured while the template 56110 is pressed against the photovoltaic cells 561 (which may be the same as cells 361 or 461 or may be different). An intermediate electrically conductive adhesive or low-temperature soldering paste may also be used between the contacts being transferred and the cell surface, particularly when contacts 5611 are hardened or cured before being transferred.

Silicone templates readily release almost all materials and give very high surface quality for soft material being shaped, and they are reusable. Thus even highly silver-filled epoxies can be used to form the conductive cell contacts. High-temperature silicones can also survive molten solder temperatures, allowing extremely conductive silver-based solders to be shaped in this fashion.

Angled contacts with smooth sides as taught by Norman are preferred for cells in systems where the light comes in at near-normal angles. But in concentrating systems that use non-imaging optics that bring some light in at shallow angles to maximize concentration and/or acceptance angle, significantly angled contact sidewalls would reflect this light at even shallower angles, causing much higher reflectance from the cell surface. Silicone is even flexible enough to allow contacts 5611 with near-vertical sidewall profiles to readily release from the template 56110, so for shallow-angle systems still further preferred embodiments of the present invention use contact profiles with near-vertical sidewalls when such cells are intended to be used in concentrating solar systems that bring significant amounts of light in at shallow angles.

In concentrating photovoltaic solar systems where a final refractive optical element is in contact with the cell, a preferred embodiment of the present invention as shown in FIG. 5B forms the contacts 5611B permanently within a template 56110B within the refractive optical element 5251. Such a template may be molded into the optical element 5251 when the element is formed, or it may be etched or carved into the refractive optical element 5251 after the element is formed. The electrical contacts 5611B within optical element 5251 must be electrically coupled to the surface of cell 561B, just as the transparent region of the refractive optical element must be optically coupled to the cell surface. Using a compliant electrical coupling means such as a bead of electrically conductive epoxy 56111 that is narrower than the contact 5611B within the refractive optical element 5251 and extends at least as far as the thickness of the optical coupling agent 56112 (usually a high-clarity silicone) ensures that the electrical coupling means 56111 will make good electrical contact with the surface of cell 561B, and then deform until the optical coupling agent 56111 spreads to make contact with the rest of surface of cell 561B.

Concentrator solar cells typically have one contact covering the back of the cell for one contact polarity, and have one or more wide bus-bar front contacts for the other contact polarity. Such cells are well suited to sparse arrays of cells, where there is room around each cell for a separate wire that connects the bus bar on the front of one cell to the back of another cell, thereby connecting the cells in series. Typically such cells use dual-bus-bar contacts to decrease the distance that electrons must travel through the tiny top-surface contacts, and typically such cells are also placed in parallel with bypass diodes so that defective or poorly illuminated cells can be bypassed and not pull down the performance of the entire cell string.

In a dense receiver array, however, the cells are packed as densely as possible and there is no room for such a separate wire, and such a wire would also have to be cooled or it would melt or oxidize under the intense illumination. Cells for dense receiver arrays thus typically have backside contacts for both contact polarities, allowing the cells to be placed side by side in a dense array as shown in Lasich '456. This, however, requires placing the cells on a substrate containing a complex circuit. In Norman the need for such a circuit is avoided by shingling the back of one cell onto the bus bar on the front of a neighboring cell, thus connecting the cells in series. While shingling of cells in non-concentrating solar systems dates back at least several decades to Vanguard, the first solar powered satellite, Norman matches shingled cells with slanted cooling tubes that allow shingling at the focus of very-high-concentration systems.

But shingling the cells also has its drawbacks. The bus bar covers a few percent of the cell surface, and while the bus bar is in turn covered by active cell area on the next cell, the bus bar still increases the size of the cell and thus reduces the number of cells per wafer and raises the cell cost. Shingling the cells also slants the cells relative to the incoming light, increasing the incidence angle for light from one side and decreasing it for the other side, creating asymmetry in the optics that complicates obtaining an even focus. To eliminate bypass diodes it is also useful to have a number of cells in parallel so that one defective cell can be compensated for by its ‘team mates’ trading a lower voltage for increased current, and this requires connecting cells in a row in parallel. While the cooling tubes of Norman do indeed connect the cells in parallel, this dual use of the cooling tubes requires the cooling tubes to be at the same voltages as their cells, increasing corrosion. There is therefore a need for a way to connect cells in parallel and in series without having the cells electrically coupled to a substrate and without shingling them.

As shown in FIG. 5C, a preferred embodiment of the present invention therefore provides improved cell contacts that utilize one or more of the side faces of the cell 561C. While numerous side contact patterns that would allow cells to be placed in parallel and in series by pressing the cells against each other are possible, in further preferred embodiments one side of cell 561C comprises a contact 5613′ electrically connected to the cell's top contacts 5611C while the opposite side of cell 561C comprises a contact 5613″ electrically connected to the cell's back-side contact 5612. In even further preferred embodiments, the side contact 5613′ that is connected to the top contacts 5611C of cell 561C covers a the top portion of its side of the cell, leaving the bottom of that side free from conductive material of contact 5613′, and the side contact 5613″ that is connected to the bottom contact 5612 of the cell covers a bottom portion of its side of the cell while leaving the top of that side free. If the sum of the heights of the top portion side contact 5613′ and the bottom portion side contact 5613″ is greater than the thickness of the cell 561C, the top portion contact 5613′ of one cell 561C will overlap and thus connect to the bottom portion contact 5613″ of another cell 561C, thus connecting the cells in series, if cells these contacts' sides pressed against each other.

The other two sides of the cell can either both have contacts connected to the cell's side contact 5613′ or to the cell's bottom contact 5613″, or could have a top portion connected to the cell's side contact 5613′ and a non-overlapping bottom portion connected to the cell's contact 5613″. Any of these allows the cells 561C in a row of cells to be connected in parallel by pressing them against each other so that the side with contact 5613″′ of one cell is pressed again the side with contact 5613^{iv} of its neighbor. It is more preferable for side contacts 5613″′ and 5613^{iv} to be electrically connected to side contact 5613′ because that can be used to shorten the average distance that current has to flow in the thin top contacts 5611C by using side contacts 5613″′ and 5613^{iv} as bus bars for the top contacts 5611C. For a current triple junction cell 561C that is 5 mm wide from side contact 5613′ to side contact 5613″ and 10 mm long from side contact 5613″′ to side contact 5613^{iv}, designing top contacts 5611C to take advantage of extra ‘bus bars’ provided by 5613″′ and 5613^{iv} will result in a roughly 1% improvement in the efficiency of the cell.

As shown in FIG. 5D, it is even possible to have a side contact 5613^{v} on the same side as contact 5613″ that is electrically connected to the top contacts 5611D, and to the other side contacts (such as 5613″′) that are connected to the top contacts. However this side contact 5613^{v} must be electrically insulated both from bottom side contact 5613″, which is on the same face of the cell, and from the contact top side contact of the cell that its side of the cell will be pressed against, in this example by insulator 5614. For a current triple junction cell 561D that is 5 mm wide by 10 mm long, designing top contacts to take advantage of extra the ‘bus bar’ of contact 5613^{v} will result in an additional roughly 1% improvement in the efficiency of the cell.

As shown in FIG. 5E, in all of the above preferred embodiments, it is exceptionally preferred for each side contact (such as 5613′E) to have a very thin electrically insulating layer 5614E separating it from the body of the cell, avoiding leakage through the semi-conducting material of the cell 561E. As shown, the top contacts 5611E must cross over any insulation for each side contact that is to be used to carry current for the top contacts.

As shown in FIG. 5F, in exemplary embodiments the insulating material 5614F on at least one of cell side contacts, either 5613′F or the contact (not shown) on the opposite side of cell 561F, provides some compliance for the conducting material so that even if the cells 561F expand less than or shrink more than the substrate they are on, electrical contact will be maintained. In this case top contacts 5611F are kinked to allow them to flex as the cells expand and contract with temperature.

Alternatively the conductive side contact itself can be compliant to maintain the contact, either by using an elastomeric contact, or, as shown in FIG. 5G, more preferably a springy metallic contact 5613′G. If the springiness of the compliant contact is enough to push the cells apart during receiver assembly, a contact adhesive or a quick-setting adhesive can be used to hold the cells together during assembly.

The compliance needed is determined by the cell width, the temperature change and the difference in thermal expansion of the materials, and may be calculated by techniques well known in the art of thermal expansion. For example, most triple junction cells are made on a germanium substrate with a thermal coefficient of expansion of 5.9 ppm/° C., and a highly thermally conductive, electrically insulating interposer such as aluminum nitride has a thermal coefficient of expansion of 4.5 ppm/° C., for a difference of 1.4 ppm/° C. If the cells are affixed to the interposers with an adhesive that cures at 150° C. and the system may be exposed to temperatures as low as −50° C., then the temperature difference can be as large as 200 degrees, for an expansion difference of 280 ppm. For a cell 5 millimeters wide this would be 0.000280*5 millimeters or 1.4 microns of compliance needed. If, however, the cells are on copper with a thermal coefficient of expansion of around 16 ppm/° C., the difference is around 10 ppm/° C., and the compliance needed is around 10 microns.

Techniques well known in semiconductor manufacturing can be used to create the insulating and conducting layers. Copper is preferred for a conductor because of its electro-migration resistance, allowing a conductive layer less than a micron thick to be used. The cell side contacts of this family of preferred embodiments of the present invention can be made on individual cells, or can be made for individual cells on a wafer full of cells before dicing the wafer. ‘Streets’ are often etched deep into the wafer surface where the wafer will be sawn, and as shown in FIG. 5H, cell side contacts 5613′H, 5613″′H, 5613^{iv}H and 5613^{v}H can be deposited at the sides of streets 56101 before the wafer 5610 is diced. The bottom side contact (not shown) could be made in a street on the bottom wafer).

The cell side contacts of this family of preferred embodiments of the present invention can also be made on a row of cells on an interposer after the cells are mounted on the interposer. As shown in FIG. 5I, a preferred way to do this is to deposit an insulating layer 5624′ on one side of a row of cells 561I on interposer 562. Another insulating layer 5624″ is deposited on the opposite side of the row of cells 561I on interposer 562, either leaving bare or later removing insulator to expose the edge 56123 of the bottom contacts 5612 of the cells 561I. A sacrificial release layer 5625 is deposited on insulating layer 5624″, again either leaving bare or later removing release layer to expose the edge 56123 of the bottom contacts 5612 of the cells 561I. Finally contact 5623 is deposited on release layer 5625 and on the exposed edge 56123 of the bottom contacts 5612 of the cells 561I, thus establishing electrical contact between bottom contacts 5612 and interposer side contact 5623. The layers thicknesses in FIG. 5I have been greatly exaggerated for clarity, and the insulating and release layers will typically be at most a few microns thick.

As shown in FIG. 5J, during assembly of a dense receiver array 56 numerous interposers 562 (of which 562ₙ and 562ₙ₊₁ are shown) of cells 561I will be placed side by side. A bead 5621 of either electrically conductive adhesive or more preferably solder can be run along the tops of the interposers 562 of cells 561I to bridge and thus connect the top edge of interposer side contact 5623 to the top contacts 5611I (which may be top contacts 5611 or 5611C, or may be other suitably top contacts) of the cells on the neighboring interposer, thus placing the interposers of cells in series and the cells on each interposer in parallel. A variety of compounds suitable for release layer 5625 are known, with compounds used as release layers in MEMS devices and that dissociate under low heat are preferred so that during soldering or curing of the electrically conductive adhesive, interposer side contact 5623 is released from insulating layer 5624″, allowing it to flex slightly to maintain contact with top contact 5611I of the neighboring interposer even as the cells 5611 shrink slightly upon cooling from solder reflow or adhesive cure temperatures. It should be noted that because the side contact 5623 will serve as a bus bar for the top contacts 5611I of the next cells, the bus bar on the top of cell 561I can be much narrower than normal, or can even be absent if the adhesive or solder 5621 will not damage the top of the cell; this reduces cell cost by minimizing the cell area.

Upon reading the above, numerous variations will suggest themselves to those familiar with the relevant art. An insulating layer 5624″ that adheres strongly to the bodies of cells 561I and only weakly to interposer side contact 5623 could eliminate the need for the release layer, although the release layer provides much more control over the release. A cell substrate that repels solder or that does not wick conductive particles from the electrically conductive adhesive could allow an additional insulating layer to be deposited on top of interposer side contact 5623 to allow eliminating insulating layer 5624′, thus keeping all interposer processing on a single side of the interposers 562. Insulators can be thermally conductive for improved overall cooling. Long interposers can be processed and then separated into interposers the width of the receiver. The interposers can have metal pre-applied in patterns that minimize the precision needed in adding layers to the interposers full of cells. The top contacts for the cells can be formed in wafer streets and then thickened while the cells are on the interposer to protrude beyond the cell kerf, etc.

In exemplary embodiments of the present invention, many interposers of cells are placed on edge in a block to allow using lithographic processing tools and techniques more economically. With the voltages of today's high-efficiency III/IV cells and the size of dishes taught by Norman, receivers with 80 to 100 cells placed in series allow two receivers in series to achieve the ideal voltage for feeding current utility-scale inverters. As shown in FIG. 5K, with interposer 562 of cells 561I less than one millimeter thick and 100 millimeters long, more than 100 interposers 562 of cells 561I can be placed in a jig 5620 and fit within the processing area of semiconductor equipment designed for processing 150 millimeter wafers. This can greatly reduces the cost of applying insulating, conducting and release layers to the sides of interposers 562 of cells 561I by allowing application to a whole receiver or more of interposers at a time rather than processing them individually. Jig 5620 preferably has a stop 56201 for each interposer and a mechanism such as comb 562020 with teeth 56202 that hold what will be the tops of all interposers 562 against their respective stops 56201 to ensure that the adding of layers can proceed with the tops of all cells known positions relative to the body of the jig 5620.

While cell side processing has been taught above in the context of producing side-contact cells that avoid shingling of cells, cell side contacts that are connected to the cells top contacts, as shown in FIGS. 5C and 5D, can give the same performance boost to shingled cells as to un-shingled cells. Also, metalizing the side opposite the bus of a to-be-shingled cell will in general increase the reflectivity of that face of the cell. In today's ultra-efficient cells the most current-limited junctions are on the top of the cell, so light entering the side of the cell misses the most important junctions. Thus reflecting this light onto the surface of the adjacent cell improves the overall efficiency. As shown in FIG. 5L, preferably this reflector 5613L^{v} also serves as a conductor contacting the top contacts of cell 561L to shorten the path that electrons must take in the higher-resistance cell top contact lines, and thus further improving cell efficiency. To connect this side contact 5613L^{v} to the contacts that will be shingled, side contacts 5613″′ and or 5613^{iv} are preferably used, along with side contact 5613′ if a top bus bar is not used. Side contact 5613L^{v} is distinguish from side contact 5613″ in that it is connected to the cell's top contact rather than the cell's bottom contact, and is distinguished from cell side contact 5613^{V} in that a cell being shingled has no used for a side contact connected to the cell's bottom contact, and hence cell side contact 5613L^{v} preferably covers the vast bulk of its side of the cell, leaving only enough un-metalized space at the bottom of the face to avoid shorting to the cell's bottom contact or to the top contact of a cell that the cell is shingled to. Preferably cell side contact 5613L^{v} is of or is coated with a highly reflective metal such as aluminum or silver, and preferably it is insulated from the body of the cell itself (not shown, but similar to FIG. 5E).

### Sixth Family of Preferred Embodiments

### Semi-Dense Array for Improved Cooling and Acceptance Angle with a Small Area of Moulded Optics

While Norman teaches and the present application improves on very high concentration systems with even foci that use no moulded optics, the dense receiver arrays that these use leave no room around the cells to spread the heat for easier cooling. Using entirely reflective optics also does not take advantage of the high acceptance angle possible for a given concentration provided by refractive optics in contact with (or optically coupled to) the cell surface. Dense receiver arrays also need either a very even focus, complicating the optics by requiring careful coordination of the curve of the rails and a curved secondary concentrator, or different areas of cell in series to compensate for an uneven focus, complicating manufacturing. And even Norman's even focus as improved upon in the present application provides a focus that is even only in one direction, meaning that some cell will be more illuminated than others, precluding having optimal illumination for all cells.

On the other hand current systems that use refractive optics in contact with the cells have sparse arrays of cells, with each cell having its own collection primary optics, spread over an area approximately as large as the system's aperture. This has its own set of drawbacks, requiring extensive inter-cell wiring, bypass diodes to handle both defective cells and shading of some cells, and complex assembly of sealed module area as large as the system's aperture.

There is thus a need for a high-concentration photovoltaic systems that combines the simple primary optics of Norman with a receiver less dense than a dense array to allow improved or less expensive cooling, that use refractive optics in contact with (or optically coupled to) the photovoltaic cells to obtain a higher acceptance angle for a given tolerance, and that provides very even illumination for all cells rather than just even average illumination for sets of cells.

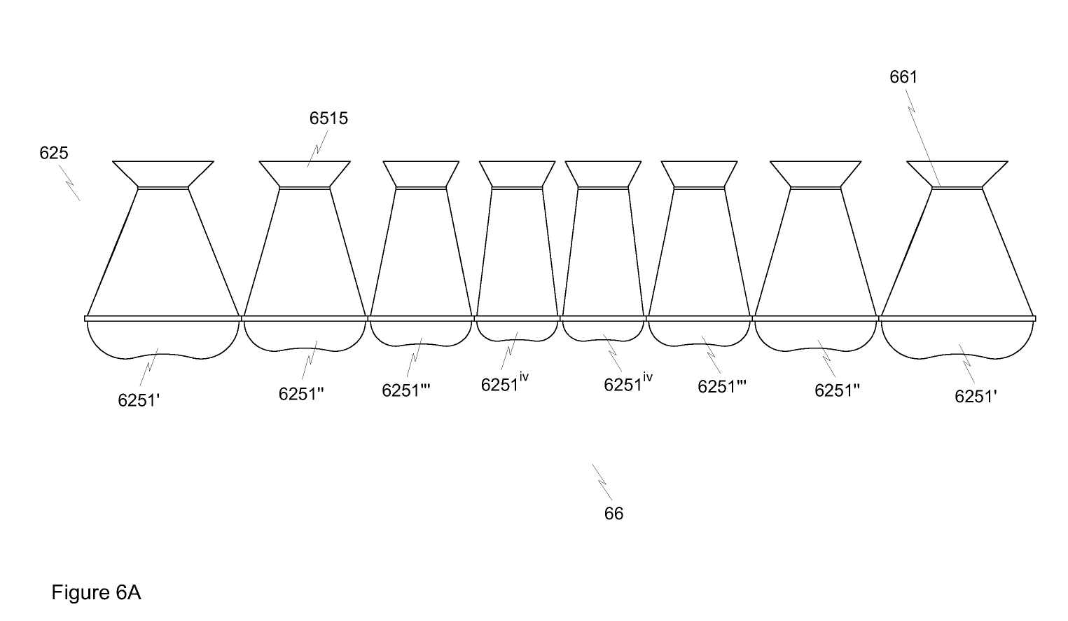

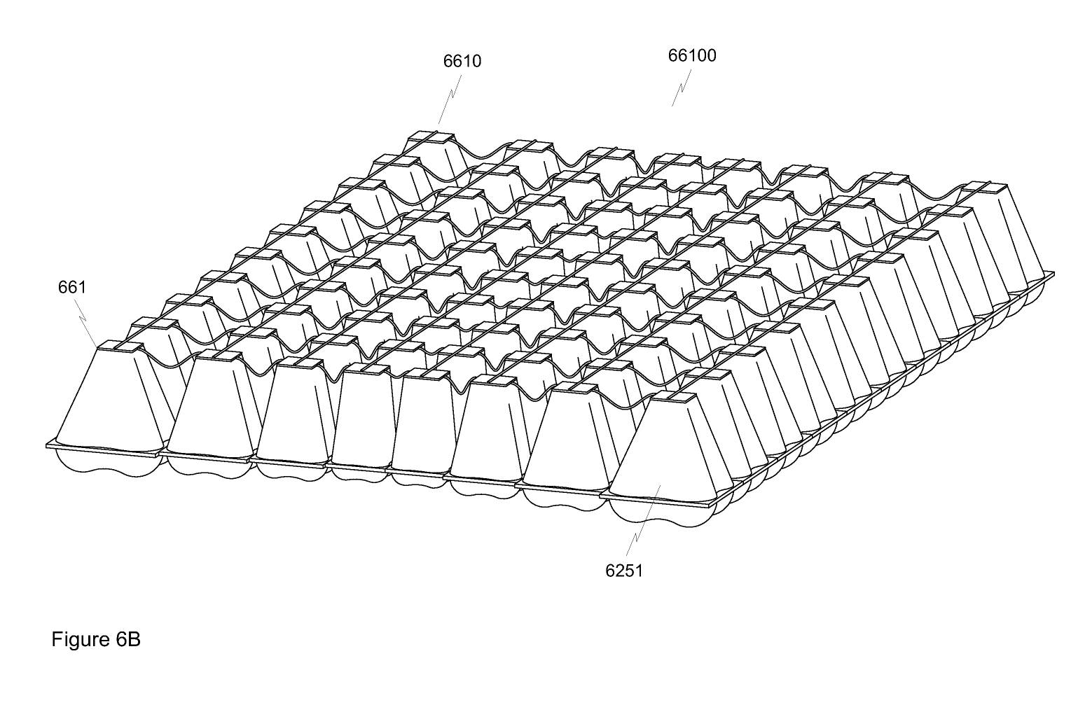

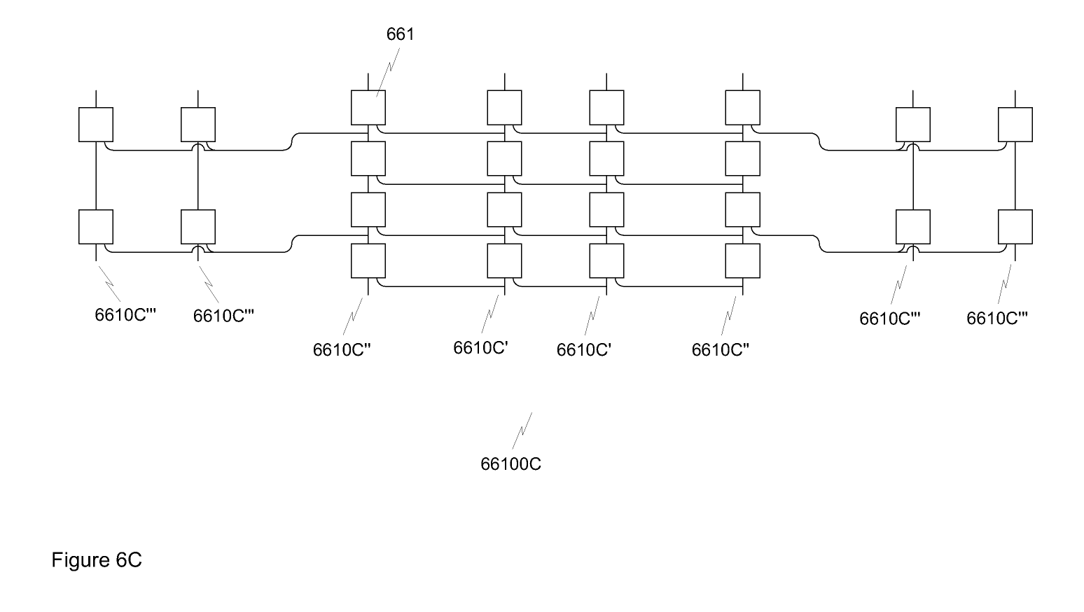

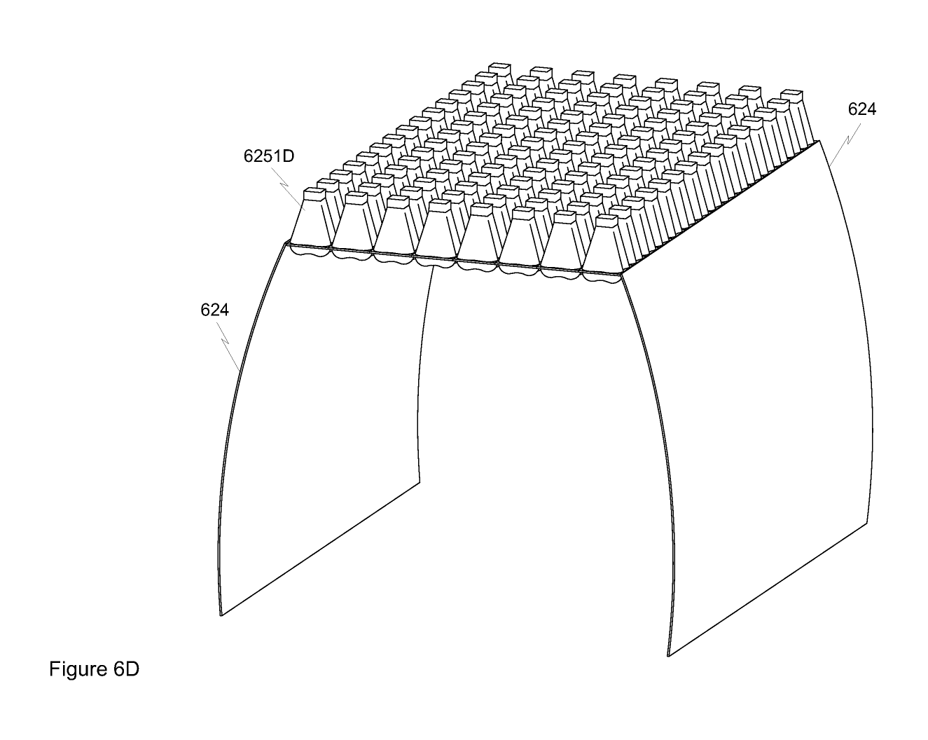

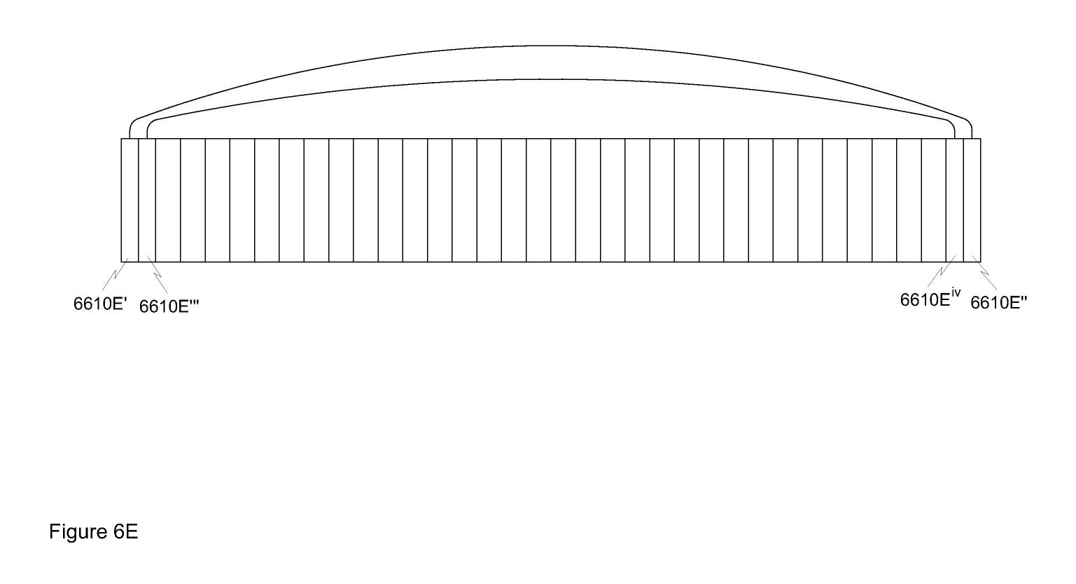

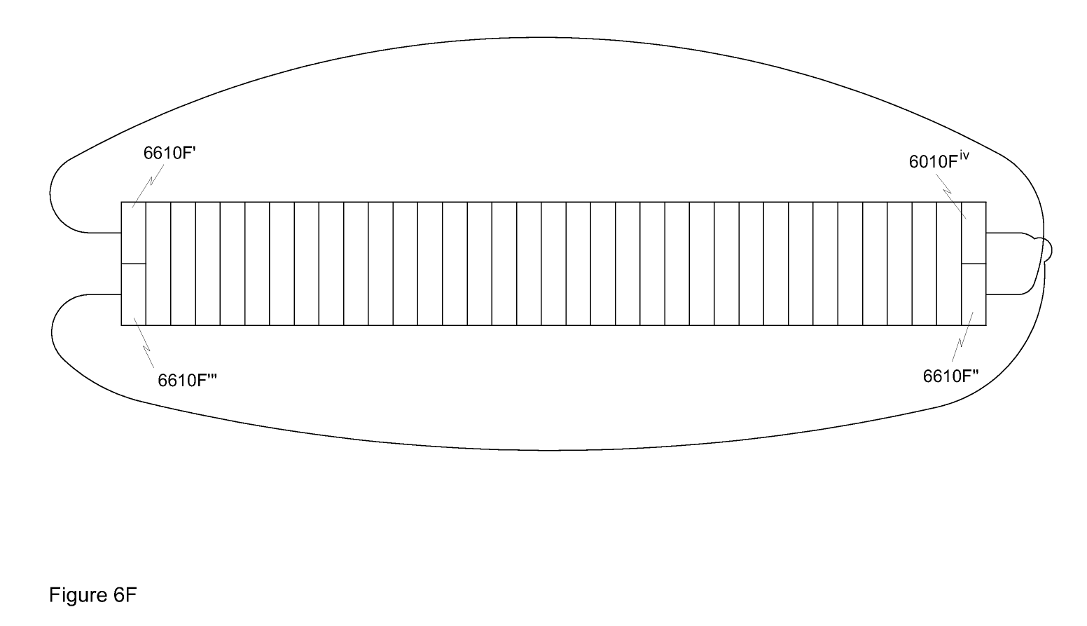

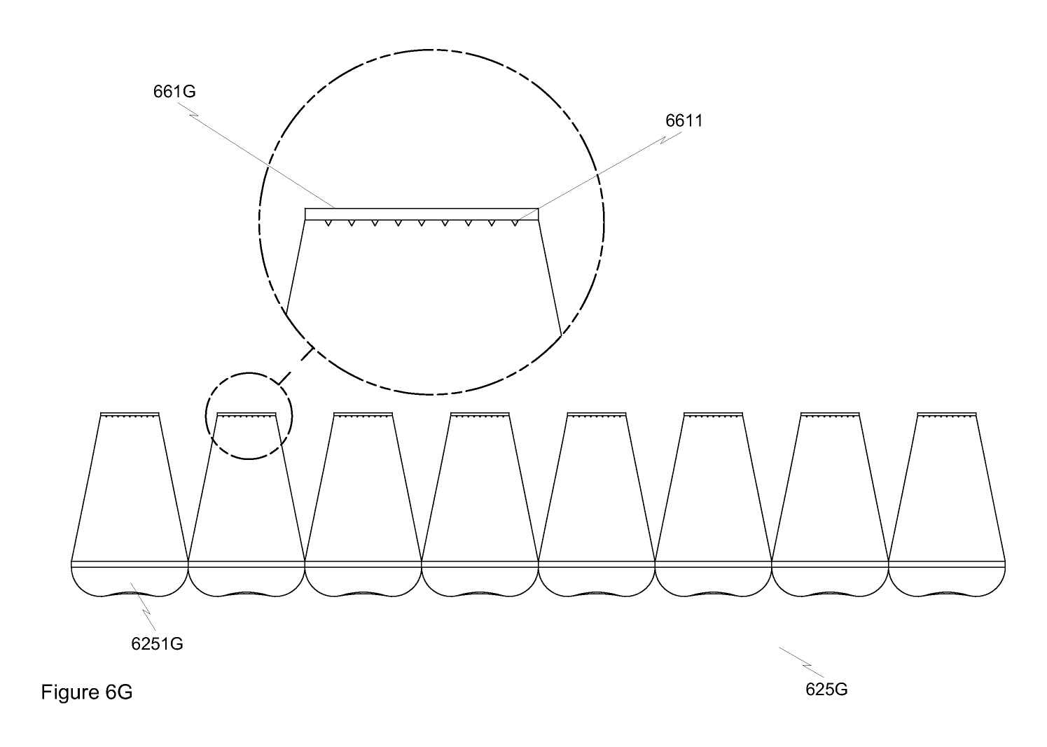

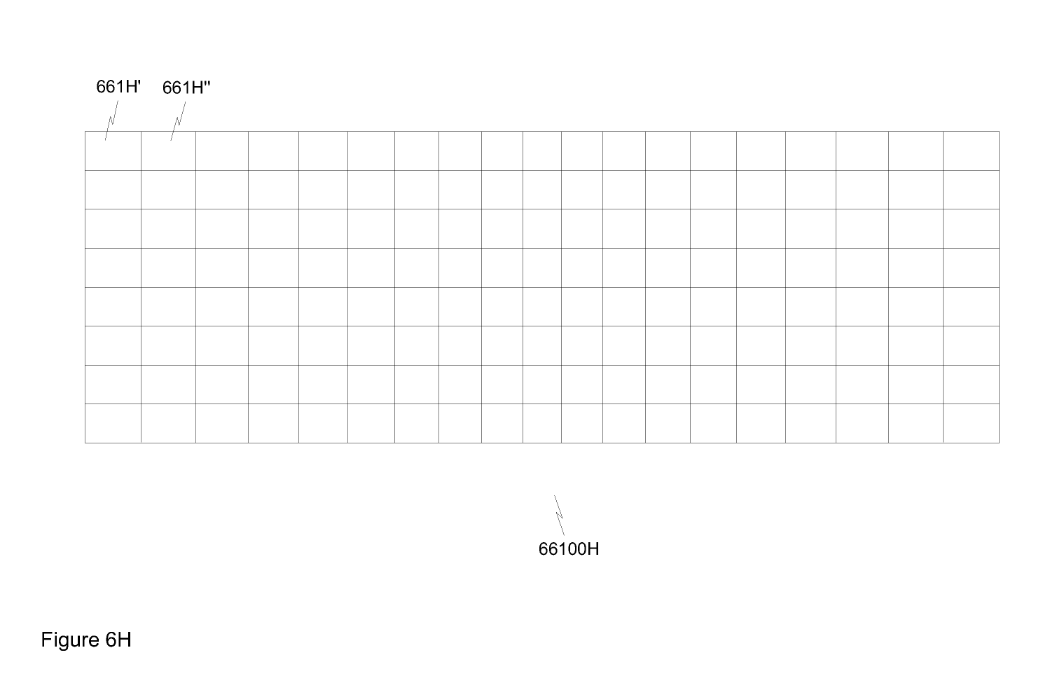

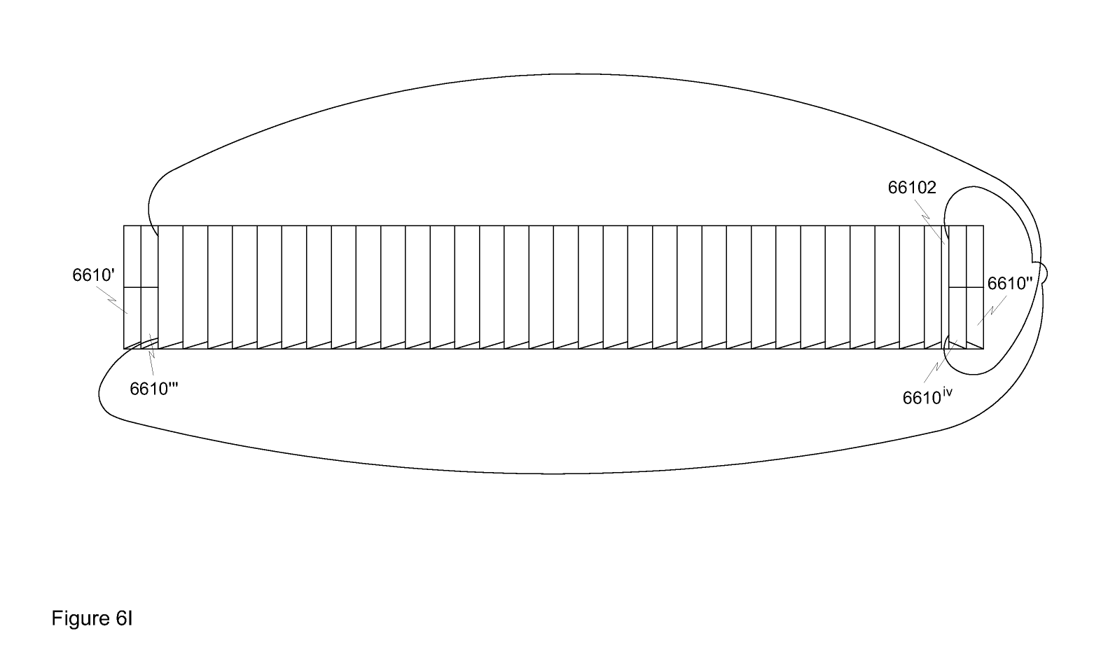

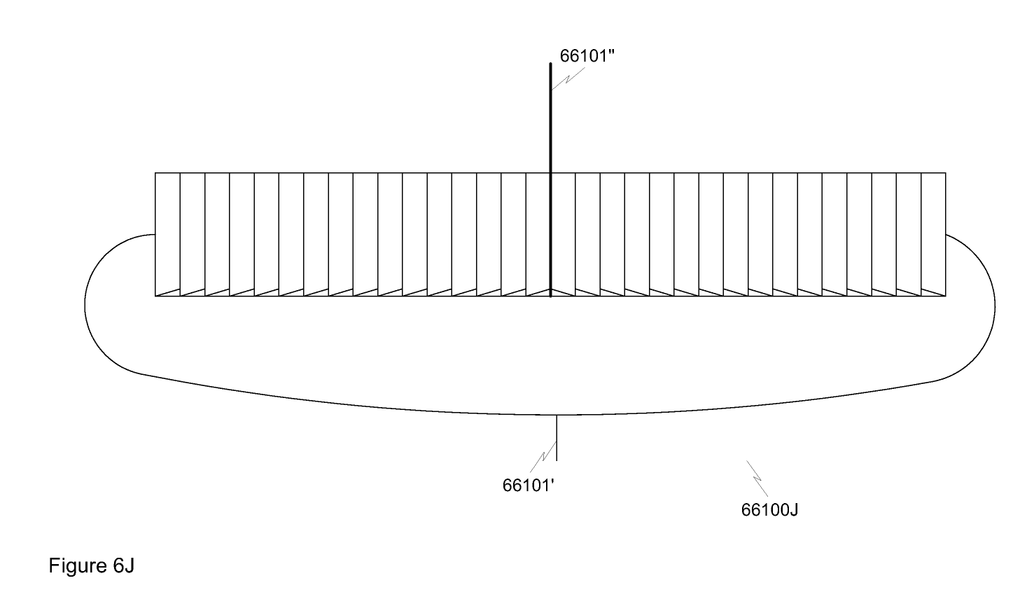

A preferred embodiment of the present invention therefore provides a semi-dense receiver array that uses an area of moulded optics far smaller than the area of the system's primary concentrator aperture, yet provides sufficient spacing between cells for improved cooling. As shown in FIG. 6A, instead of secondary concentrators and a dense receiver array, a multi-cell refractive concentrating receiver 66 is used that has a size equal to the size of the focal spot of the primary concentrator. While the total area of cells 661 (which may be the same as cells 361, 461, 561 or preferably 561B, or may be other suitable cells) in the semi-dense receiver array 66 remains the same as it would have been in a dense receiver array at the same final concentration, the cells 661 are spread out over an area several times larger, providing area around each cell 661 for a heat spreader 6515 to increase the area for the cooling tubes to draw heat from. Each cell 661 is provided with its own refractive final optical element 6251′, 6251″, 6251″′ or 6251^{iv} that further concentrate the light, but because the array 625 of final optical elements 6251′, 6251″, 6251″′ and 6251^{iv} is hundreds of times smaller than the area of the primary concentrator, the array of final refractive optical elements 625 can be moulded as a single piece. Array 625 can also be moulded as a few small pieces when that is more cost-effective, with two identical pieces being preferred to take advantage of the symmetry of most primary concentrators. Similarly the array of heat spreaders can be molded as one or a few pieces, or each nominally identical cell may have a nominally identical heat spreader pre-attached.

Because the insolation is lower around the edges of primary focal spot (not having been evened out by secondary concentrators and/or careful tailoring of the curve of the rails), the refractive optical elements 6251′, 6251″, 6251″′ and 6251^{iv} are proportionately larger at the edges of the array and further concentrate the light more so that all cells 661 can be identical in size and can receive the same total illumination.

Since the refractive optical element array 625 can be molded in one piece or two identical pieces, having different sized optical elements 6251 within the array need not increase the assembly complexity and only has a modest impact on the one-time tooling cost for molding the array 625. Having less than one square meter of moulded glass in the refractive optical element array 625 for every hundred square meters of collector area in primary concentrator 60 makes the cost of molding arrays 625 insignificant.

As shown in FIG. 6B, the cells 661 in a row of cells 6610 can still be placed in parallel and the rows of cells 6610 can still be placed in series as taught by Norman, and the insolation on each cell 661 can be the same as the average insolation was before, but each cell 661 now has several times the area around it for a heat spreader (for clarity, not shown in FIG. 6B), making the cooling far simpler. As a rule of thumb, the heat from 1000 suns concentration onto current high efficiency cells is about 60 Watts per square centimeter, which in copper at 4 Watts per centimeter per degree Kelvin (4 W/cmK) means a temperature increase of 1.5° C. for each millimeter of copper that the heat must flow through. With copper, therefore, a cell's heat spreader (not shown in FIG. 6B to more clearly show inter-cell connections but substantially the same as heat spreader 6515 as was shown in FIG. 6A) should only be a few millimeters on a side bigger than the cell 661 itself. While this does not sound like much, the largest concentrator cells are 10 mm×10 mm, and many concentrator cells are 5 mm×5 mm; a heat spreader 2.5 mm larger in all directions than the cell, for example, more than doubles the area for heat to be removed from a 10 mm×10 mm cell and quadruples the area for heat to be removed from a 5 mm×5 mm cell.

In more preferred embodiments arrays 66100 of cells 661 will in general have a density at least two to four times less dense than a dense array in order to provide room for the heat spreaders and to allow the refractive optical elements 6251 to increase the acceptance angle of the system. On the other hand, to keep the cost of the moulded optics 625 small and the inter-cell wiring distances short, such arrays 66100 are still much denser than sparse arrays, preferably at least ten times denser and more preferably at least 100 times denser than sparse arrays (i.e. arrays 625 are preferably at least 10 times smaller and more preferably are at least 100 times smaller than the overall light collecting area of the primary concentrator's aperture area). Such arrays are therefore referred to herein as semi-dense arrays.

The basic shape of the refractive optical element can be any of the final optical element shapes well known in the art. In particular shapes known in the art of secondary optical elements for Fresnel lens based systems are preferred, such as Spherical Dome, SILO, Refractive ITP, and Kohler (“High-performance Kohler concentrators with uniform irradiance on solar cell”, Hernandez, et al), because they are designed to take light coming in at comparable angles and intensities to the light coming in to the primary focus (where the sparse receiver array optics are located). Companies such as LPI LLC and SAIC International also provide refractive optical element design services that can tailor a design to meet specified criteria such as maximizing the efficiency, uniformity and acceptance angle of a given overall design based on aperture size, incoming light and desired concentration.

As shown diagrammatically in FIG. 6C, in general the number of cells 661 per row of cells will be kept constant, so for areas of more diffuse insolation the apertures of the final refractive optical elements will grow proportionately in one direction but remain constant in size in the other direction. Thus the width of the rows grows from row 6610C′ to row 6610C″ to provide more room for the wider final refractive optical element that in turn compensate for the lower insolation. However to keep that aspect ratio of the final refractive optical elements at the edges of array 66100C from growing extreme as the light intensity drops, if the light falls to less than half as intense, two rows 6610C″′ of cells 661 will be put in parallel to keep the rows from becoming too wide and half as many cells per row will be used (to keep the overall concentration on the cell the same). Thus rather the aspect ratio of the final refractive optical element growing from 1:1 up to a maximum of 2:1 before the narrower rows of fewer cells changes it to 1:2, whence it can continue growing until at a 4:2 aspect ratio (already covering an 8-fold variation in intensity across the focal region), at which point the number of cells per row would be cut again. If desired, the maximum aspect ratio of the aperture of the final refractive optical element can easily be held to 1.4:1 by cutting the number of cells per row in half twice as often. The number of cells per row could even be adjusted every row, but this creates either variation in concentration per cell, mismatched photocurrents between rows, or the complexity of putting partial rows of cells in parallel.

It is simpler but not necessary for the rows put in parallel to have the same width or the same number of cells. For example, when the intensity for a receiver with nine cells in a row falls to less than half, instead of making a nine-cell row where the cells are more than twice as wide the row could be into a five-row and a four cell row placed in parallel. What is of most importance is for the total area of the refractive final optical elements for the cells in parallel to be sized substantially inversely proportionately to the intensity so that the cells in parallel generate substantially the same maximum-power-point photocurrents under typical operating conditions as other sets of cells they are in series with. Therefore when multiple rows of cells are electrically connected in parallel, and are as a set connected in series with other sets of cells (typically but not necessarily comprising one or more rows of cells per set), and refractive final optical elements per cell are used, the total aperture area of the refractive final optical elements for a set of multiple rows of cells multiplied by the intensity of the light on that aperture area is substantially equal to the product of the aperture area time the intensity of the light for the other sets of cells said set is connected in series with. Preferably the individual refractive final optical elements are also sized substantially proportionately to the intensity (or to the intensity times the cell area if different sized cells are used) so that all of the cells receive substantially the same concentration, but this is of lesser importance.

When the cells have different efficiencies (for example, due to cell temperature or due to using cells sorted into different efficiency ranges), it is the sum for a set of cells of the product for each cell of the light intensity times the aperture area times the cell's efficiency that should be substantially equal to the like sum for other sets of cells with which the given set is to be placed into series. To be even more general, when the cells further have different current/voltage curves, the apertures of the final refractive optical elements are sized so that the sum of the photocurrents of the cells in the set is substantially equal to the sum of the photocurrents of the other sets of cells that the given set is to be placed into series with.

As shown in FIG. 6D, reflecting the diffuse light from the edges of the focal regions with secondary concentrators 624 allows greater uniformity in the refractive optical element size, and also prevents a sharp drop-off in the light if the tracker is misaligned. Even secondary concentrators with single flat facets would greatly reduce the rate of drop-off on tracker misalignment, but compound parabolic curve secondary concentrators 624 provide the highest acceptance angle for any given concentration. With the maximum concentration possible for any given acceptance angle rising by the square of the index of refraction of the final refractive optical element, or typically 1.5*1.5=2.25 for glass final optical elements, concentration can either be doubled to take advantage of the easier cooling afforded by the heat spreader, or concentration can be traded off for greatly increased acceptance angle. As taught earlier, a primary concentrator and secondary concentrators can work together to produce a very even focus, in which case all final refractive optical elements 6251D can be identical. But the additional parameter of the aperture size of the final refractive optical element means that the focus does not have to be as even. Further preferred embodiments can take advantage of this to use a compound parabolic curve secondary reflector that starts at a steeper angle, eliminating the very low angle of incidence light that a flatter secondary produces.

Since the use of compound parabolic curve secondary concentrators to produce an even focus also produces an intensity profile along the receiver that increases almost as rapidly on one end of the receiver as it decreases on the other when the tracker is misaligned in that direction, even further preferred embodiments, as shown schematically in FIG. 6E, place the end-most row on each end of the receiver, in this case row 6510E′ and row 6510E″, in parallel, and the second-to-end rows 6510E″′ and 6510E^{iv} in parallel, etc., so that moderate misalignment of the tracker has a greatly reduced effect. This is continued for enough rows to cover the tracking inaccuracy of the tracker. For example, with a 5.7 meter primary focal length each 0.1 degrees of tracker misalignment shifts the focus by about one centimeter, and this is stretched 1.5× to 2× by the lower-angle reflection from the secondary concentrator, so if the end rows have primary apertures two centimeter wide, putting just one end row from each end in parallel is sufficient for a tracker of 0.1 degree accuracy.

The width of the optics for these rows can then be adjusted so that the photo current when the tracker is pointed correctly is equal to the other rows of the array. For an even focus, this requires the rows to be half width. Alternatively, as shown in FIG. 6F, opposite full-width half-rows 6610F′ and 6610F″ are cross-coupled in parallel, as are full-width half-rows 6610F″′ and 6610F^{iv}, so that the sum of the photocurrent from the two half-rows will be relatively constant in spite of minor tracker misalignments in either the direction of the length or the width of the array. (For clarity only the outside edge connections of the cross-coupled rows have been shown in FIG. 6F; see FIG. 6I for the inside-edge connections).

As shown in FIG. 6G, combining a monolithic semi-dense array 625G of refractive final optical elements 6251G in conjunction with cell top contacts 6611 for cells 661G embedded in the final refractive optical elements (in this case elements 6251G), as taught earlier in the present application, is also a preferred embodiment of the present application.

While the use of different sized final optical elements has been taught in the context of semi-dense arrays, as shown in FIG. 6H an analog of this is a preferred embodiment for used with dense arrays 66100H for uneven focal intensity by using cells 661H′, 661H″ etc. that are proportionately wider in regions of lower intensity. While this requires placing cell of multiple widths, complicating assembly of the receiver, modern pick-and-place equipment can handle numerous component types so this is only a minor obstacle. Using rows of cells in series where the width of the cells 661H′, 661H″, etc., in a row is inversely proportional to the average insolation intensity on that row is further preferred. Even further preferred embodiments also take into account that the cells have slightly different efficiencies at different intensities, and optimize the cell widths so that the rows have equal maximum-power-point photocurrents under typical operating conditions.

Similarly while combining the end rows of the array in parallel for one or more rows to reduce the effects of tracker misalignment has been taught in the context of semi-dense arrays, an analog of this can be used with dense arrays as well and forms a preferred embodiment of the present application. Cross coupling of one or more half-rows at the ends of the array, as shown in FIG. 6I, is even more preferred. When shingled cells or side-contact cells are used for more than one row on each end, this requires reversing the direction of shingling at one end of the array for rows to be put in parallel with the corresponding rows at the other end of the array. In FIG. 6I, rows 6610I′ and 6610I^{iv} have been reversed and each half row put in parallel with the opposite half row of rows 6610I″ and 6610I″′ respectively. As shown schematically, the inside edge of reversed rows will be at the same voltage as the inside edge of the rows these are paired with. With either shingled cells or side-contact cells, a separate insulator 66102 will generally thus be used between the reversed row(s) and the rest of the array since these will be of greatly different voltage. (For clarity only the inside edge connections of the cross-coupled rows have been shown in 6I; see 6F for the outside-edge connections).

However as shown in FIG. 6J, if the entire array is paired up with half of all rows being reversed, the two central rows will be at the same voltage and no insulator will be needed. One contact 66101′ (shown schematically) for the whole array 66100J connects to the middle of the array, and the other contact 66101″ for the whole array 66100J connected to both ends of the array. While this cuts the voltage of the array in half and doubles its current, this forms an especially preferred embodiment when the receiver is large enough, or the cells are narrow enough, that the voltage is still a suitable voltage for a high-efficiency inverter with an acceptable number of receivers in series.

If a higher voltage is needed the entire receiver can be of cross-coupled half rows as taught earlier. Also, if the focus is uneven along the length of the receiver, different width rows can be used as taught earlier. For example, when the focus is not even along the receiver, combining paired rows at the ends of the receiver with different width rows to equalize the maximum power-point photocurrents of the rows is exemplary.

### Seventh Family of Preferred Embodiments

### Mutual-Shading-Impact Minimization Methods that are Compatible with High-Concentration Photovoltaic Tracking Requirements

Anti-shading algorithms for trackers with non-concentrating flat panels are known in the art. Trackers can have sensors to detect when their lowest rows of cells are shaded, and the sensors can then cause the shading tracker to backtrack until those cells are no longer shaded. However high-concentration photovoltaic systems by nature have very narrow acceptance angles, and so only work when pointed accurately at the sun. Anti-shading algorithms that would back-track CPV systems by more than a degree (or at most a few degrees even for high acceptance-angle designs) would misalign the CPV optics enough that no appreciable power would be generated.

Most CPV systems have bypass diodes anyway to cover for defective cells or bird droppings or other soiling significantly shading some cells, and these bypass diodes allow an array to function even when partly shaded. However bypass diodes have non-zero resistance, so when many are used in series, they still diminish power production. Furthermore including in bypass diodes increases manufacturing cost and complexity, and bypass diodes have non-zero leakage.

The even-focus systems as taught by Norman and improved upon in the present application avoid some of these issues by spreading light from each reflective panel across the receiver, rather than directing it to any given cell. But even so it is only the light from all mirrors that is spread evenly, not the light from any given mirror, and so significantly shading a subset of the mirrors produces less even intensity at the focus, and that un-evenness grow significant as more and more mirrors are shaded. While spacing the trackers far apart would minimize the amount of time that they shade each other, closer packing of the trackers produces more power from a given area and also minimizes trenching, conduit and wiring length from the trackers to the inverter. There is thus a need for CPV-compatible methods of minimizing the impact of mutual shading in densely-packed fields of trackers.

When the sun is low to the horizon, the tops of the trackers in one row tend to shade the bottoms of the trackers in the next row farther from the sun. The first set of mirrors shaded is the farthest from the focus, and has its light spread widely so shading those mirrors diminishes the light on the focus relatively evenly. Even with the bottom quarter of a dish shaded, one end of the receiver receives a bit of extra light that it cannot use efficiently, but no area of the receiver receives too little light to be productive. Also the embodiments of the present invention that put the output of one or more rows of cells at one end of the receiver in parallel with the output of one or more rows of cells at the other the receiver keeps the rows that lose the most light paired with those that lose the least light, helping maintain evenness.

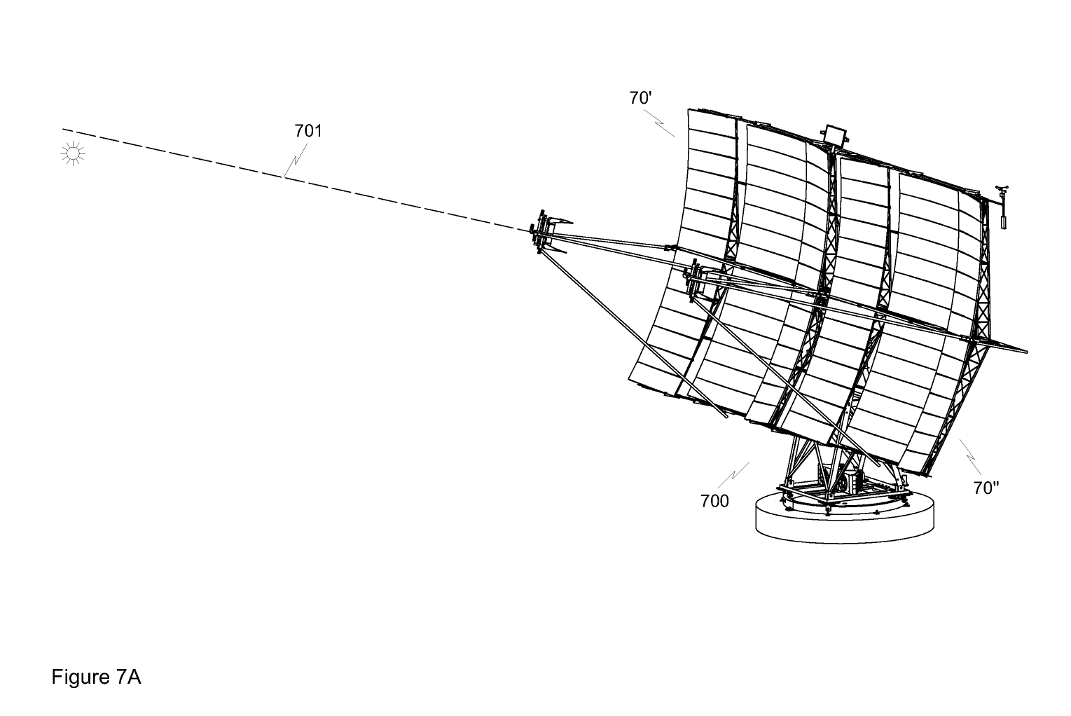

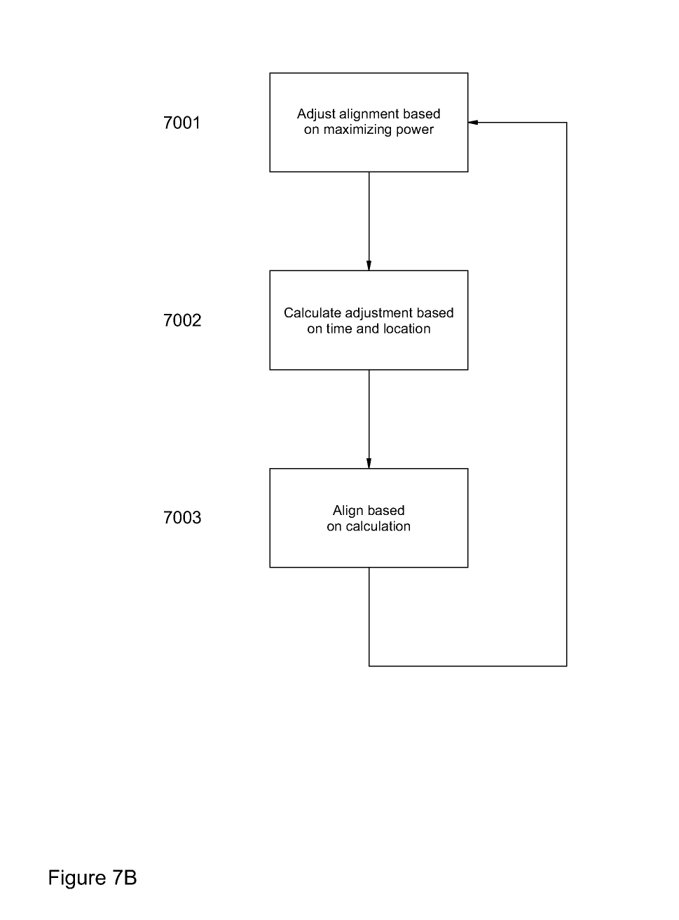

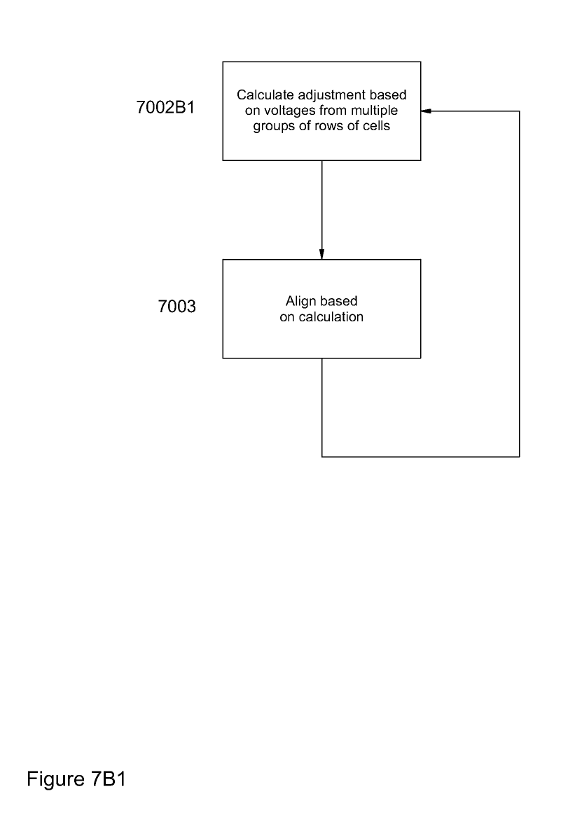

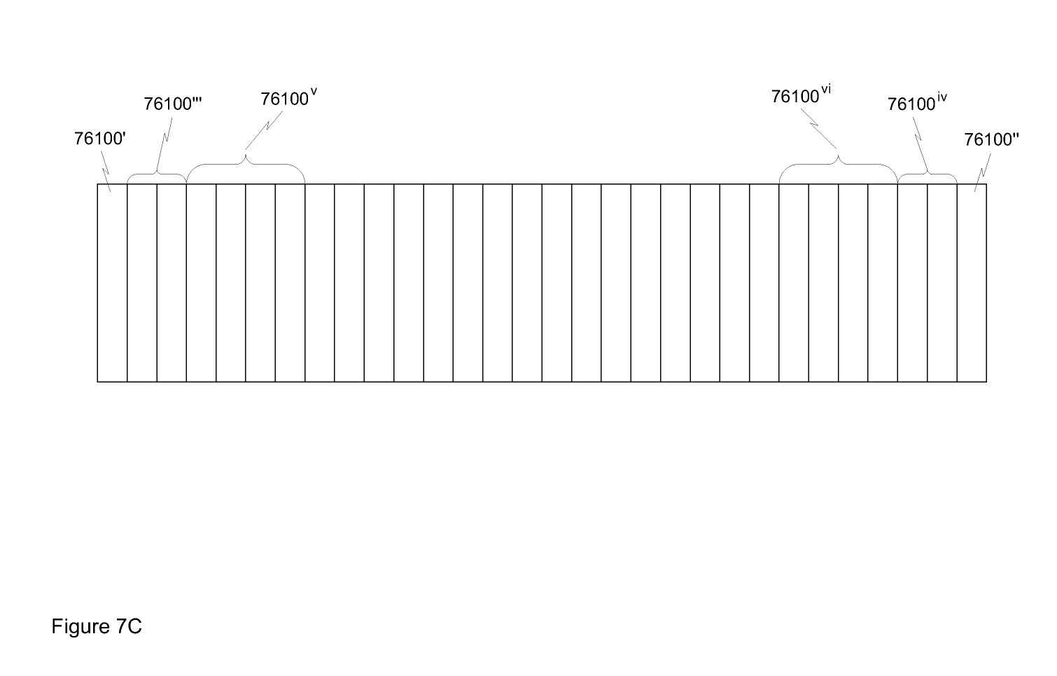

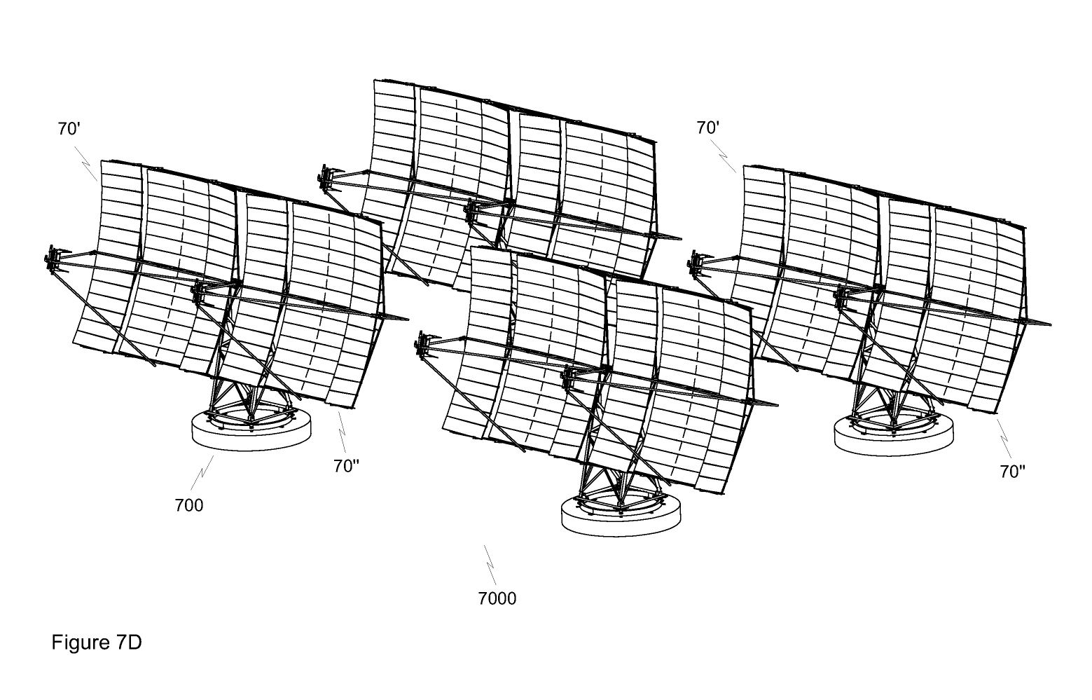

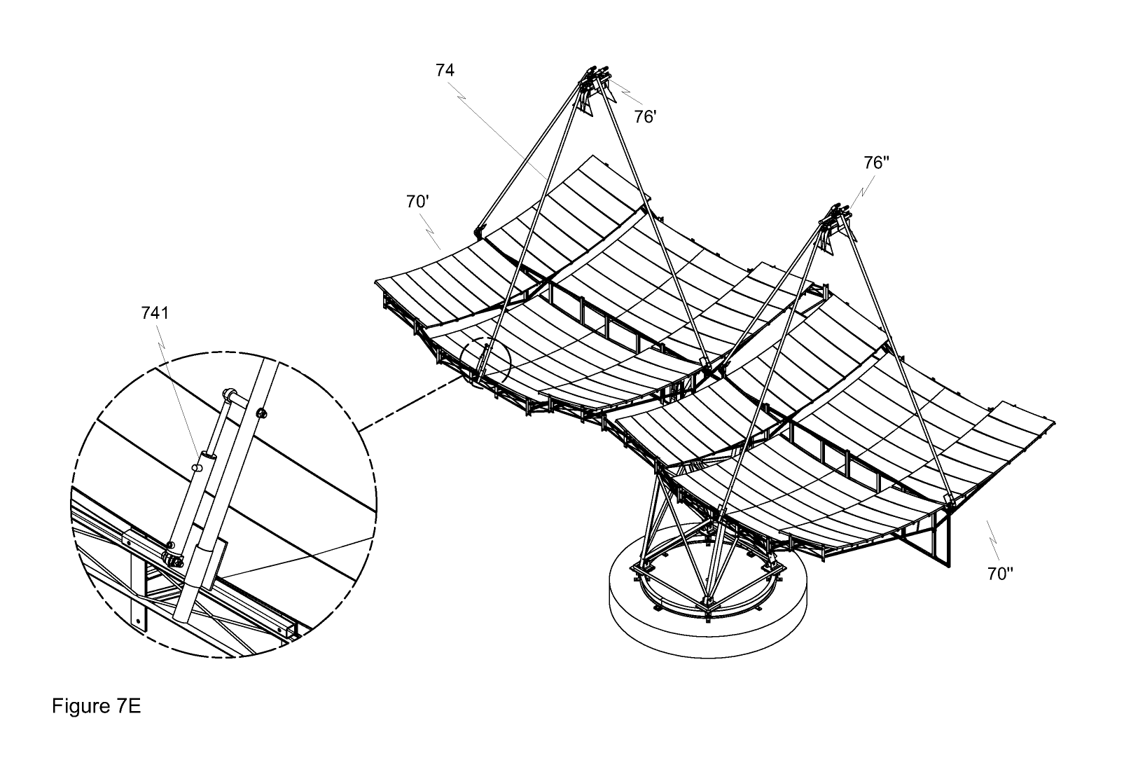

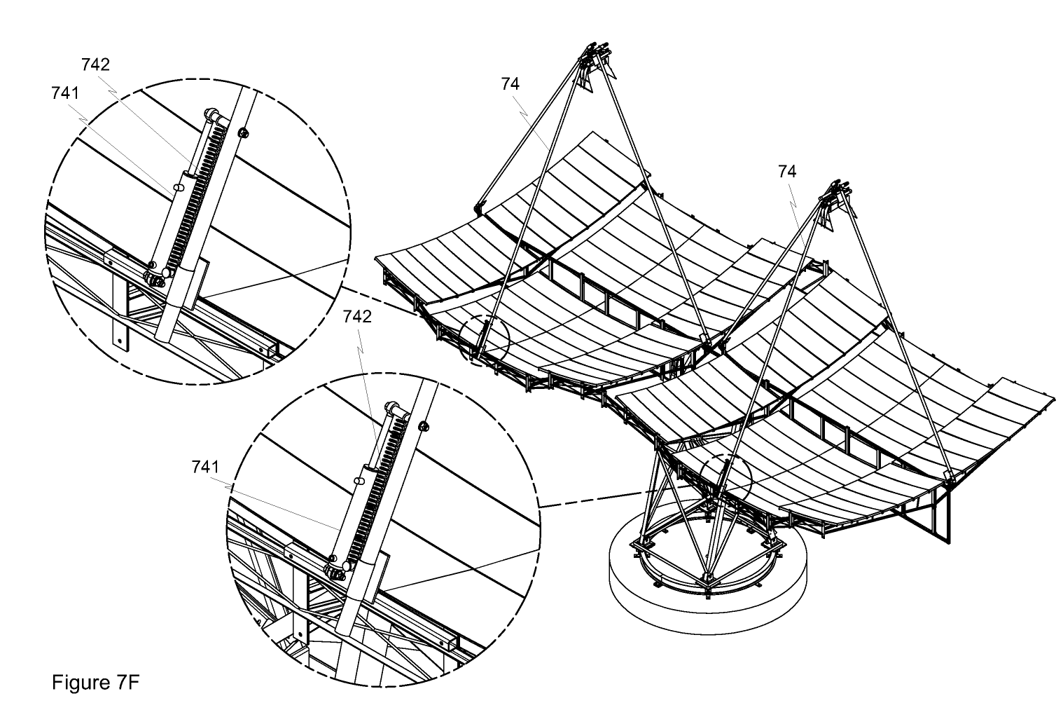

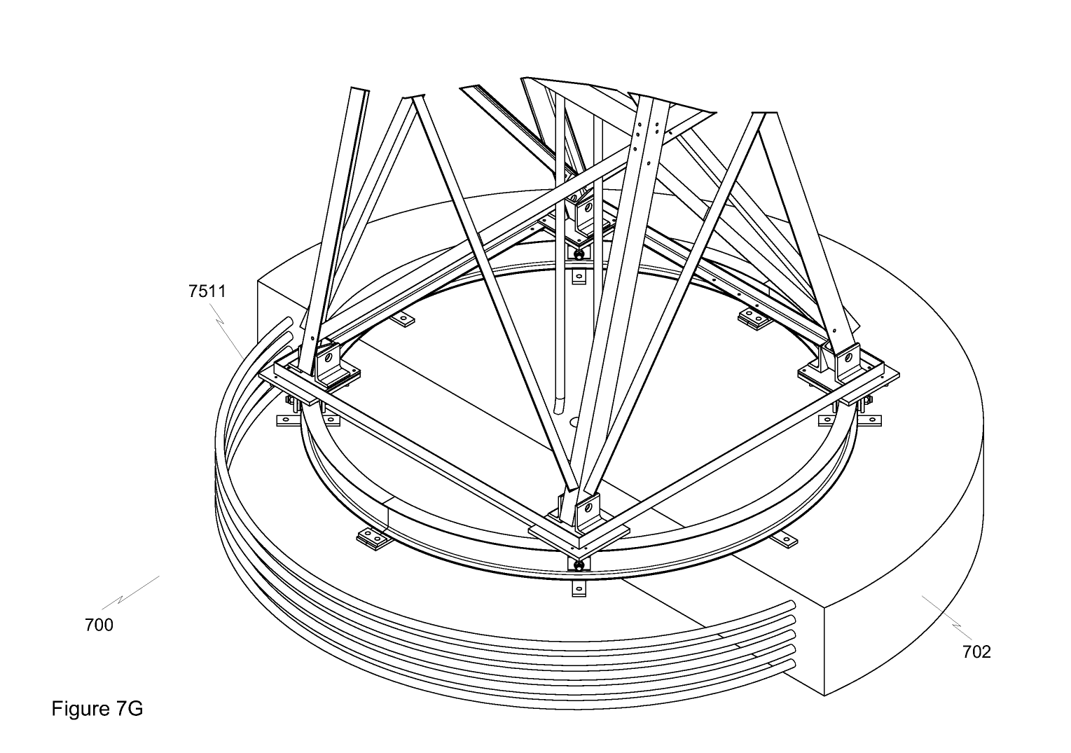

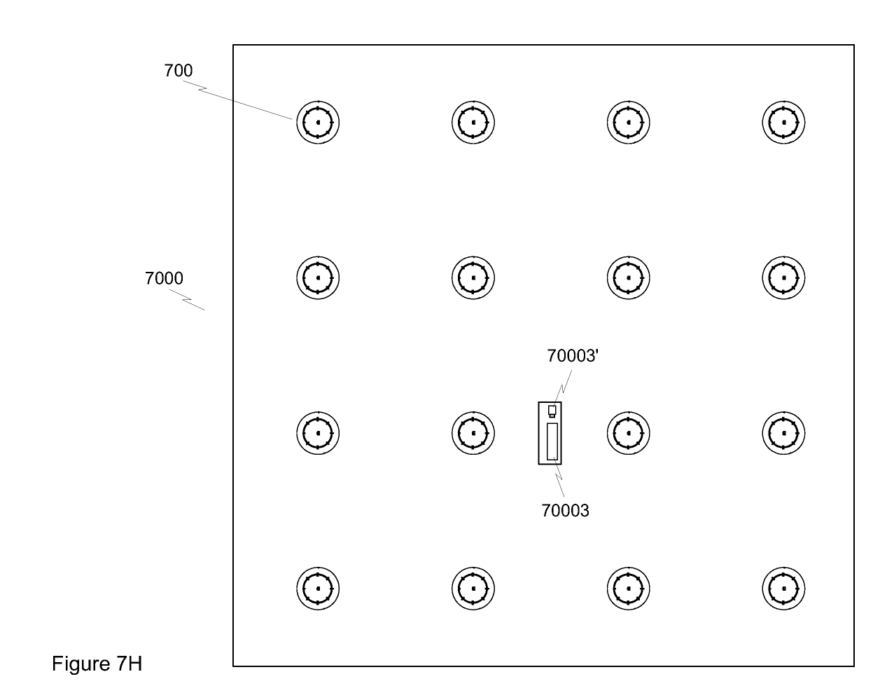

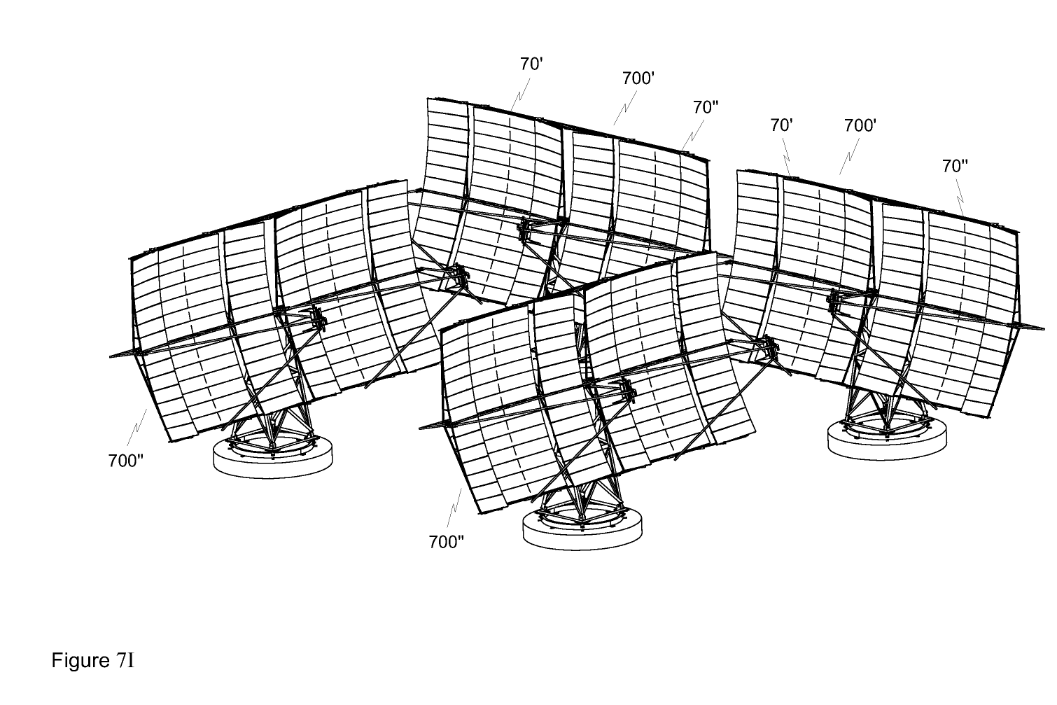

But the more shaded the dish becomes, the more uneven the illumination becomes, and the efficiency starts to drop more rapidly. However if the dish is slightly misaligned in the right direction relative to the direction of the sun, more of the light will fall onto the least illuminated portions of the receiver. While misaligning the dish does reduce its concentrating power due to off-axis aberration, this is more than made up for by evening out the light on the focus. As shown in FIG. 7A, a preferred embodiment of the present invention therefore comprises a method for deliberately slightly misaligning the tracker 700 and its dishes 70′ and 70″ (which may be the same as dishes previously taught in the present application or may be dishes of other suitable design) relative to the sun to maximize the power output under partial shading. If the tracker were truly tracking the sun's position, the axes of symmetry 701 of the dishes, as shown as a dashed line, would point straight at the sun, whereas due to the partial shading of the lower portion of dishes 70′ and 70″ the axis of symmetry is pointed slightly off from the sun.

This is somewhat similar to what Lasich teaches in U.S. Pat. No. 7,109,461 in maximizing the current output of the receiver as a source of fine tracking. However what Lasich teaches is to equalize the power output between the top of the receiver and the bottom of the receiver, and to use that as a proxy for actually maximizing the power. Under typical conditions of symmetric light intensity on the receiver Lasich's equalization of power is an excellent approximation of maximizing the total power output of the dish, and even if the weaker half of the dish were always uniformly illuminated Laisch's approximation would be accurate. But when partial shading produces significantly asymmetric light intensity on the receiver, equalization does not maximizes the power output because it forces the power levels of the two halves to be equal, and by the time that the weakest section of the weaker half is productive, the half that was weaker would typically be producing more power than the half that was stronger. Having the most weakly illuminated section of the receiver productive is a prerequisite for getting any power if bypass diodes are not used. If bypass diodes are used, the weakest section may be bypassed in maximizing power, but this leaves more receiver area productive in the more illuminated section, and hence leaves the more illuminated section producing more power than the less illuminated section when total power is at its maximum. Thus Lasich's approximation of equalizing power does not in general maximize power, although it is a good approximation thereof under Lasich's normal operating conditions.

Actually maximizing the power requires monitoring the power while adjusting the position of the receiver relative to the sun. Many tracking systems track discontinuously, starting and stopping, and multiplying the number of stops and starts to maximize the power each time would increase wear on the motors. As shown in the process flowchart of FIG. 7B, a further preferred embodiment of the present invention for discontinuous trackers therefore minimizes wear and tear on the motors by periodically using power maximization for fine tracking alignment (step 7001), and by calculating an adjustment based on astronomic tracking (step 7002) and aligning the tracker by adjusting its position based on the calculated adjustment (step 7003) at least once in before returning to step 7001 to re-maximize the power through iterative adjustments and measurements. Because the tracking movement is typically done several times per minute and the amount of shading changes very little over the course of a single minute, this produces essentially all of the benefits that maximizing the power for each tracking movement, but at a fraction of the cost.

The power per half-receiver is also a crude measurement for predicting how much the tracker should be moved under various shading conditions. Measuring voltage is also far easier than measuring current, so another preferred embodiment of the present invention measures the voltage difference across sets of small numbers of rows of cells, providing information on the insolation on each set of rows of cells. While this does divert some photocurrent to the measuring device instead of having all the photocurrent go to the system's power output, the current needed to measure voltage is so miniscule that even measuring the voltage across every row of cells individually would not have a significant impact on power output. The simplicity of measuring voltage allows numerous sets of rows to be measured, to the point of allowing, as shown in FIG. 7B1, a shading profile to be determined accurately enough to calculate (Step 7002B1) how far the tracking should be shifted from its current misalignment, and thus allowing the entire correction to be made the next time the tracking motors are activated (Step 7003).

The sets of rows of cells being monitored do not have to contain equal numbers of rows of cells, nor do they have to be distributed equally along the receiver. As shown in FIG. 7C, a further preferred embodiment of the present invention measures the voltage across sets 76100′, 76100″, 76100″′, 76100^{iv}, 76100^{v} and 76100^{vi} of rows of cells near the ends of the receiver, which are most sensitive to the effect partial shading of a dish. The sets 76100^{v} and 76100^{vi} of rows of cells farther from the ends of the receiver contain more rows of cells, allowing more rapidly determining the magnitude of the misalignment needed to correct for detect highly uneven illumination of the dishes without needing to measure too many sets of rows of cells, while the smallest sets 76100′ and 76100″ of rows of cells at the ends of the receiver provide the finest detail for maintaining the proper misalignment as the partial shading slowly evolves. A set of rows can contain only a single row.

For dual-dish systems as taught by Norman, one dish may be much more shaded than the other and therefore misaligning until the dishes produce equal power will typically not maximize the total power. In the extreme case of one dish being mostly shaded while the other is in full sun, the power will be maximized by completely ignoring the mostly shaded dish. But for dishes of the sizes that Norman teaches and current high-efficiency solar cells, two dishes need to be in series to feed a typical inverter. And if the two dishes on a tracker are in series with each other (which minimizes the dish-to-inverter wiring), then the output of the dishes would be forced to be nearly equal in order to match the photocurrents. As shown in FIG. 7D, in a large regular array 7000 of trackers, the same dish 70′ on each tracker 700 will be shaded by a tracker in the previous row of trackers, so a preferred embodiment of the present invention puts the left dish 70′ of one tracker in series with the left dish 70′ of a neighboring tracker, and the right dishes 70″ of these two trackers in series, rather than putting the dishes 70′ and 70″ of the same tracker 700 in series.

If the density of an array 7000 of trackers 700 is high enough that one dish 70′ of a tracker 700 becomes significantly shaded while the other dish 70″ remains much less significantly shaded, the maximum power can be further increased by allowing the receiver of one dish 70′ to have independent shade-impact minimization movement from the receiver of other dish 70″ on the tracker along the length of the receiver. Norman teaches accomplishing this in two dimensions by moving the whole receiver relative to the receiver mounts. But, as shown in FIG. 7E, a simpler and thus preferred way to accomplish this in one dimension is by means that allow changing the length of the receiver support leg that fixes the altitude of the receiver 76′ relative to the dish 70′, while leaving receiver 76″ fixed relative to dish 70″. Since the receiver weighs far less than and has far less area for wind loading than the whole dish, this can be accomplished with a small linear actuator 741 in receiver support leg 74.

When the grid power fails, cooling and tracking systems that use AC power from the grid for their motors cease functioning. As shown in FIG. 7F, in further preferred embodiments each receiver support altitude leg 74 has a linear actuator 741 to allow it to move independently of the receiver's dish, and these linear actuators 741 have enough travel to more the receivers entirely out of the foci of the dishes. This can allow the receivers to be moved off-focus very rapidly should the cooling system fail (whether for grid power failure or any other reason), without requiring the whole tracker to move rapidly. In even further preferred embodiments the actuators 741 push or pull against fail-safe mechanisms such as springs 742 that will move the receivers off focus should the power fail. Alternatively these actuators may be powered by flat solar panels or low-concentration solar panels that will always supply power when the sunlight is bright enough that a receiver at a focus that would be damaged if not cooled.

While Norman teaches using a tank of cooling water to ballast a tracker, even when a concrete base is used the thermal mass of the concrete can provide emergency cooling if a solar panel provides enough power to run the water pump. While the specific heat and thermal conductivity of concrete are too low to provide efficient cooling for normal operation, they are sufficient to provide hours of emergency cooling that just keeps the cells below their maximum operating temperature. As shown in FIG. 7G, the concrete tracker base 702 of a tracker 700 can have cooling fluid piping 7511 embedded in it. In addition to providing thermal mass for keeping the cells cool in when the fans cannot be run, such cooling fluid piping 7511 embedded in the concrete base can use the thermal mass of the concrete base to keep the cells warm at night or if the sun goes behind clouds for extended periods, reducing stress from thermal cycling. This only consumes a tiny amount of energy to keep a trickle of coolant flowing, or to occasionally send a pulse of warmer fluid from the concrete base to the receiver. By storing heat in the concrete from cooling the 1000 suns focus, the concrete can also be kept from freezing on winter nights, reducing the frequency of freeze/thaw cycles to extend the life of the concrete base. If the concrete is even modestly insulated, freeze/thaw cycles can be largely or even completely eliminated even in moderately cold climates. This can also allow reducing the antifreeze in the cooling fluid or even eliminating it (pure water is a better heat transfer fluid than water with antifreeze).

When keeping the receiver warm when the sun is not shining would be the only use of the concrete's thermal mass, the amount of power required is modest enough that it is preferable to install an electric heater in each receiver instead. This would greatly reduce the extreme thermal cycling that leads materials fatigue, although it would not avoid a possible one-time extreme cycle if the power goes out for an extended period on one of the coldest nights.

Similarly if the only use of the concrete's thermal mass would be to supply emergency cooling, plenty of power is available from the receivers whenever they are at the focal points and the grid is not available, and as shown in FIG. 7H it is preferred to have a small non-grid-tied 70003′ inverter near each main (grid-tied) inverter 70003 to provide AC power to run the cooling (and tracking) whenever the grid is down. Because each inverter 70003 typically serves an array 7000 of trackers 700 (for clarity only the foundation and track of each tracker is shown), a single non-grid-tied inverter 70003′ thus provides backup power to a number of trackers to minimize the cost and complexity of providing this backup power.

Such backup power for tracking and cooling can be used to keep the array of trackers on-sun and ready to supply power as soon as the grid is restored. When local storage such as batteries is available, such backup power fro tracking and cooling can keep the systems productively charging the local storage. In the case of the dual-receiver embodiments taught by Norman, such backup power can also be used to place a vast majority of the trackers of a large array into thermal collection and storage mode, keeping just enough trackers in photovoltaic mode to power the tracking and heat-transfer fluid pumping, and cooling the active photovoltaic receivers themselves.

Even with maximizing the power by adjusting the tracking, there comes a point when the illumination is uneven enough that the efficiency is reduced. With the sun low in the sky and the sunlight passing through more air, the sunlight will be weaker as well, and between that and partial shading the intensity of the light will eventually drop well below the cells' peak efficiency intensity. As shown in FIG. 7I, another preferred embodiment of the present invention, which can either be instead of or in addition to the aforementioned preferred embodiments of the present invention such as power maximization searching, therefore includes a method for minimizing shading of the panels on one set of trackers 700′ by turning the shading trackers 700″ edge-to-the-sun rather than face-to-the-sun. Although the edge-on trackers 700″ will then produce essentially no power, this lets the light fall onto trackers 700′ that will then be in close-to-optimal illumination conditions.

As a rule of thumb half of the trackers can be turned on when the sun is low enough in the sky that the trackers are approximately half shaded. If the power maximization impact minimization is not also implemented, or if the sun's intensity is such that the cells will be more efficient at the full intensity than at half that intensity, turning half of the trackers edge-on will generally be worthwhile slightly before the trackers are half shaded. If power-maximizing is implemented as described above and the sunlight is strong enough that the cells are more efficient at half-intensity than at full intensity, then turning half of the trackers edge-on will generally not be worthwhile until slightly after the trackers are half shaded. Further preferred embodiments use the cells' efficiency versus insolation curve combined with the intensity of the sunlight (or with some proxy for the intensity such as the temperature rise within the receiver divided by the coolant flow rate), in calculating when to turn some of the trackers edge-to-the-sun.

Since the trackers will generally be in an orderly array, in general the pattern of trackers turned edge-to-the-sun will be a regular pattern such as turning every second row of dishes edge-to-the-sun. If the pairing of left-dish with left dish as taught above is used, then even further preferred embodiments of the present invention match the pairing pattern of dishes 70′ with 70′ and 70″ with 70″ to pattern of tracker 700′ left face-to-the-sun so that the dishes in series will either both be edge-to-the-sun or both be face-to-the-sun.

Still further preferred embodiments of the present invention turn additional trackers when the sun is even lower in the sky. One way preferred method for this is to turn half of the remaining face-to-the-sun trackers edge-to-the-sun whenever the face-to-the-sun trackers are roughly half shaded (and using the converse algorithm in the morning, as more and more trackers are brought on line). This never requires switching trackers back and forth the between edge-on and face-on during the same morning or evening.

However at higher latitudes the sun changes altitude only slowly, so at sufficiently high latitudes (with the exact latitude depending on tracker speed and tracking power requirements) it is more preferred to switch from ½ to ⅓ to ¼ of the trackers face-to-the-sun rather than jumping straight from ½ to ¼. At the South Pole, for example, ⅓ facing the sun might be optimal for days on end. Even at the poles the shift from ¼ to ⅕ would happen faster than ½ to ⅓ or ⅓ to ¼ (since it is a smaller change in the position of the sun) and it would keep even fewer trackers in unswitched. Therefore even at the poles the preferred method starts with 1, ½, ⅓, etc. and then switches to ½̂N (1 over 2 to the Nth power) of the trackers facing the sun at a fairly low value of N.

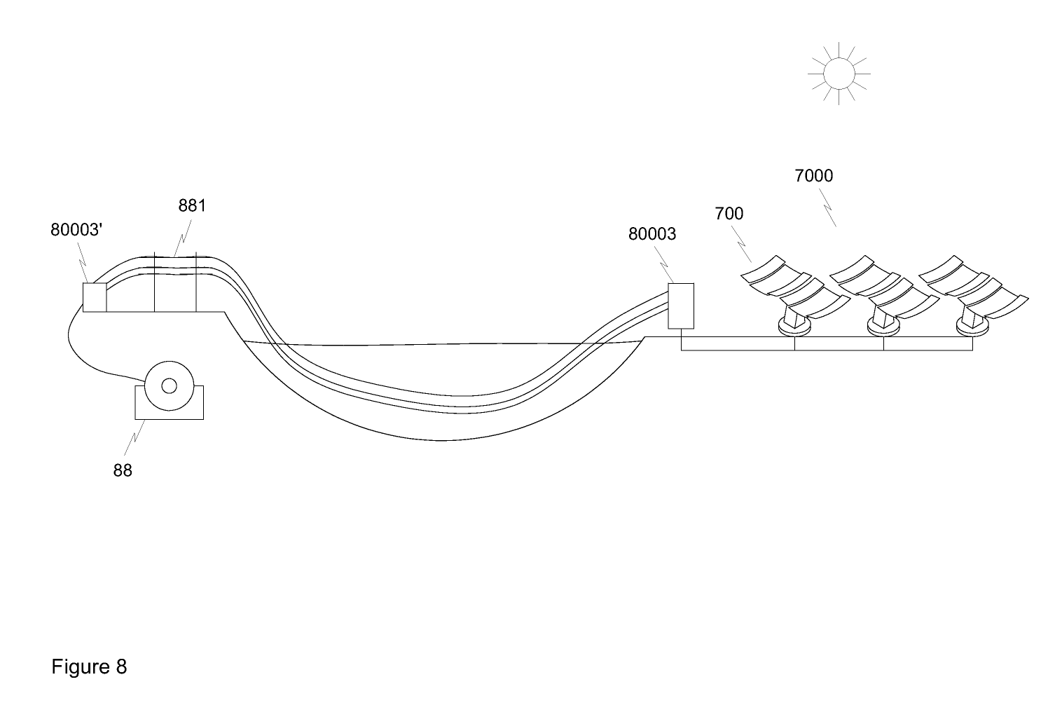

In many cases the best solar energy resources are located at significant distance from the main demands for electricity. This is especially true with systems that use lenses or mirrors to concentrate solar energy because they require clear skies and direct sunlight such as are typically found in deserts, and civilizations are usually concentrated in regions of plentiful water. The embodiments of the present invention are directed to cost-effectively generating power in such regions with plentiful direct sunlight, and so as seen in FIG. 8, arrays 7000 of trackers 700 will typically have their output stepped up to very high voltage by a voltage converter 80003 (which for AC transmission will typically be a transformer) for transmission over transmission lines 881 to a step-down voltage converter 80003′ near the point of a load, represented by large electric motor 88. In such a manner electricity from solar energy can be delivered cost-competitively with electricity from fossil fuels even in regions lacking suitable levels of direct sunlight.

The above examples and embodiments used to illustrate the families of preferred embodiments of the present invention are meant to be illustrative rather than limiting, and many of the features taught under one family of preferred embodiments may be used advantageously under other families of embodiments. In general, when a combination of features taught herein complement each other in an unexpected way, the combination is discussed, but combinations that merely complement each other as would be expected from understanding the individual feature are generally not discussed unless they provide the foundation for understanding other improvements.

The physical form factors presented are also meant to be illustrative rather than limiting examples. For example, moderately long, moderately narrow glass mirrors have been used for primary concentration in the examples because glass is currently the most field-proven type of mirror, but polymer mirror are improving rapidly. Also copper and aluminum nitride have been used as heat conductors in the examples, but if diamond were to become affordable it is six times better a heat conductor than copper and twelve times better than aluminum nitride, and carbon nanotubes are potentially even better heat conductors in one direction (along their length) than even diamond.

The use of photovoltaic receivers as used herein is in general an example, and in some many cases solar thermal receivers, photochemical receivers, etc. may also be used with preferred embodiments of the present invention (for example, turning a portion of the trackers sideways to the sun when the sun is low to keep the concentration on the remaining receivers high can be even more important for solar thermal receivers than for photovoltaic receivers). The concentration of energy from our sun as used herein is also meant to be an example. Other sources of optical and infrared energy may by concentrated, as long as their incoming rays are substantially parallel, and a light at the focus can also be turned into a collimated beam of light. Other forms of radiant energy may also be concentrated or turned into a collimated beam, such as radio waves or acoustic energy.

Even these examples of examples are meant to be illustrative rather than limiting, and numerous minor variations, especially in trading generality for features for specific purposes, will suggest themselves to those familiar with the relevant art upon reading the above descriptions of the preferred embodiments.

1. A two-axis concentrated photo-voltaic (CPV) apparatus having a substantially rectangular receiver of a given length and width, a large number of elongated solar reflective panels curved substantially in only one direction at any given point, the panels having width approximately equal to a length of the receiver, a frame mounting the panels to form a primary reflective surface whose shape in one dimension is substantially parabolic and mounting the receiver with respect to the panels, and a two-axis tracking mounting for the frame,
wherein said apparatus is structured to increase uniformity in concentrated solar flux on said receiver by at least one of:
said elongated solar reflective panels having a primary reflective surface whose shape in said one dimension differs from parabolic in manner which reflects more light onto certain regions of a secondary concentrator than a parabolic shape would, and in which the more light directed to said certain regions is redirected by said secondary concentrator to produce a more even solar flux in said dimension than if a primary reflective surface parabolic in said one dimension had been used;
a set of closely-packed refractive optical elements, wherein each element further concentrates onto one or more solar cells light concentrated by said reflective panels acting as a primary concentrator, wherein the combined aperture area of said closely-packed refractive optical elements is at least twice the combined optically receptive area of the solar cells that they concentrate onto, and wherein the aperture area of said reflective panels is at least ten times the size of the combined aperture area of said closely-packed refractive optical elements, the intensity of light across said closely-packed refractive optical elements is substantially uneven, and where each of said closely-packed refractive optical elements has an aperture area substantially inversely proportion to the average intensity of light across its aperture;
the receiver having a dense array of solar cells, the intensity of light across said dense array of solar cells being substantially uneven, each of said cells having an optically receptive area substantially inversely proportional to the average intensity of light across said optically receptive area;
a controller for said two-axis tracking mounting by rapidly iteratively adjusting its alignment relative to the sun and comparing the power output across iterations, until a maximum power output alignment relative to the sun is determined, and then adopting that maximum power alignment relative to the sun under conditions of partially shading of said reflective panels;
a controller system for said two-axis tracking mounting and other like CPV apparatus, wherein when the sun is low enough that most of said CPV apparatus are partly shaded by other CPV apparatus, said two-axis tracking mounting is turned away from the sun to minimize the shadow that said reflective panels cast on other said like CPV apparatus; and
two legs forming part of said frame and supporting said receiver that have pivots at their feet and a third leg in between said two legs wherein said third leg has an automatically controllable length adjustment mechanism for adjusting a position of said receiver in a direction of said width.

2. A CPV apparatus as claimed in claim 1, wherein said primary reflective surface is supported by a frame comprising substantially parallel, substantially identical rails whose shape establishes said shape of said primary reflective surface in said one dimension.

3. A CPV apparatus as claimed in claim 2, wherein said rails support segments of said primary reflective surface that curve substantially in only one dimension at any given point.

4. A CPV apparatus as claimed in claim 3, wherein each of said segments has an individual focus whose longest dimension is substantially parallel to said rail.

5. A CPV apparatus as claimed in claim 1, wherein said primary concentrator concentrates solar energy in two dimensions, and wherein the aperture area of primary concentrator is at least one hundred times the size of the combined aperture area of said closely-packed refractive optical elements.

6. A CPV apparatus as claimed in claim 1, wherein the intensity of light across said closely-packed refractive optical elements is substantially uneven, and wherein each of said closely-packed refractive optical elements has an aperture area substantially inversely proportion to the average intensity of light across its aperture.

7. A CPV apparatus as claimed in claim 1, wherein multiple ones of said set of closely-packed refractive optical elements are fabricated as a single monolithic piece.

8. A CPV apparatus as claimed in claim 7, wherein said set of closely-packed refractive optical elements is fabricated in at most two pieces.

9. A CPV apparatus as claimed in claim 1, wherein said solar cells are arranged in multiple groups of cells and where cells within a given group of cells are electrically in parallel and wherein said groups are electrically in series.

10. A CPV apparatus as claimed in claim 9, wherein said solar cells are arranged in a substantially regular array and wherein said groups of cells are rows of cells.

11. A CPV apparatus as claimed in claim 9, wherein the intensity of light across said closely-packed refractive optical elements is substantially uneven, and wherein the total aperture area of the refractive optical elements that concentrate onto a group of cells is substantially inversely proportion to the average intensity of light across said total aperture area.

12. A CPV apparatus as claimed in claim 11, wherein at least one of said groups has a first sub-group of its refractive optical elements located near one end of the set of closely-packed refractive optical elements and has a second sub-group of refractive optical elements at the opposite end of said set of closely-packed refractive optical elements, and wherein the total aperture area of said first sub-group is substantially equal to the total aperture area of said second sub-group.

13. A CPV apparatus as claimed in claim 12, wherein said first and second sub-groups are at opposite corners of said set of closely-packed refractive optical elements.

14. A CPV apparatus as claimed in claim 13, wherein each group comprises a first sub-group and a second sub-group, and for each group said first sub-group is substantially as far from one end of said set of closely-packed refractive optical elements as said second sub-group is from the opposite end of said set of closely-packed refractive optical elements.

15. A CPV apparatus as claimed in claim 1, wherein said solar cells are arranged in multiple groups of cells and wherein cells within a given group of cells are electrically in parallel and wherein said groups are electrically in series.

16. A CPV apparatus as claimed in claim 15, wherein at least one of said groups has a first sub-group of solar cells located near one end of said dense array of solar cells and has a second sub-group of solar cells at the opposite end of said dense array of solar cells, preferably at opposite corners of said dense array of solar cells, and where the total optically receptive area of said first sub-group is substantially equal to the total optically receptive area of said second sub-group.

17. A CPV apparatus as claimed in claim 16, wherein each group comprises a first sub-group and a second sub-group, and for each group said first sub-group is substantially as far from one end of said dense array of solar cells as said second sub-group is from the opposite end of said dense array of solar cells.

18. A CPV apparatus as claimed in claim 15, wherein one or more secondary concentrators further concentrate said solar energy between said primary concentrator and said receiver.

19. A CPV apparatus as claimed in claim 18, wherein said one or more secondary concentrators also even out the intensity of the focus of said primary concentrator onto said receiver.

20. A CPV apparatus as claimed in claim 1, wherein after determining a maximum power alignment relative to the sun, said controller is operative to perform at least one subsequent adjustment of the alignment relative to the earth is based on calculation of the movement of the suns' position relative to the earth before another cycle of iterative adjustment while comparing power output is performed.

21. A CPV apparatus as claimed in claim 20, wherein the receivers on multiple trackers that are in series to feed a given inverter input are all on trackers that are turned away from the sun or are all on trackers that are left substantially aligned to the sun when one half of said trackers are turned away from the sun to minimize the shadow that they cast on other trackers.

22. A CPV apparatus as claimed in claim 1, wherein said automatically controllable length adjustment mechanism is used to fine-tune the positioning of said at least one receiver relative to the rest of said multi-receiver tracker.

23. A CPV apparatus as claimed in claim 22, wherein said automatically controllable length adjustment mechanism includes a fail-safe mechanism that automatically moves said receiver out of the focus of the concentrated solar energy if ability to cool said receiver is lost.

24-147. (canceled)

148. A solar power system comprising an electrical load, a transmission line, and a two-axis concentrated photovoltaic apparatus as claimed in claim 1, wherein the electricity is then transported over the transmission line to reach the load.
